(19) United States
(12) Patent Application Publication
(10) Pub. No.: US 2025/0185350 A1
(43) Pub. Date: Jun. 5, 2025

(54) SEMICONDUCTOR DEVICE

(71) Applicant: FUJI ELECTRIC CO., LTD., Kanagawa (JP)

(72) Inventor: Motoyoshi KUBOUCHI, Matsumoto-city (JP)

(21) Appl. No.: 19/037,269

(22) Filed: Jan. 26, 2025

Related U.S. Application Data
(63) Continuation of application No. PCT/JP2023/041838, filed on Nov. 21, 2023.

(30) Foreign Application Priority Data
Feb. 7, 2023 (JP) 2023-016618

(51) Int. Cl. H10D 84/00; H10D 8/00; H10D 12/00; H10D 62/10; H10D 62/13; H10D 62/53; H10D 62/60

(52) U.S. Cl. CPC H10D 84/161; H10D 8/422; H10D 12/418; H10D 12/481; H10D 62/107; H10D 62/145; H10D 62/53; H10D 62/60

(57) ABSTRACT

Provided is a semiconductor device including a transistor portion and a diode portion arranged side by side with the transistor unit in a first direction, including a first mesa portion and a second mesa portion arranged farther away from the diode portion than the first mesa portion, wherein: the first mesa portion has a first region of the first conductivity type, provided in at least a partial region between a depth position of a lower end of the base region and a depth position of a lower end of the trench portion; and the second mesa portion has a second region of the first conductivity type, provided in at least a partial region between the depth position of the lower end of the base region and a depth position of the lower end of the trench portion, with a dose amount greater than that of the first region.

The contents of the following patent application(s) are incorporated herein by reference:
NO. 2023-016618 filed in JP on Feb. 7, 2023
NO. PCT/JP2023/041838 filed in WO on Nov. 21, 2023.

### BACKGROUND

### 1. Technical Field

The present invention relates to a semiconductor device.

### 2. Related Art

In a semiconductor device with a transistor portion and a diode portion, a structure where a defect region is formed in part in the diode portion and the transistor portion to adjust carrier lifetime is well known (for example, see Patent Document 1). In a semiconductor device, a structure that connects electrodes and a semiconductor substrate with contacts in a trench shape is also known (for example, see Patent Document 2).

Patent Document 1: WO2021/145079

Patent Document 2: Japanese Patent No. 7085975

### BRIEF DESCRIPTION OF THE DRAWINGS

FIG. 1 is a top view illustrating an example of a semiconductor device 100 according to one embodiment of the present invention.

FIG. 2 illustrates an enlarged view of a region D in FIG. 1.

FIG. 3A illustrates a view showing an example of a cross section e-e in FIG. 2.

FIG. 3B illustrates another example of the cross section e-e in FIG. 2.

FIG. 3C illustrates another example of the cross section e-e in FIG. 2.

FIG. 3D illustrates another example of the cross section e-e in FIG. 2.

FIG. 3E illustrates another example of the cross section e-e in FIG. 2.

FIG. 3F illustrates another example of the cross section e-e in FIG. 2.

FIG. 4A illustrates a view showing an example of a cross section f-f in FIG. 2.

FIG. 4B illustrates a figure showing one example of the cross section f-f in FIG. 2.

FIG. 4C illustrates one example the cross section f-f.

FIG. 4D illustrates one example of the cross section f-f.

FIG. 4E illustrates one example of the cross section f-f.

FIG. 4F illustrates one example of the cross section f-f.

FIG. 5 illustrates an example of a doping concentration distribution on a line r-r′ and a line s-s′ of FIG. 3A.

FIG. 6 illustrates another example of a doping concentration distribution on the line r-r′ and the line s-s′.

FIG. 7 illustrates a view showing another example of the cross section e-e.

FIG. 8A illustrates enlarged views near a first mesa portion 61, a second mesa portion 62 and a third mesa portion 63.

FIG. 8B illustrates enlarged views near the first mesa portion 61, the second mesa portion 62 and third mesa portion 63.

FIG. 9 illustrates an example of the cross section f-f in FIG. 2.

FIG. 10A illustrates enlarged views near the first mesa portion 61, the second mesa portion 62 and the third mesa portion 63 shown in FIG. 9.

FIG. 10B illustrates enlarged views near the first mesa portion 61, the second mesa portion 62 and the third mesa portion 63 shown in FIG. 9.

FIG. 11A illustrates an example of the doping concentration distribution on a line a-a′ and a line b-b′ of FIG. 10.

FIG. 11B illustrates an example of the doping concentration distribution on the line a-a′ and the line b-b′ of FIG. 10.

FIG. 12A illustrates an enlarged view in the vicinity of the first contact portion 211 shown in FIG. 9.

FIG. 12B illustrates an enlarged view in the vicinity of the second contact portion 212 shown in FIG. 9.

FIG. 13 illustrates a view showing another example of the cross section e-e.

FIG. 14 illustrates an exemplary arrangement of an adjustment region 201 and a non-adjustment region 202 in a top view.

FIG. 15 illustrates a view showing another example of the cross section e-e.

FIG. 16 illustrates enlarged views near the first mesa portion 61, the second mesa portion 62 and the third mesa portion 63.

FIG. 17 illustrates an example of the cross section f-f in FIG. 2.

FIG. 18 illustrates enlarged views near the first mesa portion 61, the second mesa portion 62 and the third mesa portion 63 shown in FIG. 17.

FIG. 19A illustrates an example of the doping concentration distribution on the line a-a′ and the line b-b′ of FIG. 18.

FIG. 19B illustrates an example of the doping concentration distribution on the line a-a′ and the line b-b′ of FIG. 18.

FIG. 20A illustrates an enlarged view in the vicinity of the first contact portion 211 shown in FIG. 16.

FIG. 20B illustrates an enlarged view in the vicinity of the second contact portion 212 shown in FIG. 16.

FIG. 21A illustrates another example of the cross section e-e.

FIG. 21B illustrates another example of the cross section e-e.

FIG. 21C illustrates another example of the cross section e-e.

FIG. 22 illustrates another configuration example of the first mesa portion 61, the second mesa portion 62 and the third mesa portion 63.

FIG. 23 illustrates an example of the doping concentration distribution on a g-g line and a h-h line of FIG. 22.

FIG. 24 illustrates another configuration example of the first mesa portion 61, the second mesa portion 62 and the third mesa portion 63.

FIG. 25 illustrates an example of the doping concentration distribution on the g-g line and the h-h line of FIG. 24.

FIG. 26 illustrates another configuration example of the first mesa portion 61, the second mesa portion 62 and the third mesa portion 63.

FIG. 27 illustrates an example of the doping concentration distribution on the g-g line and the h-h line of FIG. 26.

FIG. 28 illustrates another configuration example of the first mesa portion 61, the second mesa portion 62 and the third mesa portion 63.

FIG. 29 illustrates an example of the doping concentration distribution on the g-g line and the h-h line of FIG. 28.

FIG. 30 illustrates a view showing another example of the cross section e-e.

FIG. 31 illustrates a view showing another example of the cross section e-e.

FIG. 32 illustrates a view showing another example of the cross section e-e.

FIG. 33 illustrates a view showing another example of the cross section e-e.

FIG. 34 illustrates a view showing another example of the cross section e-e.

FIG. 35 illustrates a view showing another example of the cross section e-e.

FIG. 36 illustrates a view showing another example of the cross section e-e.

FIG. 37 illustrates a view showing another example of the cross section e-e.

FIG. 38 illustrates a view showing another example of the cross section e-e.

FIG. 39 illustrates a view showing another example of the cross section e-e.

FIG. 40 illustrates a view showing another example of the cross section e-e.

FIG. 41 illustrates another configuration example of the first mesa portion 61, the second mesa portion 62 and the third mesa portion 63.

FIG. 42 illustrates another configuration example of the first mesa portion 61, the second mesa portion 62 and the third mesa portion 63.

FIG. 43 illustrates another configuration example of the first mesa portion 61, the second mesa portion 62 and the third mesa portion 63.

### DESCRIPTION OF EXEMPLARY EMBODIMENTS

Hereinafter, the present invention will be described through embodiments of the invention, but the following embodiments do not limit the invention according to the claims. In addition, not all of the combinations of features described in the embodiments are essential to the solution of the invention.

As used herein, one side in a direction parallel to a depth direction of a semiconductor substrate is referred to as “upper” and the other side is referred to as “lower”. One surface of two principal surfaces of a substrate, a layer or another member is referred to as an upper surface, and another surface is referred to as a lower surface. “Upper” and “lower” directions are not limited to a direction of gravity, or a direction in which a semiconductor device is mounted.

In the present specification, technical matters may be described using orthogonal coordinate axes of the X axis, the Y axis, and the Z axis. The orthogonal coordinate axes merely specify relative positions of components, and do not limit a specific direction. For example, the Z axis is not limited to indicate the height direction with respect to the ground. It should be noted that the +Z axis direction and the −Z axis direction are directions opposite to each other. If the Z axis direction is described without describing the signs, it means that the direction is parallel to the +Z axis and the −Z axis.

In the present specification, orthogonal axes parallel to the upper surface and the lower surface of the semiconductor substrate are referred to as the X axis and the Y axis. In addition, an axis perpendicular to the upper surface and the lower surface of the semiconductor substrate is referred to as the Z axis. In the present specification, the direction of the Z axis may be referred to as the depth direction. In addition, in the present specification, a direction parallel to the upper surface and the lower surface of the semiconductor substrate may be referred to as a horizontal direction, including the X axis direction and the Y axis direction.

A region from a center of the semiconductor substrate in the depth direction to the upper surface of the semiconductor substrate may be referred to as an upper surface side. Similarly, a region from the center of the semiconductor substrate in the depth direction to the lower surface of the semiconductor substrate may be referred to as a lower surface side.

In the present specification, a case where a term such as “same” or “equal” is mentioned may include a case where an error due to a variation in manufacturing or the like is included. The error is, for example, within 10%.

In the present specification, a conductivity type of a doping region doped with impurities is described as a P type or an N type. In the present specification, the impurities may particularly mean either donors of the N type or acceptors of the P type, and may be described as dopants. In the present specification, doping means introducing the donor or the acceptor into the semiconductor substrate and turning it into a semiconductor presenting a conductivity type of the N type or a semiconductor presenting a conductivity type of the P type.

In the present specification, a doping concentration means a concentration of the donor or a concentration of the acceptor in a thermal equilibrium state. In the present specification, a net doping concentration means a net concentration obtained by adding the donor concentration set as a positive ion concentration to the acceptor concentration set as a negative ion concentration, taking into account of polarities of charges. As an example, when the donor concentration is N_{D} and the acceptor concentration is N_{A}, the net doping concentration at any position is given as N_{D}-N_{A}. In the present specification, the net doping concentration may be simply described as the doping concentration.

The donor has a function of supplying electrons to a semiconductor. The acceptor has a function of receiving electrons from the semiconductor. The donor and the acceptor are not limited to the impurities themselves. For example, a VOH defect in which a vacancy (V), oxygen (O), and hydrogen (H) present in the semiconductor are attached together functions as the donor which supplies the electrons. The hydrogen donor may be a donor obtained by the combination of at least a vacancy (V) and hydrogen (H). Alternatively, interstitial Si-H which is a combination of interstitial silicon (Si-i) and hydrogen in a silicon semiconductor also functions as the donor that supplies electrons. In the present specification, the VOH defect or interstitial Si-H may be referred to as a hydrogen donor.

In the semiconductor substrate in the present specification, bulk donors of the N type are distributed throughout. The bulk donor is a dopant donor substantially uniformly contained in an ingot during the manufacture of the ingot from which the semiconductor substrate is made. The bulk donor in this example is an element other than hydrogen. The bulk donor dopant is, for example, phosphorous, antimony, arsenic, selenium, or sulfur, but the invention is not limited to these. The bulk donor in this example is phosphorous. The bulk donor is also contained in a region of the P type. The semiconductor substrate may be a wafer cut out from a semiconductor ingot, or may be a chip obtained by singulating the wafer. The semiconductor ingot may be manufactured by either a Czochralski method (CZ method), a magnetic field applied Czochralski method (MCZ method), or a float zone method (FZ method). The ingot in this example is manufactured by the MCZ method. An oxygen concentration contained in the substrate manufactured by the MCZ method is 1×10¹⁷ to 7×10¹⁷/cm³. The oxygen concentration contained in the substrate manufactured by the FZ method is 1×10¹⁵ to 5×10¹⁶/cm³. When the oxygen concentration is high, hydrogen donors tend to be easily generated. The bulk donor concentration may use a chemical concentration of bulk donors distributed throughout the semiconductor substrate, or may be a value between 90% and 100% of the chemical concentration. In addition, as the semiconductor substrate, a non-doped substrate not containing a dopant such as phosphorous may be used. In that case, the bulk donor concentration (DO) of the non-doped substrate is, for example, from 1×10¹⁰/cm³ or more and to 5×10¹²/cm³ or less. The bulk donor concentration (DO) of the non-doped substrate is preferably 1×10¹¹/cm³ or more. The bulk donor concentration (DO) of the non-doped substrate is preferably 5×10¹²/cm³ or less. Each concentration in the present invention may be a value at room temperature. As an example, a value at 300K (Kelvin) (about 26.9 degrees C.) may be used as the value at room temperature.

In the present specification, a description of a P+ type or an N+ type means a higher doping concentration than that of the P type or the N type, and a description of a P− type or an N− type means a lower doping concentration than that of the P type or the N type. In addition, in the present specification, a description of a P++ type or an N++ type means a higher doping concentration than that of the P+ type or the N+ type. In the present specification, a unit system is the SI base unit system unless otherwise noted. Although a unit of length may be indicated by cm, it may be converted to meters (m) before calculations.

A chemical concentration in the present specification refers to an atomic density of an impurity measured regardless of an electrical activation state. The chemical concentration can be measured by, for example, secondary ion mass spectrometry (SIMS). The net doping concentration described above can be measured by capacitance-voltage profiling (CV method). In addition, a carrier concentration measured by spreading resistance profiling (SRP method) may be set as the net doping concentration. The carrier concentration measured by the CV method or the SRP method may be a value in a thermal equilibrium state. In addition, in a region of the N type, the donor concentration is sufficiently higher than the acceptor concentration, and thus the carrier concentration of the region may be set as the donor concentration. Similarly, in a region of the P type, the carrier concentration of the region may be set as the acceptor concentration. In the present specification, the doping concentration of the N type region may be referred to as the donor concentration, and the doping concentration of the P type region may be referred to as the acceptor concentration.

When a concentration distribution of the donor, acceptor, or net doping has a peak in a region, a value of the peak may be set as the concentration of the donor, acceptor, or net doping in the region. In a case where the concentration of the donor, acceptor or net doping is substantially uniform in a region, or the like, an average value of the concentration of the donor, acceptor or net doping in the region may be set as the concentration of the donor, acceptor or net doping. In the present specification, atoms/cm³ or/cm³ is used to indicate a concentration per unit volume. This unit is used for a concentration of a donor or an acceptor in a semiconductor substrate, or a chemical concentration. A notation of atoms may be omitted.

The carrier concentration measured by the SRP method may be lower than the concentration of the donor or the acceptor. In a range where a current flows when a spreading resistance is measured, carrier mobility of the semiconductor substrate may be lower than a value in a crystalline state. The decrease in the carrier mobility occurs when carriers are scattered due to disorder (disorder) of a crystal structure due to a lattice defect or the like.

The concentration of the donor or the acceptor calculated from the carrier concentration measured by the CV method or the SRP method may be lower than a chemical concentration of an element indicating the donor or the acceptor. As an example, in a silicon semiconductor, a donor concentration of phosphorous or arsenic serving as a donor, or an acceptor concentration of boron (boron) serving as an acceptor is approximately 99% of chemical concentrations of these. On the other hand, in the silicon semiconductor, a donor concentration of hydrogen serving as a donor is approximately 0.1% to 10% of a chemical concentration of hydrogen.

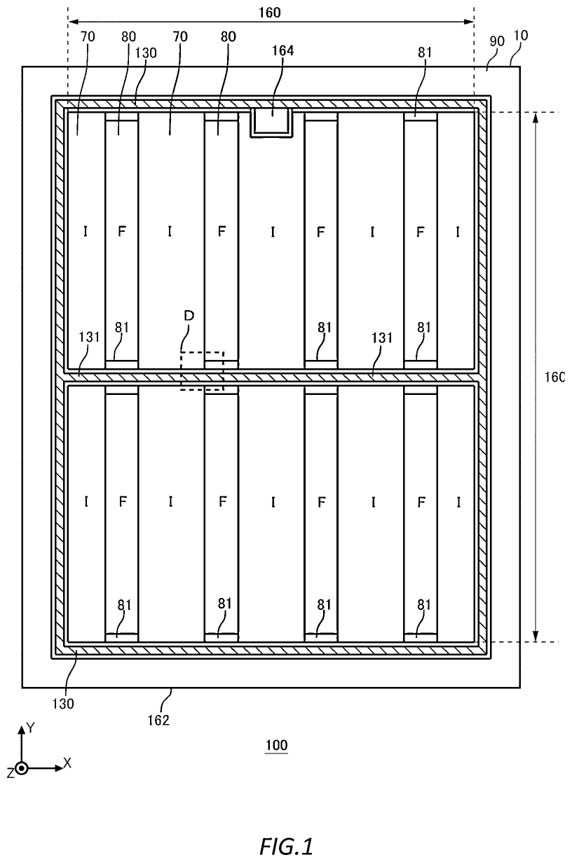

FIG. 1 is a top view illustrating an example of a semiconductor device 100 according to one embodiment of the present invention. FIG. 1 shows a position of each member projected onto an upper surface of a semiconductor substrate 10. FIG. 1 shows only some members of the semiconductor device 100, and illustration of some members is omitted.

The semiconductor device 100 includes the semiconductor substrate 10. The semiconductor substrate 10 is a substrate which is formed of a semiconductor material. As an example, the semiconductor substrate 10 is a silicon substrate. The semiconductor substrate 10 has an end side 162 in a top view. When simply referred to as the top view in the present specification, it means that the semiconductor substrate 10 is viewed from an upper surface side. The semiconductor substrate 10 in this example has two sets of end sides 162 opposite to each other in a top view. In FIG. 1, the X axis and the Y axis are parallel to any of the end sides 162. In addition, the Z axis is perpendicular to the upper surface of the semiconductor substrate 10.

The semiconductor substrate 10 is provided with an active portion 160. The active portion 160 is a region where a main current flows in a depth direction between the upper surface and a lower surface of the semiconductor substrate 10 when the semiconductor device 100 operates. An emitter electrode is provided above the active portion 160, but is omitted in FIG. 1. The active portion 160 may refer to a region that overlaps with the emitter electrode in the top view. In addition, a region sandwiched between active portions 160 in a top view may also be included in the active portion 160.

The active portion 160 is provided with a transistor portion 70 including a transistor element such as an insulated gate bipolar transistor (IGBT) and a diode portion 80 including a diode element such as a freewheeling diode (FWD). In the example in FIG. 1, each of the transistor portions 70 and each of the diode portions 80 are arranged alternately along a predetermined first direction (an X axis direction in the present example) on the upper surface of the semiconductor substrate 10. The semiconductor device 100 in this example is a reverse conduction type IGBT (RC-IGBT). A boundary region is arranged between the transistor portion 70 and the diode portion 80 in the X axis direction, but is omitted in FIG. 1.

In FIG. 1, a region where each of the transistor portions 70 is arranged is indicated by a symbol “I”, and a region where each of the diode portions 80 is arranged is indicated by a symbol “F”. In the present specification, a direction different from the first direction in the top view may be referred to as a second direction (the Y axis direction in FIG. 1). The second direction may be a direction perpendicular to the first direction. Each of the transistor portion 70 and the diode portion 80 may have a longitudinal length in the second direction. In other words, a length of the transistor portion 70 in the Y axis direction is larger than a width in the X axis direction. Similarly, a length of the diode portion 80 in the Y axis direction is larger than a width in the X axis direction. The second directions of the transistor portion 70 and the diode portion 80 may be the same as a longitudinal direction of each trench portion and a longitudinal direction of the mesa portions described below.

Each of the diode portions 80 includes a cathode region of an N+ type in a region in contact with the lower surface of the semiconductor substrate 10. In the present specification, a region where the cathode region is provided is referred to as the diode portion 80. In other words, the diode portion 80 is a region overlapping the cathode region in a top view. On the lower surface of the semiconductor substrate 10, a collector region of a P+ type may be provided in a region other than the cathode region. In the present specification, the diode portion 80 may also include an extension region 81 where the diode portion 80 extends to a gate runner described below in the Y axis direction. The collector region is provided on a lower surface of the extension region 81.

The transistor portion 70 has the collector region of the P+ type in a region in contact with the lower surface of the semiconductor substrate 10. In addition, in the transistor portion 70, an emitter region of an N type, a base region of the P type, and a gate structure having a gate conductive portion and a gate insulating film are periodically arranged on the upper surface side of the semiconductor substrate 10.

The semiconductor device 100 may include one or more pads above the semiconductor substrate 10. The semiconductor device 100 in this example has a gate pad 164. The semiconductor device 100 may have a pad such as an anode pad, a cathode pad, and a current detection pad. Each pad is arranged in a vicinity of the end side 162. The vicinity of the end side 162 refers to a region between the end side 162 and the emitter electrode in a top view. When the semiconductor device 100 is mounted, each pad may be connected to an external circuit via a wiring line such as a wire.

A gate potential is applied to the gate pad 164. The gate pad 164 is electrically connected to a conductive portion of a gate trench portion of the active portion 160. The semiconductor device 100 includes a gate runner that connects the gate pad 164 and the gate trench portion. In FIG. 1, the gate runner is hatched with diagonal lines.

The gate runner in this example has an outer circumferential gate runner 130 and an active-side gate runner 131. The outer circumferential gate runner 130 is arranged between the active portion 160 and the end side 162 of the semiconductor substrate 10 in a top view. The outer circumferential gate runner 130 in this example encloses the active portion 160 in a top view. A region enclosed by the outer circumferential gate runner 130 in a top view may be defined as the active portion 160. In addition, a well region is formed below the gate runner. The well region is a P type region having a higher concentration than the base region described below, and is formed from the upper surface of the semiconductor substrate 10 to a position deeper than that of the base region. A region enclosed by the well region in a top view may be defined as the active portion 160.

The outer circumferential gate runner 130 is connected to the gate pad 164. The outer circumferential gate runner 130 is arranged above the semiconductor substrate 10. The outer circumferential gate runner 130 may be a metal wiring containing aluminum or the like, or a wiring formed of a semiconductor such as polysilicon doped with an impurity.

The active-side gate runner 131 is provided in the active portion 160. Providing the active-side gate runner 131 in the active portion 160 can reduce a variation in a wiring line length from the gate pad 164 for each region of the semiconductor substrate 10.

The outer circumferential gate runner 130 and the active-side gate runner 131 are connected to the gate trench portion of the active portion 160. The outer circumferential gate runner 130 and the active-side gate runner 131 are arranged above the semiconductor substrate 10. The outer circumferential gate runner 130 and the active-side gate runner 131 may be a metal wiring containing aluminum or the like, or a wiring formed of a semiconductor such as polysilicon doped with an impurity.

The active-side gate runner 131 may be connected to the outer circumferential gate runner 130. The active-side gate runner 131 in this example is provided extending in the X axis direction so as to cross the active portion 160 substantially at the center of the Y axis direction from one outer circumferential gate runner 130 to another outer circumferential gate runner 130 which sandwich the active portion 160. When the active portion 160 is divided by the active-side gate runner 131, the transistor portions 70 and the diode portions 80 may be alternately arranged in the X axis direction in each divided region.

The semiconductor device 100 may include a temperature sensing portion (not shown) that is a PN junction diode formed of polysilicon or the like, and a current detection portion (not shown) that simulates an operation of the transistor portion provided in the active portion 160.

The semiconductor device 100 in this example includes an edge termination structure portion 90 between the active portion 160 and the end side 162 in a top view. The edge termination structure portion 90 in this example is arranged between the outer circumferential gate runner 130 and the end side 162. The edge termination structure portion 90 reduces electric field strength on the upper surface side of the semiconductor substrate 10. The edge termination structure portion 90 may include at least one of a guard ring, a field plate, and a RESURF which are annularly provided enclosing the active portion 160.

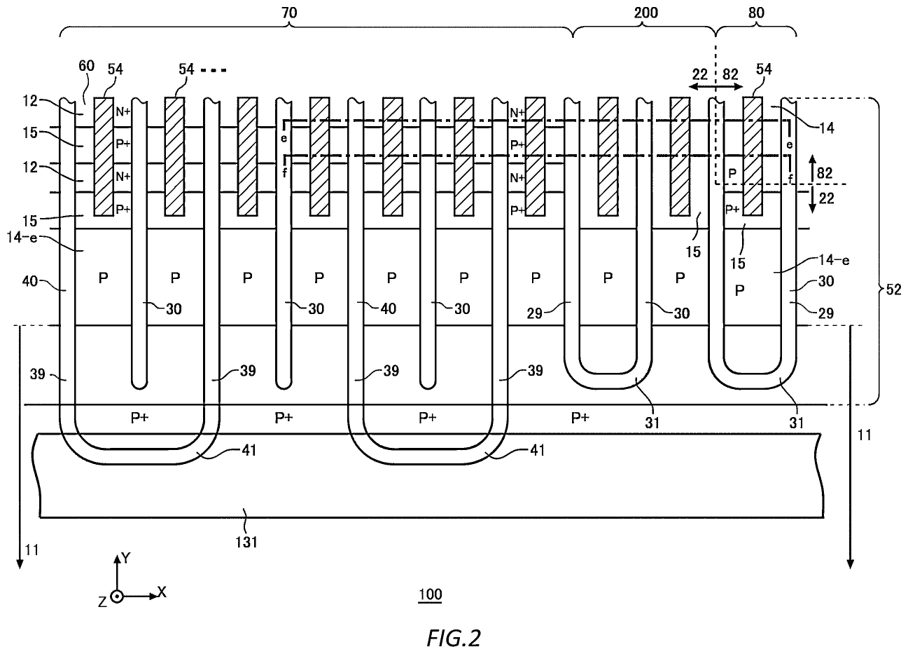

FIG. 2 illustrates an enlarged view of a region D in FIG. 1. The region D is a region including a transistor portion 70, a diode portion 80, and an active-side gate runner 131. Although omitted in FIG. 1, a boundary region 200 is arranged between the transistor portion 70 and the diode portion 80 in the X axis direction. A semiconductor device 100 in this example includes a gate trench portion 40, a dummy trench portion 30, a well region 11, an emitter region 12, a base region 14, and a contact region 15 which are provided inside the upper surface side of a semiconductor substrate 10. The gate trench portion 40 and the dummy trench portion 30 are each one example of a trench portion. In addition, the semiconductor device 100 in this example includes an emitter electrode 52 and the active-side gate runner 131 that are provided on or above the upper surface of the semiconductor substrate 10. The emitter electrode 52 is an example of a metal electrode. The emitter electrode 52 and the active-side gate runner 131 are provided in isolation from each other.

An interlayer insulating film is provided between the emitter electrode 52 and the active-side gate runner 131, and the upper surface of the semiconductor substrate 10, but the interlayer insulating film is omitted in FIG. 2. In the interlayer insulating film in this example, a contact hole 54 is provided penetrating the interlayer insulating film. In FIG. 2, each contact hole 54 is hatched with the diagonal lines.

The emitter electrode 52 is provided above the gate trench portion 40, the dummy trench portion 30, the well region 11, the emitter region 12, the base region 14, and the contact region 15. The emitter electrode 52 is in contact with the emitter region 12, the contact region 15, and the base region 14 at the upper surface of the semiconductor substrate 10, through the contact hole 54. In addition, the emitter electrode 52 is connected to a dummy conductive portion in the dummy trench portion 30 through the contact hole provided in the interlayer insulating film. The emitter electrode 52 may be connected to the dummy conductive portion of the dummy trench portion 30 at an edge of the dummy trench portion 30 in the Y axis direction. The dummy conductive portion of the dummy trench portion 30 may not be connected to the emitter electrode 52 and a gate conductive portion, and may be controlled to be at potential different from potential of the emitter electrode 52 and potential of the gate conductive portion.

The active-side gate runner 131 is connected to the gate trench portion 40 through the contact hole provided in the interlayer insulating film. The active-side gate runner 131 may be connected to a gate conductive portion of the gate trench portion 40 at an edge portion 41 of the gate trench portion 40 in the Y axis direction. The active-side gate runner 131 is not connected to the dummy conductive portion in the dummy trench portion 30.

The emitter electrode 52 is formed of a material including a metal. FIG. 2 shows a range where the emitter electrode 52 is provided. For example, at least a part of a region of the emitter electrode 52 is formed of aluminum or an aluminum-silicon alloy, for example, a metal alloy such as AlSi, AlSiCu. The emitter electrode 52 may have a barrier metal formed of titanium, a titanium compound, or the like below a region formed of aluminum or the like. Further, a plug portion, which is formed by embedding tungsten or the like so as to be in contact with the barrier metal and aluminum or the like, may be included in the contact hole.

The well region 11 is provided overlapping the active-side gate runner 131. The well region 11 is provided so as to extend with a predetermined width even in a range not overlapping the active-side gate runner 131. The well region 11 in this example is provided away from an end of the contact hole 54 in the Y axis direction toward the active-side gate runner 131 side. The well region 11 is a region of a second conductivity type having a higher doping concentration than the base region 14. The base region 14 of this example is a P type, and the well region 11 is a P+ type.

Each of the transistor portion 70, the diode portion 80, and the boundary region 200 includes a plurality of trench portions arranged in the first direction. In the transistor portion 70 of this example, one or more gate trench portions 40 and one or more dummy trench portions 30 are alternately provided along the first direction. In the diode portion 80 of this example, the plurality of dummy trench portions 30 are provided along the first direction. In the diode portion 80 in this example, the gate trench portion 40 is not provided. In the boundary region 200 of this example, the plurality of dummy trench portions 30 are provided along the first direction. In the boundary region 200 of this example, the gate trench portion 40 is not provided.

The gate trench portion 40 of this example may have two linear portions 39 extending along the second direction perpendicular to the first direction (portions of a trench that are linear along the second direction), and the edge portion 41 connecting the two linear portions 39. The second direction in FIG. 2 is the Y axis direction.

At least a part of the edge portion 41 is preferably provided in a curved shape in a top view. By connecting between end portions of the two linear portions 39 in the Y axis direction by the edge portion 41, it is possible to reduce the electric field strength at the end portions of the linear portions 39.

In the transistor portion 70, the dummy trench portions 30 are provided between the respective linear portions 39 of the gate trench portions 40. Between the respective linear portions 39, one dummy trench portion 30 may be provided, or a plurality of dummy trench portions 30 may be provided. The dummy trench portion 30 may have a linear shape extending in the second direction, or may have linear portions 29 and an edge portion 31 similar to the gate trench portion 40. The semiconductor device 100 shown in FIG. 2 includes both of the linear dummy trench portion 30 having no edge portion 31, and the dummy trench portion 30 having the edge portion 31.

A diffusion depth of the well region 11 may be deeper than the depth of the gate trench portion 40 and the dummy trench portion 30. The end portions in the Y axis direction of the gate trench portion 40 and the dummy trench portion 30 are provided in the well region 11 in a top view. In other words, the bottom portion in a depth direction of each trench portion is covered with the well region 11 at the end portion in the Y axis direction of each trench portion. With this configuration, the electric field strength on the bottom portion of each trench portion can be reduced.

A mesa portion 60 is provided between the respective trench portions in the first direction. The mesa portion 60 refers to a region sandwiched between the trench portions inside the semiconductor substrate 10. As an example, an upper end of the mesa portion 60 is the upper surface of the semiconductor substrate 10. A depth position of a lower end of the mesa portion 60 is the same as a depth position of a lower end of the trench portion. The mesa portion 60 of this example is provided extending in the second direction (the Y axis direction) along the trench, on the upper surface of the semiconductor substrate 10. The mesa portion 60 of the transistor portion 70, the mesa portion 60 of the diode portion 80 and the mesa portion 60 of the boundary region 200 may have different structures. When merely referring to the mesa portion 60 in the present specification, it refers to each of the mesa portion 60 of the transistor portion 70, the mesa portion 60 of the diode portion 80 and the mesa portion 60 of the boundary region 200.

In each mesa portion 60, the base region 14 is provided. In the mesa portion 60, a region arranged closest to the active-side gate runner 131, in the base region 14 exposed on the upper surface of the semiconductor substrate 10, is defined as a base region 14-e. While FIG. 2 shows the base region 14-e arranged at one end portion of each mesa portion in the second direction, the base region 14-e is also arranged at the other end portion of each mesa portion.

Each mesa portion may be provided with at least one of the emitter region 12 of a first conductivity type, and the contact region 15 of the second conductivity type in a region sandwiched between the base regions 14-e in a top view. The emitter region 12 in this example is the N+ type, and the contact region 15 is the P+ type. The emitter region 12 and the contact region 15 may be provided between the base region 14 and the upper surface of the semiconductor substrate 10 in the depth direction.

The mesa portion 60 of the transistor portion 70 has the emitter regions 12 exposed on the upper surface of the semiconductor substrate 10. The emitter region 12 is provided in contact with the gate trench portion 40. The mesa portion 60 in contact with the gate trench portion 40 may be provided with the contact region 15 exposed on the upper surface of the semiconductor substrate 10.

Each of the contact region 15 and the emitter region 12 in the mesa portion 60 is provided from one trench portion to another trench portion in the X axis direction. As an example, the contact region 15 and the emitter region 12 of the mesa portion 60 are alternately arranged along the second direction of the trench portion (the Y axis direction).

In another example, the contact region 15 and the emitter region 12 of the mesa portion 60 may be provided in a stripe pattern along the second direction of the trench portion (the Y axis direction). For example, the emitter region 12 is provided in a region in contact with the trench portion, and the contact region 15 is provided in a region sandwiched between the emitter regions 12.

The mesa portion 60 of the diode portion 80 and the boundary region 200 is not provided with the emitter region 12. The base region 14 and the contact region 15 may be provided on an upper surface of the mesa portion 60 of the diode portion 80 and the boundary region 200. In the region sandwiched between the base regions 14-e at the upper surface of the mesa portion 60, the contact region 15 may be provided in contact with each of the base regions 14-e. The base region 14 may be provided in a region interposed between the contact regions 15 on the upper surface of the mesa portion 60 of the diode portion 80. The base region 14 may be arranged in the entire region sandwiched between the contact regions 15. The mesa portion 60 of the boundary region 200 may have a structure identical to or different from that of the mesa portion 60 of the diode portion 80. The mesa portion 60 of the boundary region 200 in the present example is provided with a contact region 15 over the entire region sandwiched by the base regions 14-e. That is, the area of the contact region 15 of the mesa portion 60 of the boundary region 200 may be greater than the area of the contact region 15 of the mesa portion 60 of the diode portion 80. In this case, it is easier to extract holes in the semiconductor substrate 10 via the mesa portion 60 of the boundary region 200 to the emitter electrode 52.

In another example, the mesa portion 60 of the boundary region 200 may be a P type impurity region with the same degree or lower doping concentration than that of the base region 14 of the transistor portion 70. The P type impurity region may occupy the entire mesa portion 60 of the boundary region 200, and other regions may be provided in the mesa portion 60 of the boundary region 200. By providing a P type impurity region with a lower doping concentration in the mesa portion 60 of the boundary region 200 than that in the base region 14, hole implantation from the mesa portion 60 of the boundary region 200 can be suppressed and the reverse recovery loss can be reduced.

The mesa portion 60 of the boundary region 200 may have an N type impurity region provided with the same degree or lower doping concentration than that of the emitter region 12. Note that in that case, the boundary region 200 is not provided with the gate trench portion 40. Moreover, the trench portion at the boundary position between the transistor portion 70 and the boundary region 200 is the dummy trench portion 30. Because the mesa portion 60 of the boundary region 200 does not have the N type impurity region in direct contact with the gate trench portion 40, no more current flows in the boundary region 200 than in the transistor portion 70. This allows suppressing the implantation of holes from the mesa portion 60 of the boundary region 200 and reducing the reverse recovery loss.

Above each mesa portion 60, the contact hole 54 is provided. The contact hole 54 is arranged in the region sandwiched between the base regions 14-e. The contact hole 54 in this example is provided above respective regions of the contact region 15, the base region 14, and the emitter region 12. The contact hole 54 is not provided in regions corresponding to the base region 14-e and the well region 11. The contact hole 54 may be arranged at the center of the mesa portion 60 in the first direction (the X axis direction).

In the diode portion 80, a cathode region 82 of the N+ type is provided in a region in direct contact with the lower surface of the semiconductor substrate 10. On the lower surface of the semiconductor substrate 10, a collector region of the P+ type 22 may be provided in a region where the cathode region 82 is not provided. The cathode region 82 and a collector region 22 are provided between a lower surface 23 of the semiconductor substrate 10 and a buffer region 20. In FIG. 2, a boundary between the cathode region 82 and the collector region 22 is indicated by a dotted line.

The cathode region 82 is arranged away from the well region 11 in the Y axis direction. With this configuration, the distance between a region of a P type (the well region 11) having a comparatively high doping concentration and formed up to the deep position, and the cathode region 82 is ensured, so that the breakdown voltage can be improved. The end portion in the Y axis direction of the cathode region 82 in this example is arranged farther away from the well region 11 than the end portion in the Y axis direction of the contact hole 54. In another example, the end portion in the Y axis direction of the cathode region 82 may be arranged between the well region 11 and the contact hole 54.

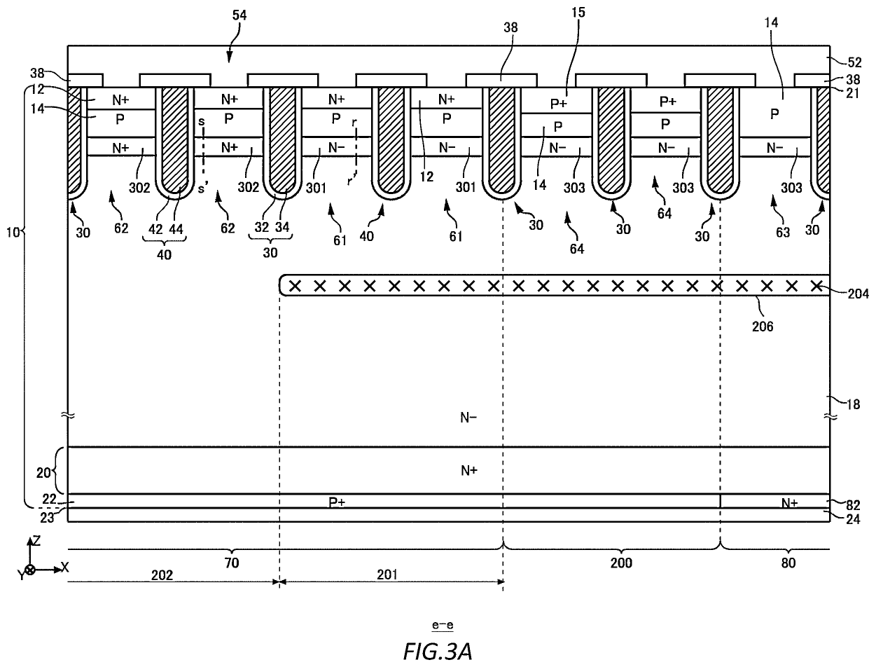

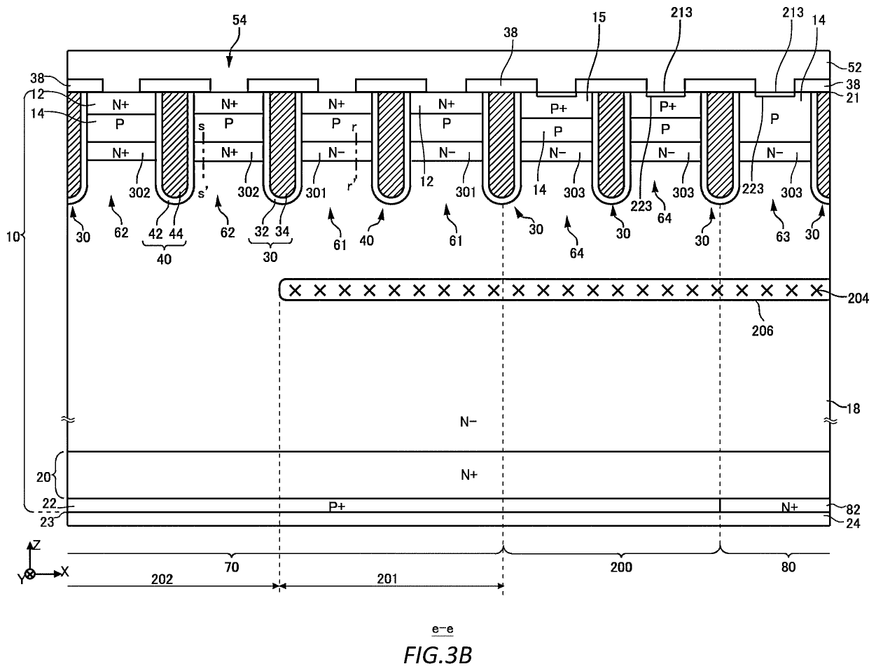

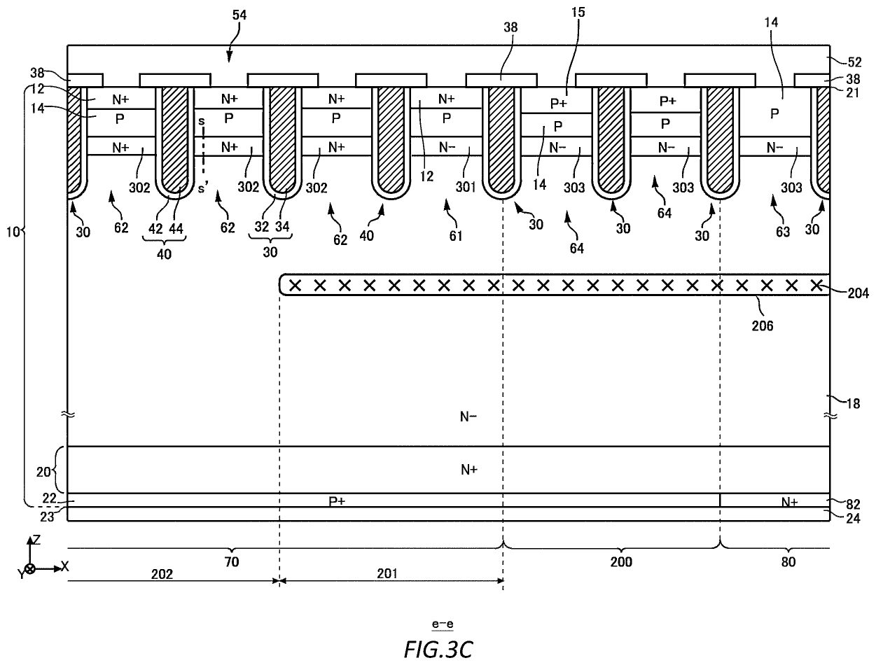

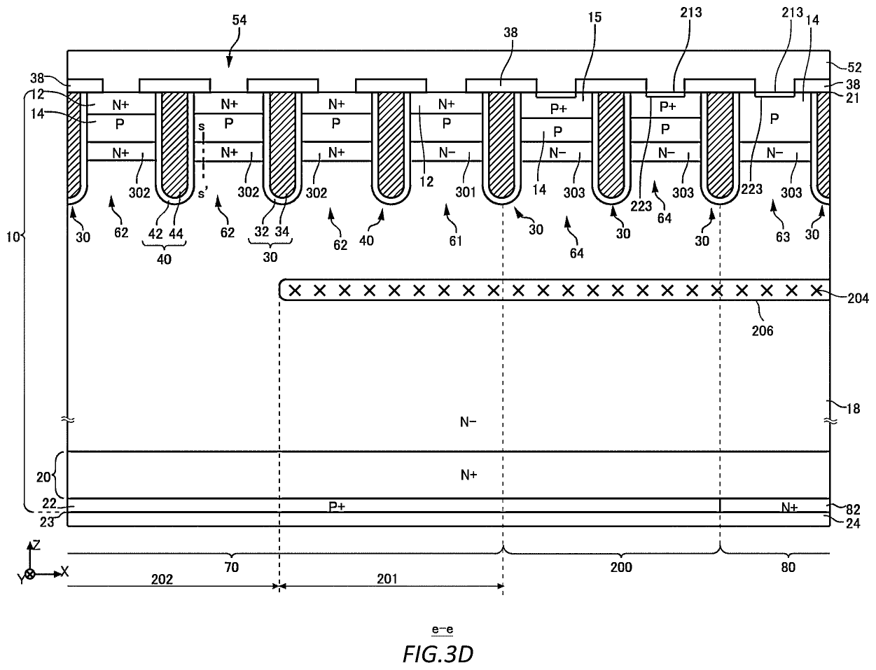

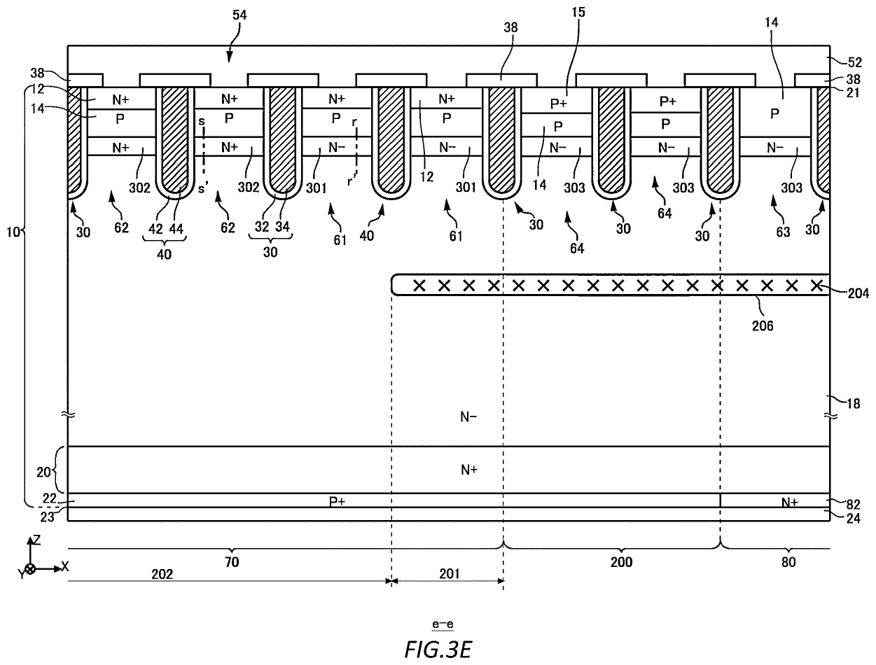

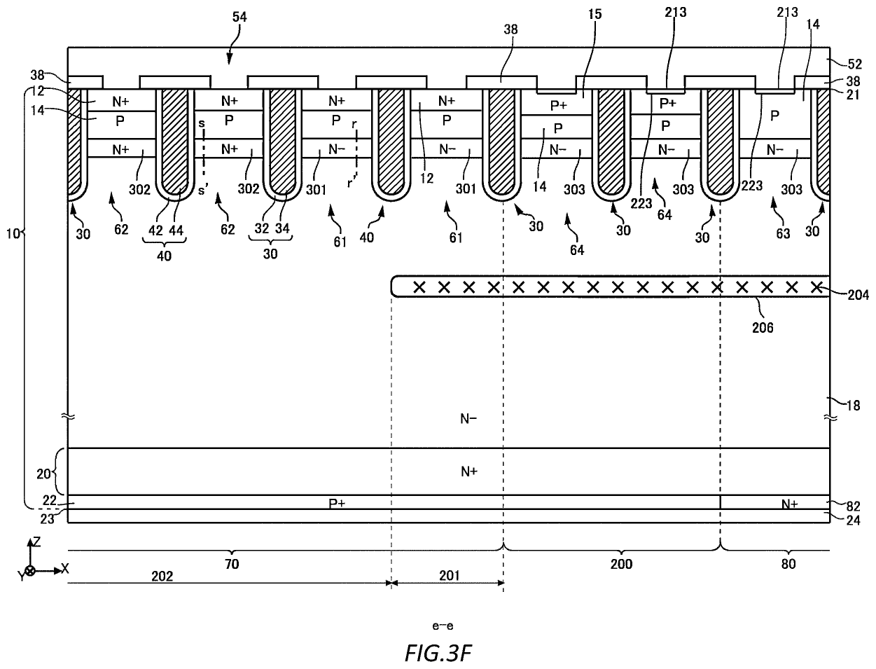

FIG. 3A illustrates a view showing an example of a cross section e-e in FIG. 2. The cross section e-e is the XZ plane passing through an emitter region 12 and a cathode region 82. A semiconductor device 100 in this example includes a semiconductor substrate 10, an interlayer insulating film 38, an emitter electrode 52, and a collector electrode 24 in the cross section.

The interlayer insulating film 38 is provided on the upper surface of the semiconductor substrate 10. The interlayer insulating film 38 is a film including at least one layer of an insulating film such as silicate glass to which an impurity such as boron or phosphorous is added, a thermal oxide film, and other insulating films. The interlayer insulating film 38 is provided with a contact hole 54 described with reference to FIG. 2.

The emitter electrode 52 is provided above the interlayer insulating film 38. The emitter electrode 52 is in contact with an upper surface 21 of the semiconductor substrate 10 through the contact hole 54 of the interlayer insulating film 38. The collector electrode 24 is provided on a lower surface 23 of the semiconductor substrate 10. The emitter electrode 52 and the collector electrode 24 are formed of a metal material such as aluminum. In the present specification, a direction in which the emitter electrode 52 and the collector electrode 24 are connected to each other (Z axis direction) is referred to as the depth direction. The emitter electrode 52 may have a barrier metal containing titanium in the portion in direct contact with the upper surface 21 of the semiconductor substrate 10. The barrier metal may have a titanium nitride layer, or may have a stacked structure of a titanium nitride layer and a titanium layer. The emitter electrode 52 may have a plug portion such as tungsten filled inside the contact hole 54.

The plug portion may also be provided in the trench contact portion described below. The semiconductor substrate 10 includes a drift region 18 of an N type or an N− type. The drift region 18 is provided in each of the transistor portion 70, the diode portion 80, and the boundary region 200.

In the present example, the plurality of mesa portions 60 include one or more first mesa portions 61, one or more second mesa portions 62, one or more third mesa portions 63, and one or more fourth mesa portions 64. The first mesa portion 61 and the second mesa portion 62 are provided in the transistor portion 70, the third mesa portion 63 is provided in the diode portion 80, and the fourth mesa portion 64 is provided in the boundary region 200. The second mesa portion 62 is arranged further away from the diode portion 80 than the first mesa portion 61.

In the first mesa portion 61 and the second mesa portion 62 of the transistor portion 70, the emitter region 12 of the N+ type and the base region 14 of the P type are provided in sequence from the upper surface 21 side of the semiconductor substrate 10. The drift region 18 is provided below the base region 14.

The emitter region 12 is exposed on the upper surface 21 of the semiconductor substrate 10 and is provided in contact with a gate trench portion 40. The emitter region 12 may be in contact with the trench portions on both sides of the mesa portion 60. The emitter region 12 has a higher doping concentration than the drift region 18.

The base region 14 is provided below the emitter region 12. The base region 14 in this example is provided in contact with the emitter region 12. The base region 14 may be in contact with the trench portions on both sides of the first mesa portion 61 and the second mesa portion 62.

The third mesa portion 63 of the diode portion 80 is provided with the P type of base region 14 in contact with the upper surface 21 of the semiconductor substrate 10. In the present specification, the base region 14 of the third mesa portion 63 may be referred to as an anode region. The doping concentration of the base region 14 of the third mesa portion 63 may be the same as, or may be lower than the doping concentration of the base regions 14 of the first mesa portion 61 and the second mesa portion 62. The drift region 18 is provided below the base region 14.

In the fourth mesa portion 64 of the boundary region 200 in the present example, a contact region 15 of the P+ type is provided to be in direct contact with the upper surface 21 of the semiconductor substrate 10. The drift region 18 is provided below the contact region 15. The base region 14 may be provided between the contact region 15 and the drift region 18.

In each of the transistor portion 70, the diode portion 80, and the boundary region 200, an N+ type buffer region 20 may be provided below the drift region 18. The doping concentration of the buffer region 20 is higher than the doping concentration of the drift region 18. The buffer region 20 may have a concentration peak having a higher doping concentration than the doping concentration of the drift region 18. The doping concentration of the concentration peak refers to a doping concentration at the local maximum of the concentration peak. In addition, as the doping concentration of the drift region 18, an average value of doping concentrations in the region where the doping concentration distribution is substantially flat may be used.

The buffer region 20 in this example may have two or more concentration peaks in the depth direction (the Z axis direction) of the semiconductor substrate 10. The concentration peak of the buffer region 20 may be provided at the same depth position as, for example, a chemical concentration peak of hydrogen (a proton) or phosphorous. The buffer region 20 may function as a field stopper layer which prevents a depletion layer expanding from the lower end of the base region 14 from reaching the collector region 22 of a P+ type and the cathode region 82 of the N+ type.

In the transistor portion 70, the collector region 22 of the P+ type is provided below the buffer region 20. An acceptor concentration of the collector region 22 is higher than an acceptor concentration of the base region 14. The collector region 22 may include an acceptor which is the same as or different from an acceptor of the base region 14. The acceptor of the collector region 22 is, for example, boron.

Below the buffer region 20 in the diode portion 80, the cathode region 82 of the N+ type is provided. A donor concentration of the cathode region 82 is higher than a donor concentration of the drift region 18. A donor of the cathode region 82 is, for example, hydrogen or phosphorous. Note that an element serving as a donor and an acceptor in each region is not limited to the example described above.

In the boundary region 200, the collector region 22 of the P+ type is provided below the buffer region 20. The collector region 22 of the boundary region 200 may have the same doping concentration as the collector region 22 of the transistor portion 70. The boundary position between the cathode region 82 and the collector region 22 in the X axis direction may be regarded as the boundary position between the diode portion 80 and the boundary region 200 in the X axis direction. In another example, in the boundary region 200, a part or the entire collector region 22 may be replaced to the cathode region 82. When the cathode region 82 is provided on the lower surface of the boundary region 200, the region where the contact regions 15 and the base regions 14 are alternately arranged in the region sandwiched between the base regions 14-e may be regarded as the diode portion 80, and the region where the contact regions 15 are arranged in the entire region sandwiched between the base regions 14-e may be regarded as the boundary region 200. When the cathode region 82 is provided on the lower surface of the boundary region 200, the boundary region 200 may be regarded as a part of the diode portion 80.

Among the gate trench portions 40 in direct contact with the emitter regions 12, the gate trench portion 40 arranged closest to the diode portion 80 in the X axis direction is regarded as the boundary position between the transistor portion 70 and the boundary region 200 (or the diode portion 80) in the X axis direction. The center position of the gate trench portion 40 in the X axis direction may be regarded as the boundary position between the transistor portion 70 and the boundary region 200 (or the diode portion 80) in the X axis direction. Of the two trench portions in contact with the emitter region 12 arranged closest to the diode portion 80 in the X axis direction, the trench portion on the diode portion 80 side may be the dummy trench portion 30. In this case, the dummy trench portion 30 may be regarded as the boundary position between the transistor portion 70 and the boundary region 200 (or the diode portion 80) in the X axis direction.

The boundary region 200 may alternatively be provided with the emitter region 12. Note that in that case, the boundary region 200 is not provided with the gate trench portion 40. Moreover, the trench portion at the boundary position between the transistor portion 70 and the boundary region 200 is the dummy trench portion 30. In other words, transistor operations do not occur in the boundary region 200. The boundary region 200 may alternatively be provided with the gate trench portion 40. Note that in that case, the boundary region 200 is not provided with the emitter region 12. In other words, transistor operations do not occur in the boundary region 200.

The collector region 22 and the cathode region 82 are exposed on the lower surface 23 of the semiconductor substrate 10 and are connected to the collector electrode 24. The collector electrode 24 may be in contact with the entire lower surface 23 of the semiconductor substrate 10. The emitter electrode 52 and the collector electrode 24 are formed of a metal material such as aluminum.

One or more gate trench portions 40 and one or more dummy trench portions 30 are provided on the upper surface 21 side of the semiconductor substrate 10. Each trench portion is provided from the upper surface 21 of the semiconductor substrate 10 to a region below the base region 14, penetrating the base region 14. In a region where at least any of the emitter region 12 or a contact region 15 is provided, each trench portion also penetrates these doping regions. A configuration in which a trench portion penetrates a doping region is not limited to a configuration which is manufactured by forming a doping region and forming a trench portion in this order. The configuration of the trench portion penetrating the doping region includes a configuration of the doping region being formed between the trench portions after forming the trench portion.

As described above, the transistor portion 70 is provided with the gate trench portion 40 and a dummy trench portion 30. The diode portion 80 and the boundary region 200 of this example are provided with the dummy trench portion 30, and are not provided with the gate trench portion 40. Note that the gate trench portion 40 may be arranged or the dummy trench portion 30 may be arranged at the boundary between the boundary region 200 and the transistor portion 70.

The boundary region 200 is a buffering structure for arranging different structures of the transistor portion 70 and the diode portion 80 side by side. Therefore, the width of the boundary region 200 in the X axis direction may be short. For example, in the boundary region 200, one or more fourth mesa portions 64 may be provided, and the boundary region 200 may not be provided.

The boundary region 200 may include a plurality of fourth mesa portions 64 in the X axis direction. This allows the effects of the transistor portion 70 on the characteristics of the diode portion 80, for example, the effects of the operation of the gate trench portion 40 and the discharge or implantation of holes in the contact region 15, on the forward voltage and reverse recovery characteristics, to be suppressed. The number of mesa portions refers to the number of mesa portions arranged side by side in the X axis direction.

The gate trench portion 40 includes a gate trench provided in the upper surface 21 of the semiconductor substrate 10, a gate insulating film 42, and a gate conductive portion 44. The gate insulating film 42 is provided covering an inner wall of the gate trench. The gate insulating film 42 may be formed by oxidizing or nitriding a semiconductor on the inner wall of the gate trench.

The gate conductive portion 44 is provided farther inward inside the gate trench than the gate insulating film 42. That is, the gate insulating film 42 insulates the gate conductive portion 44 from the semiconductor substrate 10. The gate conductive portion 44 is formed of a conductive material such as polysilicon.

The gate conductive portion 44 may be provided longer than the base region 14 in the depth direction. The gate trench portion 40 in the cross section is covered with the interlayer insulating film 38 on the upper surface 21 of the semiconductor substrate 10. The gate conductive portion 44 is electrically connected to the gate runner. When a predetermined gate voltage is applied to the gate conductive portion 44, a channel is formed by an electron inversion layer in a surface layer of the base region 14 at a boundary in contact with the gate trench portion 40.

The dummy trench portions 30 may have the same structure as the gate trench portions 40 in the cross section. The dummy trench portion 30 includes a dummy trench provided in the upper surface 21 of the semiconductor substrate 10, a dummy insulating film 32, and a dummy conductive portion 34. The dummy conductive portion 34 is electrically connected to the emitter electrode 52. The dummy insulating film 32 is provided covering an inner wall of the dummy trench. The dummy conductive portion 34 is provided in the dummy trench, and is provided farther inward than the dummy insulating film 32. The dummy insulating film 32 insulates the dummy conductive portion 34 from the semiconductor substrate 10. The dummy conductive portion 34 may be formed of the same material as the gate conductive portion 44. For example, the dummy conductive portion 34 is formed of a conductive material such as polysilicon or the like. The dummy conductive portion 34 may have the same length as the gate conductive portion 44 in the depth direction.

The gate trench portion 40 and the dummy trench portion 30 in this example are covered with the interlayer insulating film 38 on the upper surface 21 of the semiconductor substrate 10. Note that the bottom portions of the dummy trench portion 30 and the gate trench portion 40 may be formed in a curved-surface shape (a curved shape in the cross section) convexly downward.

The semiconductor device 100 of this example includes a lifetime adjustment region 206 containing a lifetime killer that adjusts a lifetime of carriers. The lifetime adjustment region 206 of this example is a region where a lifetime of charge carriers is locally small. The charge carriers are electrons or holes. The charge carriers may be simply referred to as carriers. The lifetime adjustment region 206 in the present example is formed by implanting charged particles such as helium ions from the upper surface 21 side of the semiconductor substrate 10. In the present example, the concentration distribution of helium or the like in the depth direction of the semiconductor substrate 10 may have a tapered shape from the lifetime adjustment region 206 to the upper surface 21 of the semiconductor substrate 10. That is, from the lifetime adjustment region 206 to the upper surface 21, the concentration (/cm3) of helium or the like may decrease monotonously. The concentration of helium or the like in the upper surface 21 may be greater than 0. On the other hand, in a direction from the lifetime adjustment region 206 toward the lower surface 23, the concentration of helium or the like may have a tapered shape. However, the tapering toward the lower surface 23 drops more steeply in concentration of helium or the like than the tapering toward the upper surface 21. The concentration of helium or the like in the lower surface 23 is lower than the concentration of helium or the like in the upper surface 21. The concentration of helium or the like in the upper surface 21 may be equal to a measurement limit or less, or may be 0. The lifetime adjustment region 206 may be formed by implanting charged particles of helium ions or the like from the lower surface 23 side of the semiconductor substrate 10.

By implanting charged particles such as helium ions into the semiconductor substrate 10, the lattice defects 204 such as vacancies are formed in the vicinity of the implanting position. The lattice defects 204 generate recombination centers. The lattice defects 204 may be mainly composed of vacancies such as monatomic vacancies (V) or diatomic divacancy (VV), may be dislocations, may be interstitial atoms, or may be transition metals or the like. For example, atoms adjacent to the vacancies have dangling bonds. In a broad sense, the lattice defects 204 may also include donors and acceptors, but in the present specification, the lattice defects 204 mainly composed of vacancies may be referred to as vacancy type lattice defects, vacancy type defects, or simply lattice defects. In the present specification, the lattice defects 204 may be simply referred to as recombination centers or lifetime killers as recombination centers contributing to recombination of carriers. The lifetime killers may be formed by implanting helium ions into the semiconductor substrate 10. The helium chemical concentration may be regarded as the density of the lattice defects 204. Note that since the lifetime killer formed by implanting helium ions may be terminated by hydrogen existing in the buffer region 20, the depth position of the density peak of the lifetime killer may not be identical to the depth position of the helium chemical concentration peak. In addition, when implanting hydrogen ions into the semiconductor substrate 10, the lifetime killer may be formed in a passed-through region of hydrogen ions that is more on the implantation surface side than the projected range.

The lattice defect 204 is an example of the lifetime killer. In FIG. 3A, the lattice defects 204 at the implanting position of the charged particles are schematically indicated by X marks. In a region where many lattice defects 204 remain, the carriers are captured by the lattice defects 204, and thus the lifetime of the carriers is shortened. By adjusting the lifetime of carriers, characteristics of the diode portion 80 such as a reverse recovery time and a reverse recovery loss can be adjusted. A position at which the carrier lifetime shows a local minimum value in the depth direction of the semiconductor substrate 10 may be set as the depth position of the lifetime adjustment region 206.

The lifetime adjustment region 206 is arranged in the upper surface 21 side of the semiconductor substrate 10. The upper surface 21 side is a region from a center position of the semiconductor substrate 10 in the depth direction to the upper surface 21 of the semiconductor substrate 10. The lifetime adjustment region 206 of this example is arranged below the lower end of the trench portion.

When the lifetime adjustment region 206 is formed by irradiation of particle beams with high penetrating power such as electron beams, lattice defects are formed substantially uniformly from the upper surface 21 to the lower surface 23 of the semiconductor substrate 10. In this case, the depth position of the lifetime adjustment region 206 may be regarded as being arranged on the upper surface 21 side of the semiconductor substrate 10.

The lifetime adjustment region 206 is provided in the diode portion 80. When the semiconductor device 100 has the boundary region 200, the boundary region 200 may also have the lifetime adjustment region 206 provided therein. The lifetime adjustment region 206 may be provided across the entire diode portion 80 in the X axis direction. The lifetime adjustment region 206 is provided over the entire boundary region 200.

The lifetime adjustment region 206 of the diode portion 80 is provided to extend to a part of the transistor portion 70 in the X axis direction. The lifetime adjustment region 206 of the diode portion 80 is provided at the same depth position as the lifetime adjustment region 206 of the transistor portion 70. In the transistor portion 70, the region with the lifetime adjustment region 206 provided therein is regarded as an adjustment region 201, and the region without the lifetime adjustment region 206 provided therein is regarded as a non-adjustment region 202. The adjustment region 201 is a region overlapping the lifetime adjustment region 206 in the top view. The non-adjustment region 202 is a region not overlapping the lifetime adjustment region 206 in the top view. The non-adjustment region 202 is a region where the carrier lifetime at the same depth position as the lifetime adjustment region 206 is longer than the carrier lifetime of the lifetime adjustment region 206 of the diode portion 80. The non-adjustment region 202 may be a region where the charged particles such as helium ions or the like, for forming the lifetime killer such as the lattice defect 204, are not implanted. The chemical concentration (/cm3) of helium or the like in the non-adjustment region 202 may be the same as the chemical concentration of the charged particles in the center of the drift region 18 in the Z axis direction.

The adjustment region 201 has one or more first mesa portions 61. The lifetime adjustment region 206 extends from a region below the diode portion 80 to a region below the first mesa portion 61. All the mesa portions 60 of the adjustment region 201 may be the first mesa portions 61. The non-adjustment region 202 has one or more second mesa portions 62. All the mesa portions 60 of the non-adjustment region 202 may be the second mesa portions 62. The diode portion 80 has one or more third mesa portions 63. All the mesa portions 60 of the diode portion 80 may be the third mesa portions 63. The boundary region 200 has one or more fourth mesa portions 64. All the mesa portions 60 of the boundary region 200 may be the fourth mesa portions 64.

The first mesa portion 61 has a first region 301 of the N− type provided in at least a part of a region between the depth position of the lower end of the base region 14 and the depth position of the lower end of the trench portion of the gate trench portion 40 or the like. In the present specification, the depth position of the lower end of the base region 14 may be referred to as Z14, and the depth position of the lower end of the trench portion may be referred to as Zt. The first region 301 may be provided over the entire region between the depth position Z14 and the depth position Zt.

The second mesa portion 62 has a second region 302 of the N+ type provided between the depth position Z14 and the depth position Zt. The second region 302 may be provided over the entire region between the depth position Z14 and the depth position Zt. The second region 302 is a region with a doping concentration higher than that of the first region 301. The first region 301 and the second region 302 may be provided throughout each mesa portion in the X axis direction. The first region 301 and the second region 302 may be provided to cover the entire lower surface of the base region 14 of each mesa portion.

The dose amount (/cm²) of N type dopants in the second region 302 is greater than the dose amount of N type dopants in the first region 301. The dose amount of each region may use a value obtained by integrating the doping concentration of each region over a predetermined region in the depth direction.

The predetermined region may be a region of the N type with a doping concentration higher than that of the drift region 18 between the base region 14 and the drift region 18. The predetermined region may be a range of the full width at half maximum of a peak of the N type doping concentration between the base region 14 and the drift region 18. The second region 302 in the present example is a region with a doping concentration higher than that of the drift region 18. By providing the second region 302 having the high concentration between the drift region 18 and the base region 14, it is possible to improve a carrier implantation enhancement effect (IE effect) and reduce an ON voltage. The doping concentration of the second region 302 may be 10 times or greater, or 50 times or greater, or 100 times or greater than the doping concentration of the drift region 18.

The doping concentration of the first region 301 in the present example is equal to or greater than the doping concentration of the drift region 18, and less than the doping concentration of the second region 302. The value of the doping concentration of each region may use a peak value. The doping concentration of the first region 301 may be the same as the doping concentration of the drift region 18. That is, the drift region 18 provided in the first mesa portion 61 may be regarded as the first region 301. The doping concentration of the first region 301 may be greater than the doping concentration of the drift region 18. The doping concentration of the first region 301 may be half or less, or 1/10 or less, or 1/100 or less of the doping concentration of the second region 302.

The adjustment region 201 is irradiated with charged particles from the upper surface 21 to form the lifetime adjustment region 206 (see FIG. 3A). On the other hand, the irradiation of charged particles may form a level in the gate insulating film 42 in the adjustment region 201, causing the threshold voltage (ON voltage and OFF voltage) in the adjustment region 201 to be lower than the threshold voltage in the non-adjustment region 202. As the threshold voltage decreases, the turn-off timing is delayed, so the turn-off in the adjustment region 201 is later than in the non-adjustment region 202, and the current crowding may occur in the adjustment region 201, resulting in a decrease in the withstand capability.

In the present example, the doping concentration of the first region 301 of the adjustment region 201 is lower than the doping concentration of the second region 302.

Therefore, the carrier concentration in the drift region 18 or the like of the adjustment region 201 can be lowered to suppress the current flowing in the adjustment region 201. Therefore, even if the turn-off of the adjustment region 201 is delayed, the current flowing in the adjustment region 201 can be suppressed to prevent the decrease in the withstand capability.

In the example of FIG. 3A, all the mesa portions 60 of the adjustment region 201 are the first mesa portions 61 provided with low concentration first regions 301. In another example, a part of mesa portions 60 of the adjustment region 201 may be second mesa portions 62 provided with high concentration second regions 302. As an example, among the mesa portions 60 of the adjustment region 201, one or more mesa portions 60 closest to the non-adjustment region 202 may be the second mesa portions 62. Among the mesa portions 60 of the adjustment region 201, one or more mesa portions 60 closest to the diode portion 80 may be the first mesa portions 61.

The doping concentrations of the first region 301 may be the same as, or may be different from each other in each of the first mesa portions 61. As an example, the doping concentration of the first region 301 may be higher as the first mesa portion 61 is closer to the non-adjustment region 202.

The doping concentration of the first region 301 may be adjusted according to the density of the lattice defects 204 in the lifetime adjustment region 206 provided below. For example, the doping concentration of the first region 301 may be lower as the density of the lattice defects 204 below is higher. In this manner, the doping concentration of the first region 301 is lower in regions with greater irradiation amount of charged particles. Therefore, it is possible that the lower the threshold voltage of the first mesa portion 61, the lower the doping concentration of the first region 301, and the lower the carrier concentration. Therefore, the later the turn-off of the first mesa portion 61, the lower the carrier concentration below, and thereby current crowding can be suppressed. As an example, in the adjustment region 201, the density of the lattice defects 204 of the lifetime adjustment region 206 may be lower as leaving further away from the diode portion 80. In this case, as the first mesa portion 61 leaves further away from the diode portion 80, the doping concentration of the first region 301 may be higher.

The third mesa portion 63 and the fourth mesa portion 64 have a third region 303 of the N− type provided between the depth position Z14 and the depth position Zt. The third region 303 may be provided over the entire region between the depth position Z14 and the depth position Zt. The second region 302 in the present example may have a dose amount greater than that of the third region 303. The third region 303 in the present example is a region with a doping concentration lower than that of the second region 302. The third region 303 may have a doping concentration higher than that of the first region 301, may have a doping concentration identical to that of the first region 301, or may have a doping concentration lower than that of the first region 301. In another example, the third region 303 may have a doping concentration identical to that of the second region 302. The third region 303 may be provided throughout each mesa portion in the X axis direction. The third region 303 may be provided to cover a whole lower surface of the base region 14 in each mesa portion.

FIG. 3B illustrates a figure showing one example of the cross section e-e in FIG. 2. The cross section e-e is the XZ plane passing through an emitter region 12 and a cathode region 82. A semiconductor device 100 in this example includes a semiconductor substrate 10, an interlayer insulating film 38, an emitter electrode 52, and a collector electrode 24 in the cross section.

FIG. 3B is different from FIG. 3A in a point of including a third plug region 223 that covers the bottom of the third contact portion 213, provided in the third mesa portion 63 of the diode portion 80 and the fourth mesa portion 64 of the boundary region 200. The other structures are similar to the example shown in FIG. 3A. In the present specification, the portion contacting the emitter electrode 52 in each mesa portion may be referred to as a contact portion. The contact portion of the first mesa portion 61 is regarded as a first contact portion 211, the contact portion of the second mesa portion 62 is regarded as a second contact portion 212, the contact portion of the third mesa portion 63 and the fourth mesa portion 64 is regarded as the third contact portion 213. The third plug region 223 is a region of the P++ type with a doping concentration higher than that of the contact region 15.

As shown in the present example, even if FIG. 3B includes the third plug region 223 that covers the bottom of the third contact portion 213, provided in the third mesa portion 63 of the diode portion 80 and the fourth mesa portion 64 of the boundary region 200, the similar effect to that of FIG. 3A can be obtained.

FIG. 3C illustrates another example of the cross section e-e. In the present example, the lifetime adjustment region 206 is different from the example shown in FIG. 3A in a point of extending up to a region below at least one second mesa portion 62. The other structures are similar to the example shown in FIG. 3A.

In the present example, among the mesa portions 60 of the adjustment region 201, one or more mesa portions 60 closest to the non-adjustment region 202 are the second mesa portions 62 and the other mesa portions 60 are the first mesa portions 61. In the present example, the second region 302 and the lifetime adjustment region 206 overlap in part in the top view. The adjustment region 201 has the first mesa portions 61, and thereby the carrier density near the first mesa portion 61 can be reduced, and the decrease of the withstand capability can be suppressed. The number of the first mesa portions 61 in the adjustment region 201 may be equal to or more than the number of the second mesa portions 62 in the adjustment region 201, or even more. In the adjustment region 201, one first mesa portion 61 may be arranged between two second mesa portions 62. A second mesa portion 62 may be located on the boundary between the adjustment region 201 and the non-adjustment region 202.

FIG. 3D illustrates a figure showing one example of a cross section e-e in FIG. 2. The cross section e-e is the XZ plane passing through an emitter region 12 and a cathode region 82. A semiconductor device 100 in this example includes a semiconductor substrate 10, an interlayer insulating film 38, an emitter electrode 52, and a collector electrode 24 in the cross section.

FIG. 3D is different from FIG. 3C in a point of including a third plug region 223 that covers the bottom of the third contact portion 213, provided in the third mesa portion 63 of the diode portion 80 and the fourth mesa portion 64 of the boundary region 200. Other structures are similar to the example shown in FIG. 3C. As shown in the present example, even if FIG. 3D includes a third plug region 223 that covers the bottom of the third contact portion 213, provided in the third mesa portion 63 of the diode portion 80 and the fourth mesa portion 64 of the boundary region 200, the similar effect to that of FIG. 3C can be obtained.

FIG. 3E illustrates another example of the cross section e-e. The present example is different from the example shown in FIG. 3A in a point that the second mesa portion 62 and the second region 302 are arranged away from the lifetime adjustment region 206 in the X axis direction. The other structures are similar to the example shown in FIG. 3A.

One or more first mesa portions 61 may be provided between the end of the lifetime adjustment region 206 in the X axis direction and the end of the second region 302 in the X axis direction. In the present example, among the mesa portions 60 of the non-adjustment region 202, one or more mesa portions 60 closest to the adjustment region 201 are first mesa portions 61, and the other mesa portions 60 are second mesa portions 62. The non-adjustment region 202 has one or more first mesa portions 61, and thereby the distance between the lifetime adjustment region 206 and the second region 302 can be ensured, and the decrease of the withstand capability can further be suppressed. The doping concentration of the first region 301 in the first mesa portion 61 of the non-adjustment region 202 may be the same as, or may be higher than the doping concentration of the first region 301 in the first mesa portion 61 of the adjustment region 201. However, the doping concentration of the first region 301 is lower than the doping concentration of the second region 302 in the first mesa portion 61 of the non-adjustment region 202. The first mesa portion 61 may be located on the boundary between the adjustment region 201 and the non-adjustment region 202.

FIG. 3F illustrates another example of the cross section e-e. The present example is different from the example shown in FIG. 3E in a point of including a third plug region 223 that covers the bottom of the third contact portion 213, provided in the third mesa portion 63 of the diode portion 80 and the fourth mesa portion 64 of the boundary region 200. Other structures are similar to the example shown in FIG. 3E. As shown in the present example, even if FIG. 3D includes a third plug region 223 that covers the bottom of the third contact portion 213, provided in the third mesa portion 63 of the diode portion 80 and the fourth mesa portion 64 of the boundary region 200, the similar effect to that of FIG. 3E can be obtained.

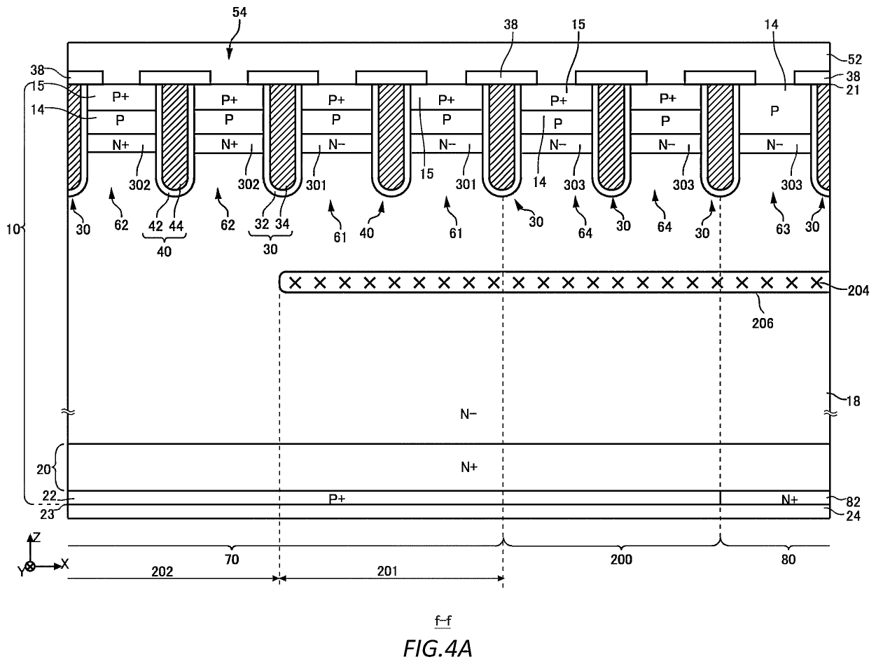

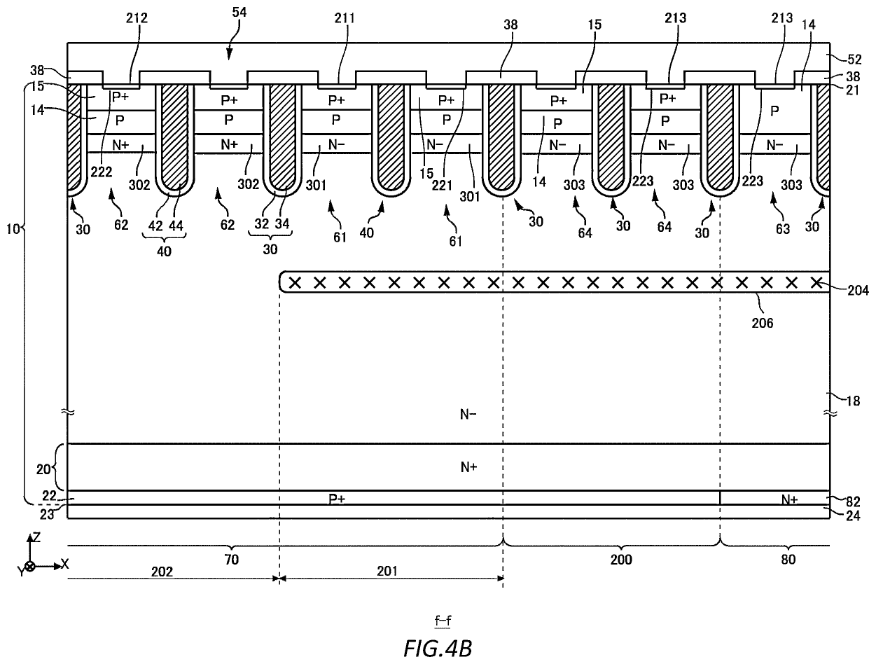

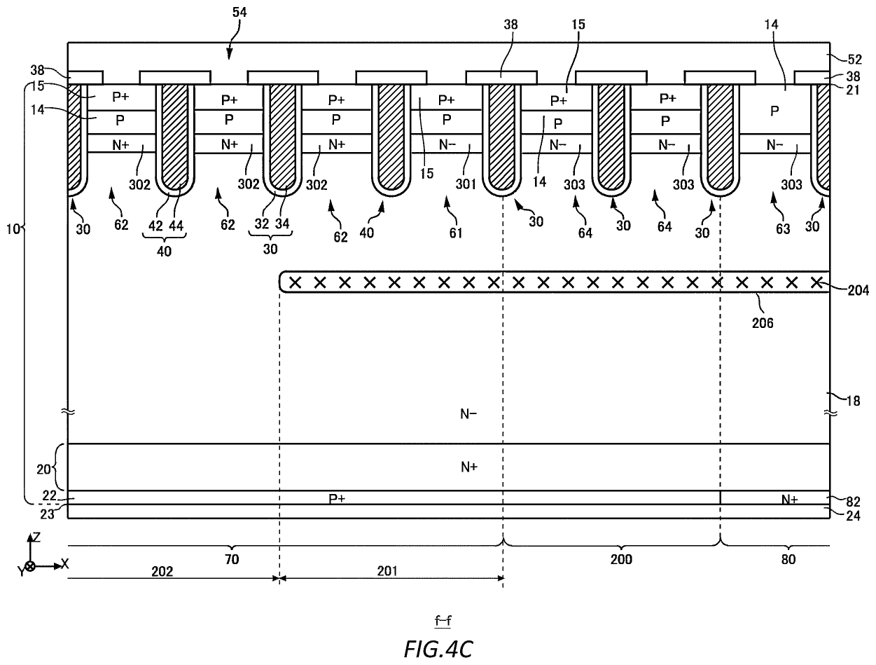

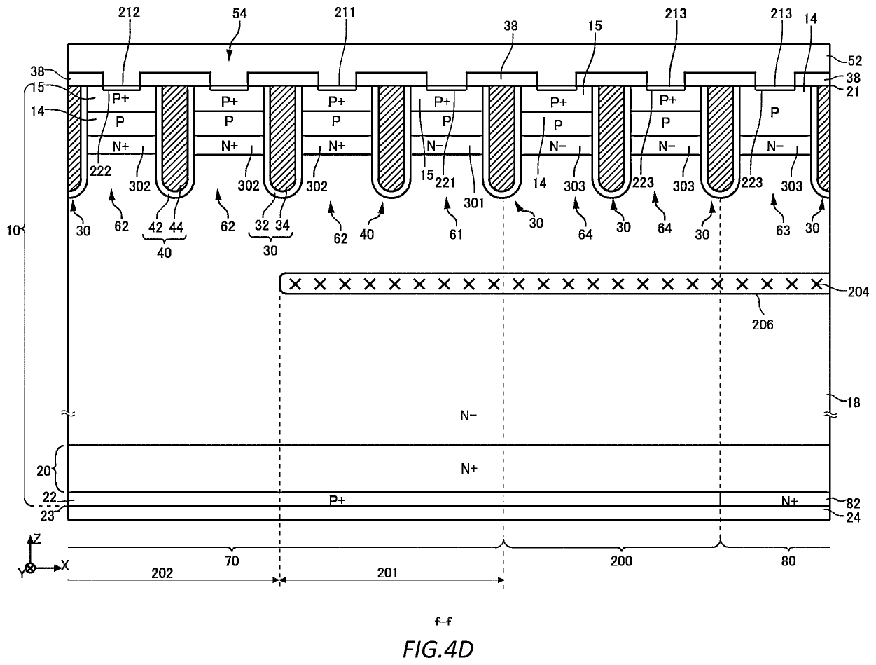

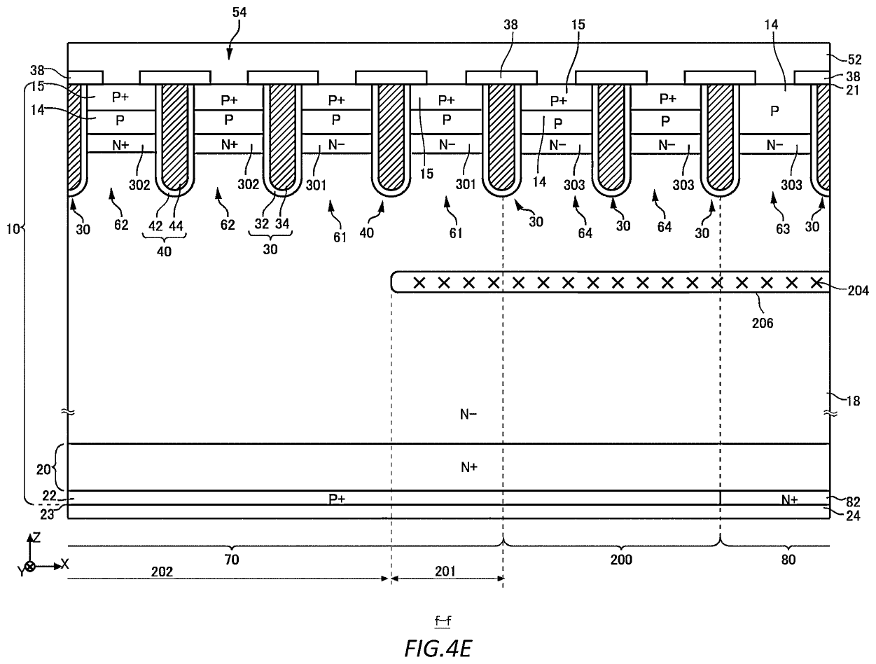

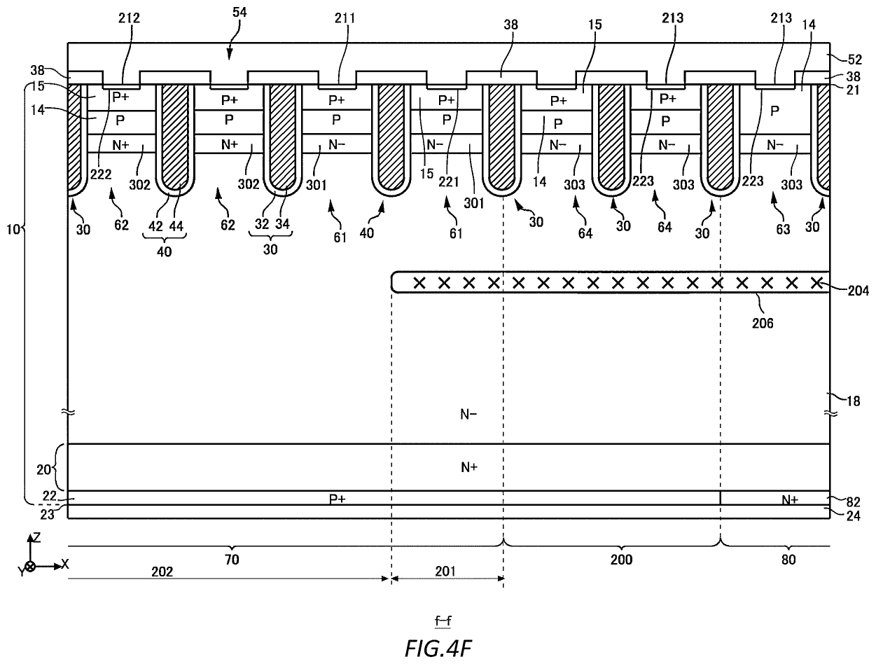

FIG. 4A illustrates a view showing an example of a cross section f-f in FIG. 2. The cross section f-f is an XZ plane passing through the contact region 15 and the cathode region 82. The cross section in the present example has a structure that replaces the emitter region 12 in the example shown in FIG. 3A with the contact region 15. Structures other than the contact region 15 are similar to those in FIG. 3A.

FIG. 4B illustrates a view showing an example of an cross section f-f in FIG. 2. The cross section f-f is an XZ plane passing through the contact region 15 and the cathode region 82. The cross section in the present example has a structure that replaces the emitter region 12 with the contact region 15 in the example shown in FIG. 3B. Structures other than the contact region 15 are similar to those in FIG. 3B. As shown in FIG. 4B, the first mesa portion 61 may be provided with a first plug region 221 covering the first contact portion 211. The second mesa portion 62 may be provided with a second plug region 222 covering the second contact portion 212. The first plug region 221 and the second plug region 222 are regions of the P++ type with a doping concentration higher than that of the contact region 15.

FIG. 4C illustrates one example of the cross section f-f. The cross section in the present example has a structure that replaces the emitter region 12 with the contact region 15 in the example shown in FIG. 3C. Structures other than the contact region 15 are similar to those in FIG. 3C.

FIG. 4D illustrates one example of the cross section f-f. The cross section in the present example has a structure that replaces the emitter region 12 with the contact region 15 in the example shown in FIG. 3D. Structures other than the contact region 15 are similar to those in FIG.

3D. As shown in FIG. 4D, the first mesa portion 61 may be provided with a first plug region 221 covering the first contact portion 211. The second mesa portion 62 may be provided with a second plug region 222 covering the second contact portion 212.

FIG. 4E illustrates one example of the cross section f-f. The cross section in the present example has a structure that replaces the emitter region 12 with the contact region 15 in the example shown in FIG. 3E. Structures other than the contact region 15 are similar to those in FIG. 3E.

FIG. 4F illustrates one example of the cross section f-f. The cross section in the present example has a structure that replaces the emitter region 12 with the contact region 15 in the example shown in FIG. 3F. Structures other than the contact region 15 are similar to those in FIG.

3F. As shown in FIG. 4F, the first mesa portion 61 may be provided with a first plug region 221 covering the first contact portion 211. The second mesa portion 62 may be provided with a second plug region 222 covering the second contact portion 212.

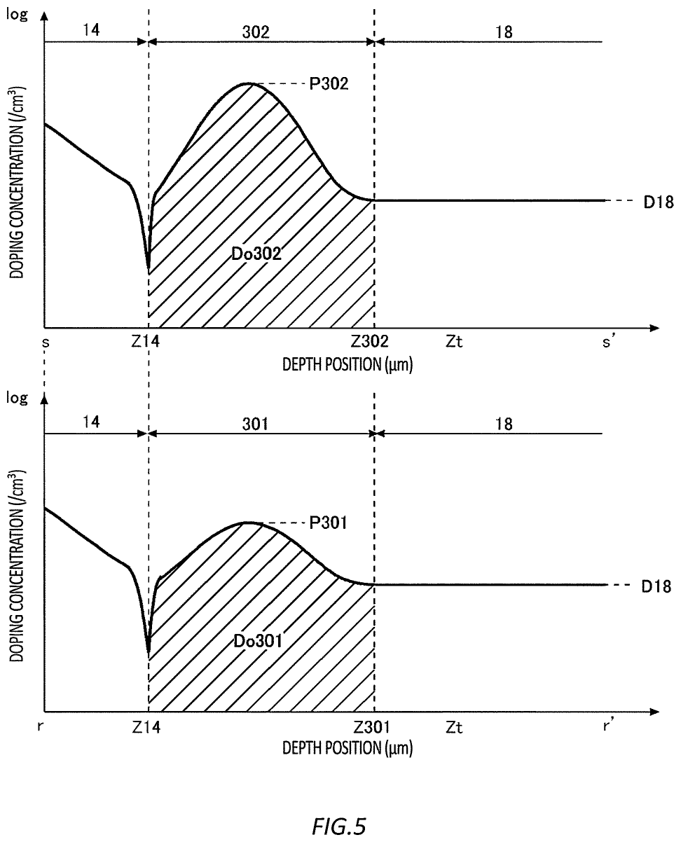

FIG. 5 illustrates an example of doping concentration distributions on a line r-r′ and a line s-s′ of FIG. 3A. The line r-r′ is a line parallel to the Z axis passing through the first region 301, and the line s-s′ is a line parallel to the Z axis passing through the second region 302.

In the present example, the boundary between the second region 302 and the base region 14 is provided with a PN bonding. The depth position of the boundary is regarded as Z14. In the second region 302, the doping concentration distribution has a peak. The doping concentration at the local maximum of the peak is regarded as P302. The doping concentration of the drift region 18 is regarded as D18. The peak concentration P302 is higher than the doping concentration D18. On a side closer to the lower surface 23 than the local maximum of the peak, the position where the doping concentration first becomes D18 is regarded as a depth position Z302 of the lower end of the second region 302.

In the present example, the boundary between the first region 301 and the base region 14 is provided with a PN bonding. The depth position of the boundary is regarded as Z14. The doping concentration distribution in the first region 301 in the present example has a peak. The doping concentration at the local maximum of the peak is regarded as P301. The peak concentration P301 is higher than the doping concentration D18. On a side closer to the lower surface 23 than the local maximum of the peak, the position where the doping concentration first becomes D18 is regarded as a depth position Z301 of the lower end of the first region 301. The depth position Z301 may be the same as or different from the depth position Z302.

The peak concentration P301 is lower than the peak concentration P302. As described above, the peak concentration P301 may be half or less, or may be 1/10 or less, or may be 1/100 or less of the peak concentration P302.

The dose amount per unit area (ions/cm²) of the dopant ions with respect to the first region 301 is regarded as Do301. The dose amount Do301 of the first region 301 may use a value obtained by integrating the doping concentration of the first region 301 from the depth position Z14 to Z301. The dose amount per unit area (ions/cm²) of the dopant ions with respect to the second region 302 is regarded as Do302. The dose amount Do302 of the second region 302 may use a value obtained by integrating the doping concentration of the second region 302 from the depth position Z14 to Z302. The area of the hatched portion by the hatched lines in FIG. 5 corresponds to each dose amount.

The dose amount Do302 may be greater than the dose amount Do301. The dose amount Do302 may be twice or more, or may be 10 times or more, or may be 100 times or more of the dose amount Do301.

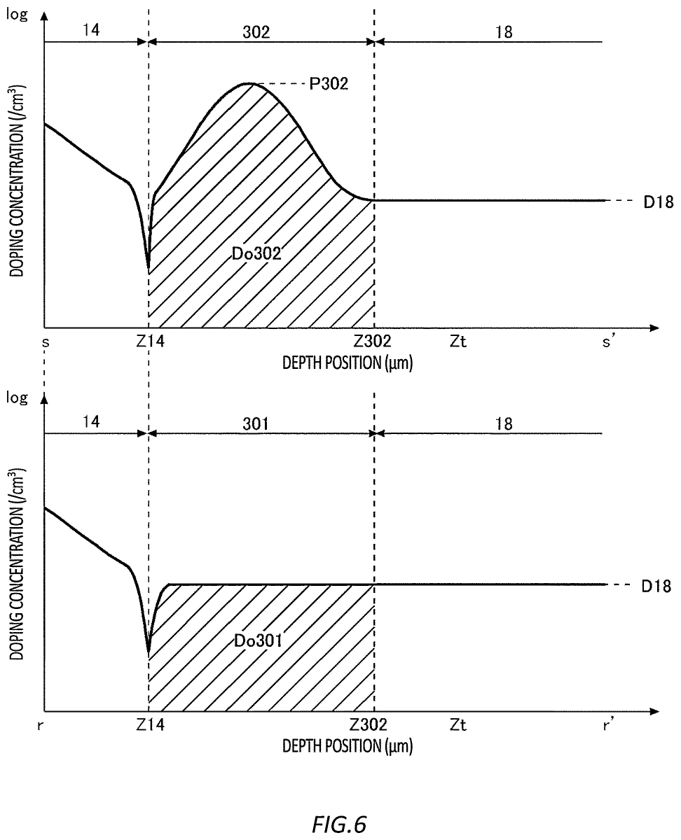

FIG. 6 illustrates another example of doping concentration distributions on the line r-r′ and line s-s′. The doping concentration of the first region 301 is the same as the doping concentration of the drift region 18 in the present example. In this case, the depth position Z302 of the lower end of the second region 302 may be used as the depth position of the lower end of the first region 301.

The doping concentration D18 of the first region 301 is less than the peak concentration P302. The dose amount Do301 of the first region 301 is less than the dose amount Do302 of the second region 302.

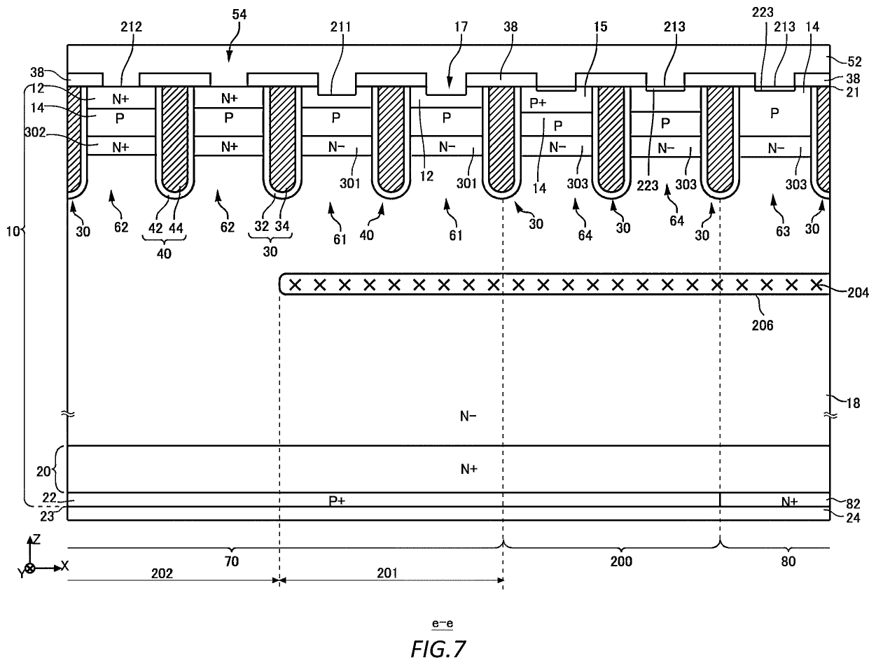

FIG. 7 illustrates a view showing another example of the cross section e-e. The present example is different from the examples described in FIG. 1 to FIG. 6 in a point that the first mesa portion 61 has the first contact portion 211, the second mesa portion 62 has the second contact portion 212, the third mesa portion 63 and the fourth mesa portion 64 have the third contact portion 213. Other structures are similar to those in any of the examples described in FIG. 1 to FIG. 6.

The first contact portion 211 may be provided with respect to some first mesa portions 61, the first contact portion 211 may also be provided with respect to all the first mesa portions 61. The second contact portion 212 may be provided with respect to some second mesa portions 62, the second contact portion 212 may also be provided with respect to all the second mesa portions 62. The third contact portion 213 may be provided with respect to some third mesa portions 63, the third contact portion 213 may also be provided with respect to all the third mesa portions 63.

The third contact portion 213 may be provided with respect to some fourth mesa portions 64, the third contact portion 213 may also be provided to all the fourth mesa portions 64.

In the present example, each contact portion refers to a boundary where the emitter electrode 52 contacts the semiconductor substrate 10. The contact portion may include a surface of the emitter electrode 52 and a surface of the semiconductor substrate 10. When a metal silicide layer is formed at the boundary between the emitter electrode 52 and the semiconductor substrate 10, the metal silicide layer may be included in the emitter electrode 52 (metal electrode). That is, the boundary between the metal silicide layer and the semiconductor substrate 10 may be regarded as the contact portion.

In at least a part of the mesa portions 60, the trench contact portion 17 may be provided. The trench contact portion 17 is a portion where the metal electrode of the emitter electrode 52 or the like is provided inside the semiconductor substrate 10. The trench contact portion 17 can be formed by forming a groove on the upper surface 21 of the semiconductor substrate 10 that is exposed via the contact hole 54, and filling the metal electrode the inside of the groove. In the mesa portion 60 provided with the trench contact portion 17, the region, in the trench contact portion 17, where the mesa portion 60 contacts the metal electrode of the emitter electrode 52 or the like corresponds to the contact portion. In the example of FIG. 7, the trench contact portion 17 is provided in the first mesa portion 61.

In at least a part of the mesa portions 60, the plug region may be provided in the region that contacts the lower end of the contact portion. The plug region may be a region of a P++ type with a doping concentration higher than that of the contact region 15. In the example of FIG. 7, a third plug region 223 in direct contact with the third contact portion 213 is provided.

The first contact portion 211 of the first mesa portion 61 shown in FIG. 7 may be provided at a depth shallower than the lower end of the emitter region 12. The first plug region 221 is not provided in the lower end of the first contact portion 211. In another example, the lower end of the first contact portion 211 may be provided at a depth reaching the base region 14, the first plug region 221 may be provided to contact the lower end of the first contact portion 211.

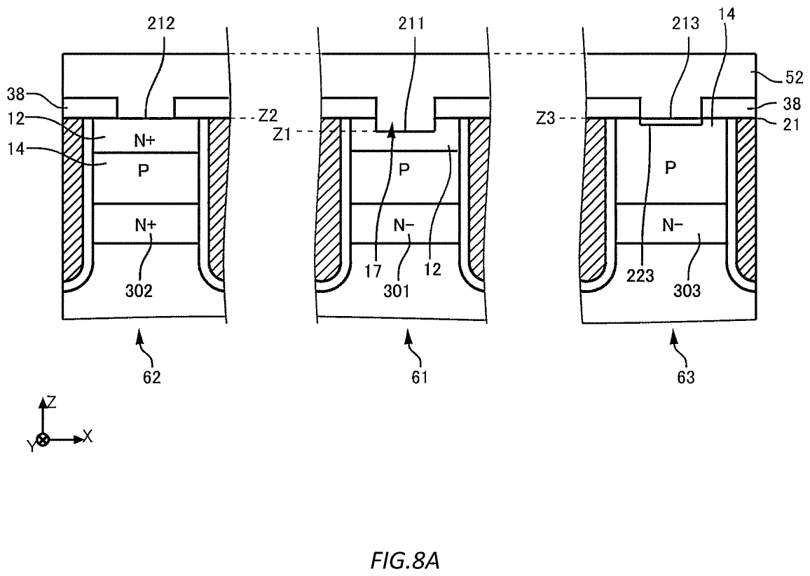

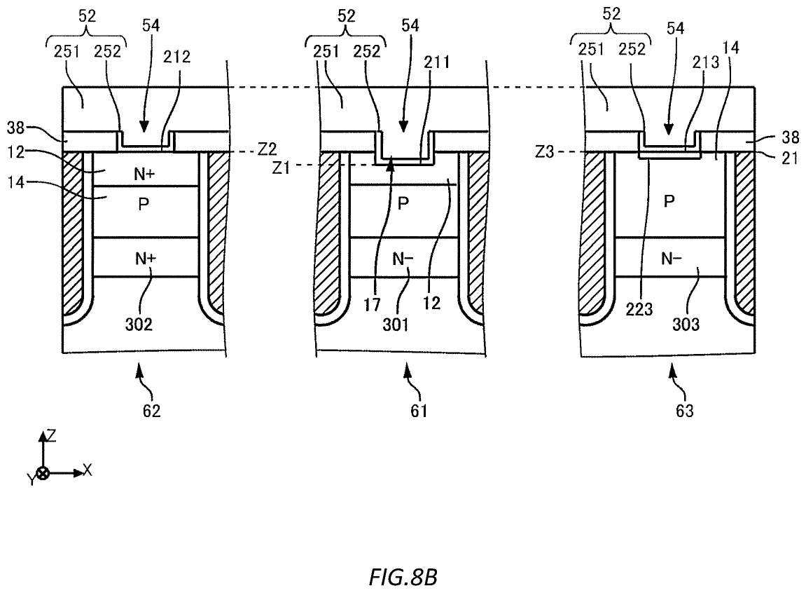

FIG. 8A illustrates enlarged views near the first mesa portion 61, the second mesa portion 62, and the third mesa portion 63. In FIG. 8A, the first mesa portion 61, the second mesa portion 62, and the third mesa portion 63 are shown one by one respectively, and the regions between each mesa portions are omitted.

The depth position of the lower end of the first contact portion 211 is regarded as Z1, the depth position of the lower end of the second contact portion 212 is regarded as Z2, and the depth position of the lower end of the third contact portion 213 is regarded as Z3. The lower end of each contact portion refers to the portion arranged lowest at the boundary where the metal electrode contacts the semiconductor substrate 10. The depth position Z2 is arranged above the depth position Z1. That is, the depth position Z1 is away from the upper surface 21 of the semiconductor substrate 10 further than the depth position Z2. In the example of FIG. 8A, the depth position Z1 is a position below the upper surface 21 of the semiconductor substrate 10, and the depth position Z2 is a depth position with a depth identical to the upper surface 21 of the semiconductor substrate 10. In another example, the depth position Z2 may be located between the depth position Z1 and the upper surface 21 of the semiconductor substrate 10. In this case, taking the upper surface 21 of the semiconductor substrate 10 as reference, the depth position Z2 may be at half or less, or may be at 1/4 or less of the depth position Z1.

The adjustment region 201 is irradiated with charged particles from the upper surface 21 to form the lifetime adjustment region 206 (see FIG. 7). On the other hand, the irradiation of charged particles may form a level in the gate insulating film 42 in the adjustment region 201, causing the threshold voltage (ON voltage and OFF voltage) in the adjustment region 201 to be lower than the threshold voltage in the non-adjustment region 202. As the threshold voltage decreases, the turn-off timing is delayed, so the turn-off in the adjustment region 201 is later than in the non-adjustment region 202, and the current crowding may occur in the adjustment region 201, resulting in a decrease in the withstand capability.

In the semiconductor device 100 in the present example, the depth position Z1 of the first contact portion 211 is made deeper than the depth position Z2 of the second contact portion 212. In this manner, in the first mesa portion 61, hole extraction from the semiconductor substrate 10 to the emitter electrode 52 becomes easier. Therefore, even if current crowding occurs in the first mesa portion 61, the decrease of the withstand capability can be suppressed. The depth position

Z1 of the first contact portion 211 may be shallower, or may be deeper than the emitter region 12.

The lower end of the third contact portion 213 in the present example is arranged above the first contact portion 211. The depth position Z3 of the third contact portion 213 may be at the same depth as the depth position Z2 of the second contact portion 212, or may be arranged between the depth position Z2 and the depth position Z1. The depth position Z3 of the third contact portion 213 may be at the same depth as the depth position Z1 of the first contact portion 211.

The third mesa portion 63 may be provided to contact the lower end of the third contact portion 213, and have a third plug region 223 of the P++ type with a higher doping concentration than the base region 14 (anode region). The third plug region 223 may have a higher doping concentration than the contact region 15. The base region 14 (anode region) of the third mesa portion 63 may be lower than the doping concentration than the base region 14 of the transistor portion 70. In this case, the implantation of holes from the third mesa portion 63 to the drift region 18 can be suppressed.

As shown in FIG. 7, at least one first mesa portion 61 is provided with both of the trench contact portions 17 and the first region 301. All the first mesa portions 61 may have both of the trench contact portions 17 and the first region 301. In another example, some first mesa portions 61 may have the first region 301 but be without the trench contact portions 17.

FIG. 8B illustrates enlarged views near the first mesa portion 61, the second mesa portion 62, and the third mesa portion 63. In FIG. 8B, the first mesa portion 61, the second mesa portion 62, and the third mesa portion 63 are shown respectively, and the each mesa portions between the regions are omitted.

The emitter electrode 52 (metal electrode) of the present example includes a barrier metal portion 252 and an upper portion 251. The barrier metal portion 252 is provided above the upper surface 21 of the semiconductor substrate 10. The barrier metal portion 252 is provided on the bottom surface of at least either of the contact hole 54 or the trench contact portion 17. The barrier metal portion 252 may be provided at the lower end of each contact portion. The barrier metal portion 252 may contact the semiconductor substrate 10. The barrier metal portion 252 may be provided on a side surface of the contact hole 54 and the trench contact portion 17. The barrier metal portion 252 may be provided or may also be not provided on the upper surface of the interlayer insulating film 38.

The barrier metal portion 252 is formed of a material that absorbs more hydrogen than the upper portion 251. With this configuration, entry of hydrogen into the semiconductor substrate 10 is suppressed. The barrier metal portion 252 in the present example contains titanium. The barrier metal portion 252 may include a titanium nitride layer. The barrier metal portion 252 may be a stacked film of a titanium layer and a titanium nitride layer.

The upper portion 251 is provided above the barrier metal portion 252. The upper portion 251 is provided above the interlayer insulating film 38. The upper portion 251 is formed of a material different from that of the barrier metal portion 252. In the present example, the upper portion 251 does not contain titanium. As an example, the upper portion 251 contains aluminum. The upper portion 251 may be an alloy of aluminum and silicon. Inside the contact hole 54 or the trench contact portions 17, the upper portion 251 may contain a plug portion formed of tungsten, or the plug portion may be provided above the interlayer insulating film 38. Even if the first contact portion 211, the second contact portion 212 and the third contact portion 213 include the barrier metal portion 252 as shown in the present example, the similar effect to FIG. 8A can also be obtained.

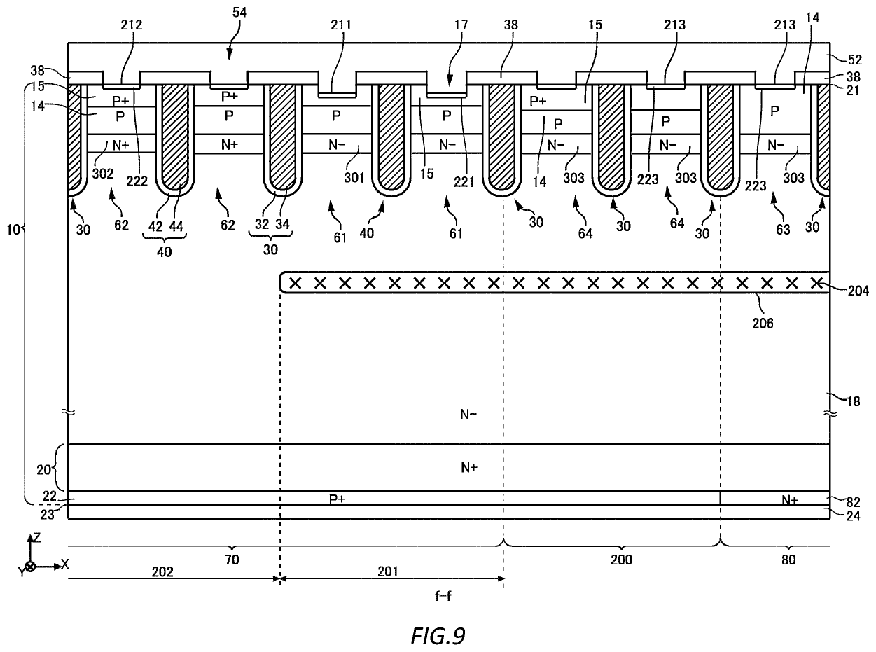

FIG. 9 illustrates an example of a cross section f-f in FIG. 2. The cross section f-f is an XZ plane passing through the contact region 15 and the cathode region 82. In the cross section f-f, a contact region 15 is arranged instead of the emitter region 12 in the cross section e-e as shown in FIG. 7. Other structures are similar to the cross section e-e. Also in the cross section f-f, the structures of the first contact portion 211, the second contact portion 212 and the third contact portion 213 are similar to those in the cross section e-e.

The first mesa portion 61 in the present example is provided to contact the lower end of the first contact portion 211, and has a first plug region 221 of the P++ type with a higher doping concentration than the contact region 15. At least a part of the first plug region 221 is provided to overlap the contact region 15 in a top view. That is, the first plug region 221 is provided in any XZ cross section passing through the contact region 15. The first plug region 221 may be provided in the XZ cross section passing through the center in the Y axis direction of the contact region 15. A part of the first plug region 221 may overlap the emitter region 12 in the top view. The first plug region 221 may be provided in the end region of the emitter region 12 that contacts the contact region 15. The first plug region 221 may not be provided in any XZ cross section passing through the emitter region 12. For example, the first plug region 221 is not provided in the XZ cross section passing through the center in the Y axis direction of the emitter region 12. The entire first plug region 221 may be provided to overlap the contact region 15. In this case, the first plug region 221 does not overlap the emitter region 12 in the top view.

The second mesa portion 62 in the present example is provided to contact the lower end of the second contact portion 212, and has a second plug region 222 of the P++ type with a higher doping concentration than the contact region 15. At least a part of the second plug region 222 is provided to overlap the contact region 15 in a top view. That is, the second plug region 222 is provided in any XZ cross section passing through the contact region 15. The second plug region 222 may be provided in the XZ cross section passing through the center in the Y axis direction of the contact region 15. A part of the second plug region 222 may overlap the emitter region 12 in the top view. The second plug region 222 may be provided in the end region of the emitter region 12 that contacts the contact region 15. The second plug region 222 may not be provided in any XZ cross section passing through the emitter region 12. For example, the second plug region 222 is not provided in the XZ cross section passing through the center in the Y axis direction of the emitter region 12. The entire second plug region 222 may be provided to overlap the contact region 15.

In this case, the second plug region 222 does not overlap the emitter region 12 in the top view. By providing each plug region, it is easier to extract holes in each mesa portion. Therefore, it is possible to suppress reduction in withstand capability.

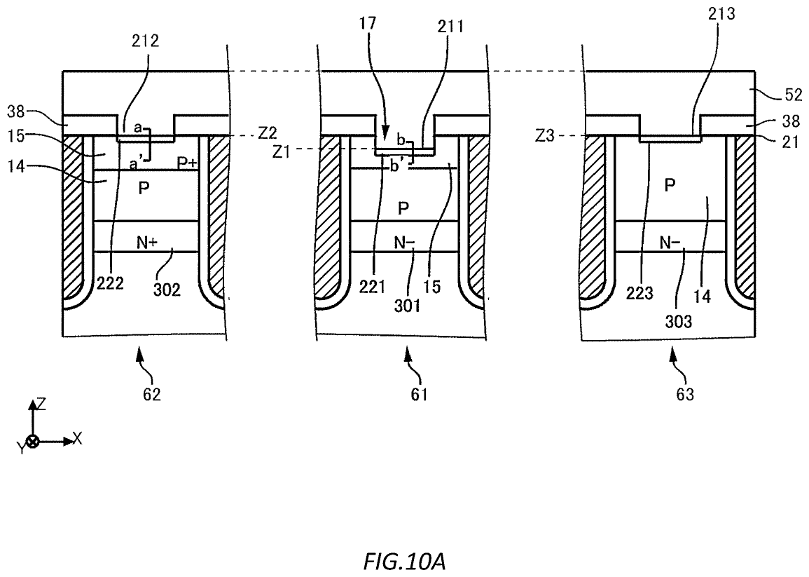

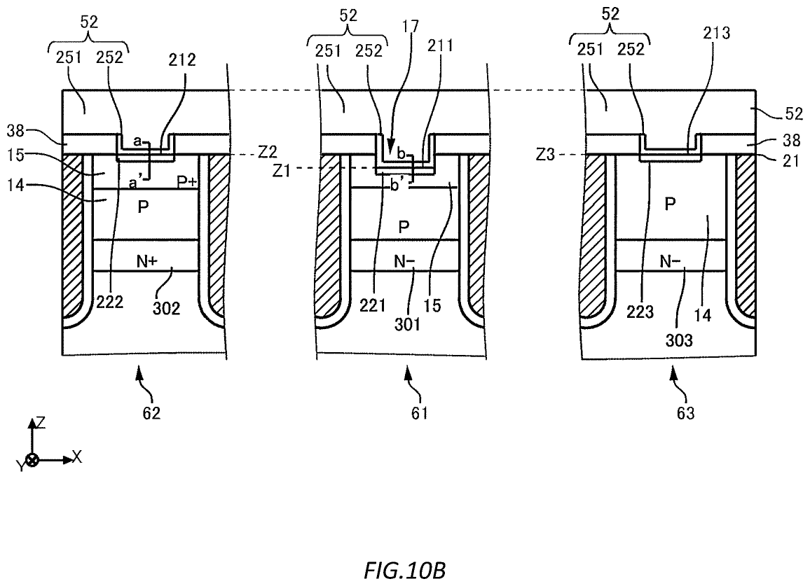

FIG. 10A illustrates enlarged views near the first mesa portion 61, the second mesa portion 62, and the third mesa portion 63 shown in FIG. 9. In FIG. 10A, the first mesa portion 61, the second mesa portion 62, and the third mesa portion 63 are shown one by one respectively, and the each mesa portions between the regions are omitted. The structure of the third mesa portion 63 is similar to that of the third mesa portion 63 shown in FIG. 8A.

The first mesa portion 61 has a contact region 15 instead of the emitter region 12 and a first plug region 221 contacting the lower end of the first contact portion 211 with respect to the structure shown in FIG. 8A. Other structures are similar to those of the example shown in FIG. 8A. The second mesa portion 62 has a contact region 15 instead of the emitter region 12 and a second plug region 222 contacting the lower end of the second contact portion 212 with respect to the structure shown in FIG. 8A. Other structures are similar to those of the example shown in FIG. 8A.

The first plug region 221 may be provided up to a region lower than the second plug region 222. Each plug region is a region of the P++ type with a high concentration. Therefore, if each plug region is arranged near the channel region (the portion where the base region 14 contacts the gate trench portion 40), acceptors implanted to the plug region tend to spread to the channel region, and the doping concentration of the channel region becomes higher. If the doping concentration of the channel region becomes higher, the threshold voltage increases.

In the present example, the first plug region 221 is formed deeper than the second plug region 222. Therefore, the threshold voltage of the first mesa portion 61 can be relatively higher. This can offset the decrease in the threshold voltage of the first mesa portion 61 due to the formation of the lifetime adjustment region 206.

The first plug region 221 and the second plug region 222 may be formed by implantation of impurities by different dose amounts (/cm²). This allows for adjusting the threshold voltage of each mesa portion more precisely. For example, the difference in the dose amount between the first plug region 221 and the second plug region 222 may be set according to a variation amount of the threshold voltage of the first mesa portion 61 due to the formation of the lifetime adjustment region 206. This can offset the variation in the threshold voltage precisely. The first plug region 221 and the second plug region 222 may also be formed by implantation of impurities by the same dose amount. This allows for manufacturing the semiconductor device by easy process.

FIG. 10B illustrates enlarged views near the first mesa portion 61, the second mesa portion 62, and the third mesa portion 63 shown in FIG. 9. In FIG. 10B, the first mesa portion 61, the second mesa portion 62, and the third mesa portion 63 are shown one by one respectively, and the each mesa portions between the regions are omitted. The structure of the third mesa portion 63 is similar to that of the third mesa portion 63 shown in FIG. 8B.

The first mesa portion 61 has a contact region 15 instead of the emitter region 12 and a first plug region 221 contacting the lower end of the first contact portion 211 with respect to the structure shown in FIG. 8B. Other structures are similar to those of the example shown in FIG. 8B. The second mesa portion 62 has a contact region 15 instead of the emitter region 12 and a second plug region 222 contacting the lower end of the second contact portion 212 with respect to the structure shown in FIG. 8B. Other structures are similar to those of the example shown in FIG. 8B. Even if the first contact portion 211, the second contact portion 212 and the third contact portion 213 include the barrier metal portion 252 as shown in the present example, the similar effect to FIG. 10A can also be obtained.

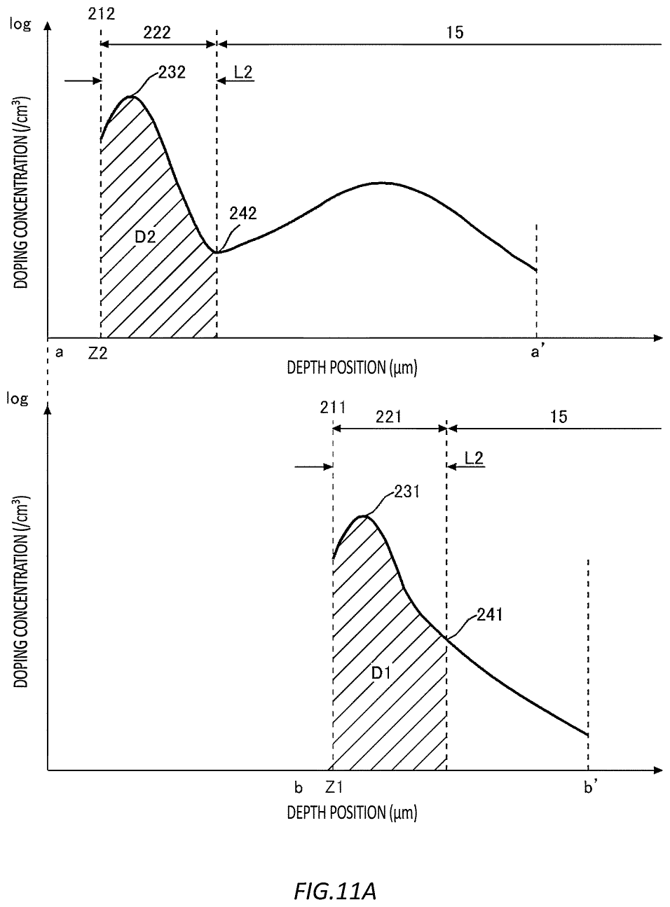

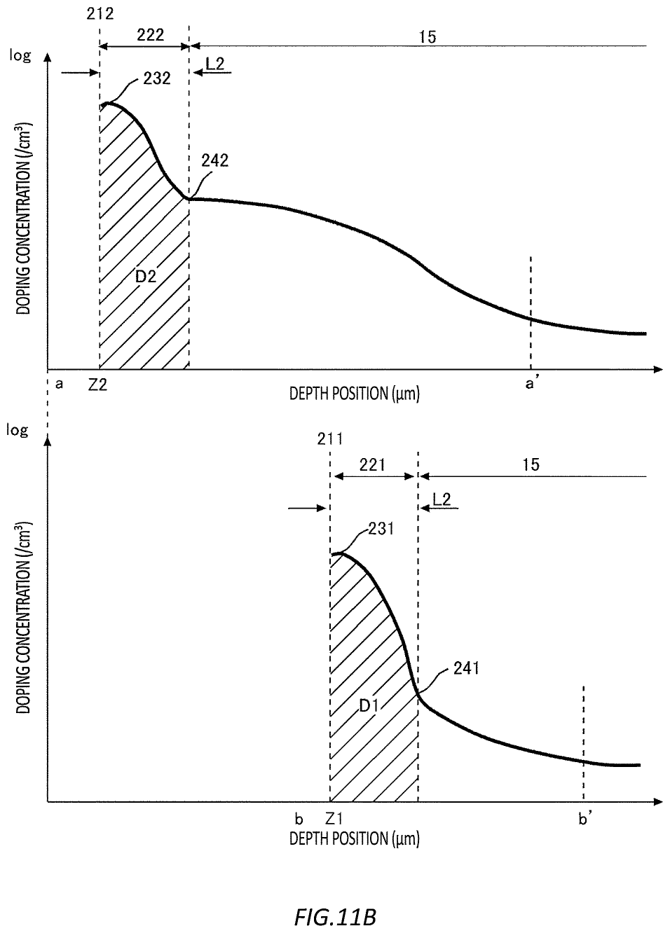

FIG. 11A illustrates an example of a doping concentration distribution on a line a-a′ and a line b-b′ in FIG. 10A. The line a-a′ is a line parallel to the Z axis, passing through the second plug region 222. The line b-b′ is a line parallel to the Z axis, passing through the first plug region 221. The first plug region 221 and the second plug region 222 have a first peak 231 and a second peak 232 of the doping concentration. The second plug region 222 has a bonding portion 242 of the doping concentration in the boundary with the contact region 15. The first plug region 221 in the present example may not have a valley portion 242 of the doping concentration in the boundary with the contact region 15, but may have a bonding portion that becomes a valley portion.

The dose amount of the second plug region 222 is regarded as D2, and the dose amount of the first plug region 221 is regarded as D1. The dose amount D2 may use a value obtained by integrating the doping concentration from the lower end position Z2 of the second contact portion 212 to the bonding portion 242 of the doping concentration in the depth direction. Similarly, the dose amount D1 may use a value obtained by integrating the doping concentration from the lower end position Z1 of the first contact portion 211 to the bonding portion 241 of the doping concentration in the depth direction. When there does not exist a valley portion of the doping concentration in the boundary between the first plug region 221 and the contact region 15, the value obtained by integrating the doping concentration over a predetermined depth distance L2 from the depth position Z1 may be regarded as the dose amount D1. The distance L2 is a distance from the depth position Z2 in the second plug region 222 to the bonding portion 242 in the depth direction, for example. That is, in the first plug region 221 and the second plug region 222, the value obtained by integrating the doping concentration over the same distance L2 may be used as each dose amount. In another example, the value obtained by integrating the doping concentration from the lower end position (Z1 or Z2) of each contact portion to the peak of the doping concentration (the first peak 231 or the second peak 232) may be used as an indicator representing each dose amount. The doping concentration at the peak (the first peak 231 or the second peak 232) of the doping concentration may be used as an indicator representing each dose amount.

As described above, the dose amount D1 and the dose amount D2 may be the same. The dose amounts being the same means that an error of ±20% may be allowed, an error of ±10% may be allowed, and an error of ±5% may be allowed.

FIG. 11B illustrates an example of a doping concentration distribution on a line a-a′ and a line b-b′ in FIG. 10B. The line a-a′ is a line parallel to the Z axis, passing through the second plug region 222. The line b-b′ is a line parallel to the Z axis, passing through the first plug region 221. The first plug region 221 and the second plug region 222 have a first peak 231 and a second peak 232 of the doping concentration.

The dose amount of the second plug region 222 is regarded as D2, and the dose amount of the first plug region 221 is regarded as D1. The dose amount D2 may use a value obtained by integrating the doping concentration from the lower end position Z2 of the second contact portion 212 to the bonding portion 242 of the doping concentration in the depth direction. Similarly, the dose amount D1 may use a value obtained by integrating the doping concentration from the lower end position Z1 of the first contact portion 211 to the bonding portion 241 of the doping concentration in the depth direction. The value obtained by integrating the doping concentration over the predetermined depth distance L2 from the depth position Z1 may be regarded as the dose amount D1. The distance L2 is a distance from the depth position Z2 in the second plug region 222 to the bonding portion 242 in the depth direction, for example. That is, in the first plug region 221 and the second plug region 222, the value obtained by integrating the doping concentration over the same distance L2 may be used as each dose amount. In another example, the value obtained by integrating the doping concentration from the lower end position (Z1 or Z2) of each contact portion to the peak of the doping concentration (the first peak 231 or the second peak 232) may be used as an indicator representing each dose amount. The doping concentration at the peak (the first peak 231 or the second peak 232) of the doping concentration may be used as an indicator representing each dose amount.

The lower end of the first contact portion 211, which is the bottom of the trench contact portion 17, is in direct contact with a region with a doping concentration of the contact region 15 lower than that of the lower end of the second contact portion 212. In this manner, compared to the case where the lower end position Z1 of the first contact portion 211 is at the same depth as the lower end position Z2 of the second contact portion 212, hole implantation from the first mesa portion 61 is suppressed, and the reverse recovery loss reduces. Accordingly, by providing the trench contact portion 17 in the first mesa portion 61 of the transistor portion 70, the reverse recovery loss can be reduced.

As described above, the dose amount D1 and the dose amount D2 may be the same. The dose amounts being the same means that an error of ±20% may be allowed, an error of ±10% may be allowed, and an error of ±5% may be allowed.

The first plug region 221 and the second plug region 222 are formed by exposing the bottom of the first contact portion 211 and the second contact portion 212 and performing ion implantation on the exposed portion. The concentration difference of the doping concentrations of the contact regions 15 of the first contact portion 211 and the second contact portion 212 is sufficiently less than the formed doping concentration of the first peak 231 and the second peak 232.

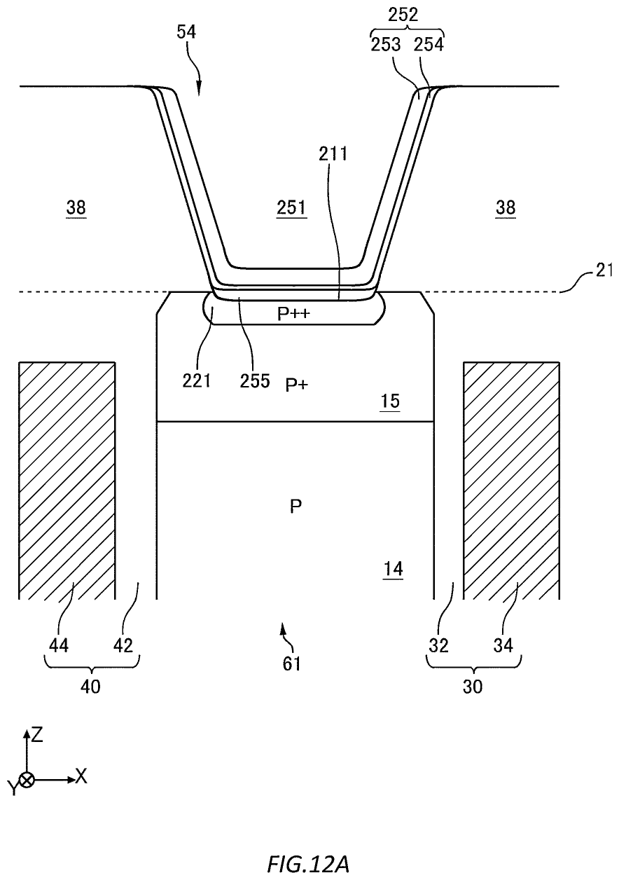

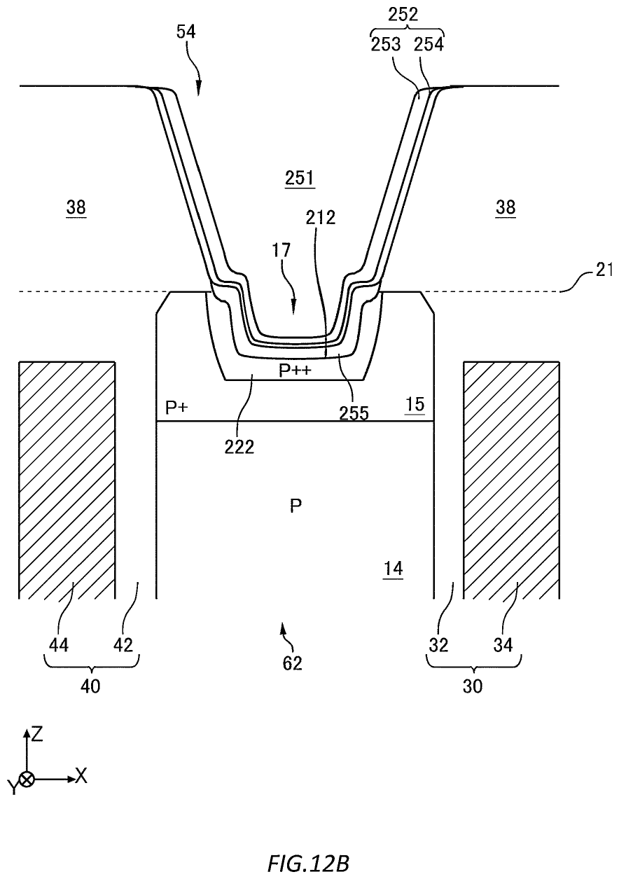

FIG. 12A illustrates an enlarged view in the vicinity of a first contact portion 211. The barrier metal portion 252 in the present example has a first layer 253 and a second layer 254. The first layer 253 is a titanium layer or a titanium nitride layer provided between the upper portion 251 and the semiconductor substrate 10. The second layer 254 is a titanium nitride layer provided between the first layer 253 and the semiconductor substrate 10.

The barrier metal portion 252 of the first mesa portion 61 is provided inside the contact hole 54. The barrier metal portion 252 may contact the semiconductor substrate 10. The barrier metal portion 252 may further have a silicide layer 255. The silicide layer 255 is formed at a position in contact with the semiconductor substrate 10. The silicide layer 255 is a layer in which a part of the second layer 254 is silicided. In the position of the barrier metal portion 252 contacting the semiconductor substrate 10, all the second layer 254 may change to the silicide layer 255 and no more exist.

FIG. 12B illustrates an enlarged view in the vicinity of a second contact portion 212. Similar to the example in the example of FIG. 12A, the barrier metal portion 252 has a first layer 253 and a second layer 254. Also, the barrier metal portion 252 may have a silicide layer 255. The barrier metal portion 252 of the second mesa portion 62 is provided inside the

contact hole 54 and the trench contact portion 17. Therefore, the barrier metal portion 252 of the second mesa portion 62 becomes larger in volume than the barrier metal portion 252 of the first mesa portion 61. The thickness of the barrier metal portion 252 provided on the side wall of the contact hole 54 of the first mesa portion 61 may be the same as the thickness of the barrier metal portion 252 provided on the side wall of the contact hole 54 of the second mesa portion 62. The barrier metal portion 252 of the first mesa portion 61 and the barrier metal portion 252 of the second mesa portion 62 may be formed by the same process.

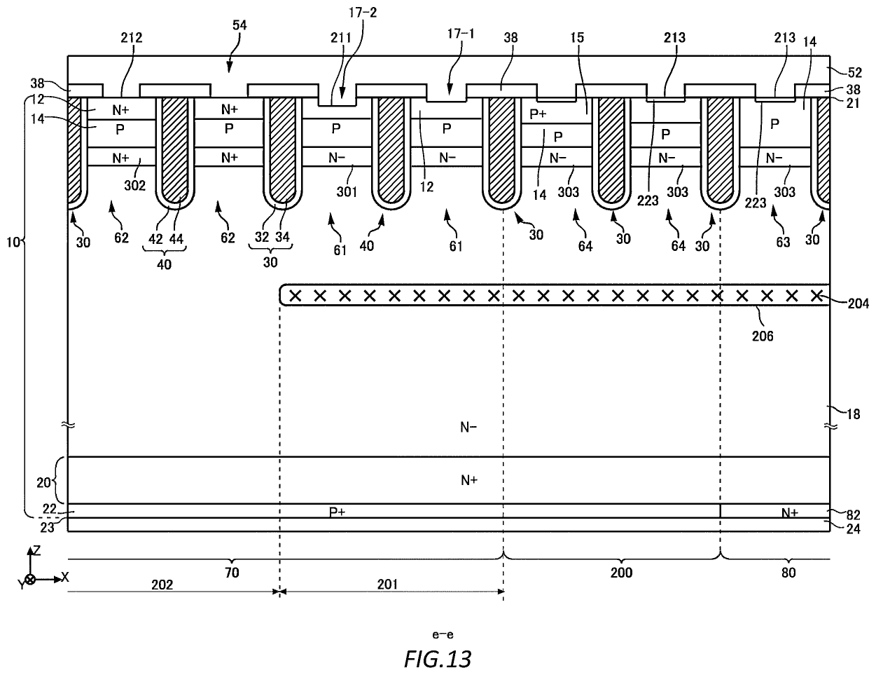

FIG. 13 illustrates a view showing another example of the cross section e-e. In the present example, the adjustment region 201 includes two or more first mesa portions 61 arranged side by side in the X axis direction. The semiconductor device 100 in the present example has a structure of the trench contact portion 17 of the first mesa portion 61 different from that in the other examples described in the present specification. Structures other than the trench contact portion 17 in the first mesa portion 61 are similar to any aspect described in the present specification.

In the present example, the trench contact portion 17-2 of at least one first mesa portion

61 is provided deeper than the trench contact portion 17-1 of the first mesa portion 61 arranged closer to the diode portion 80 than the first mesa portion 61 with the trench contact portion 17-2. The trench contact portion 17 of each first mesa portion 61 may be formed deeper the further away from the diode portion 80. However, the adjustment region 201 may include two or more trench contact portions 17 that are arranged next to each other in the X axis direction at the same depth. With such a structure, the ease of hole extraction in the adjustment region 201 can gradually change.

In another example, the depth of each trench contact portion 17 may be adjusted according to the density of lattice defects 204 in the lower lifetime adjustment region 206. As an example, the lower the density of the lattice defects 204 arranged below, the shallower the trench contact portion 17 may be formed. This makes it easier to offset the variation in the threshold voltage. As an example, if the density of the lattice defects 204 becomes lower as being further away from the diode portion 80, the trench contact portion 17 may be formed shallower as being further away from the diode portion 80.

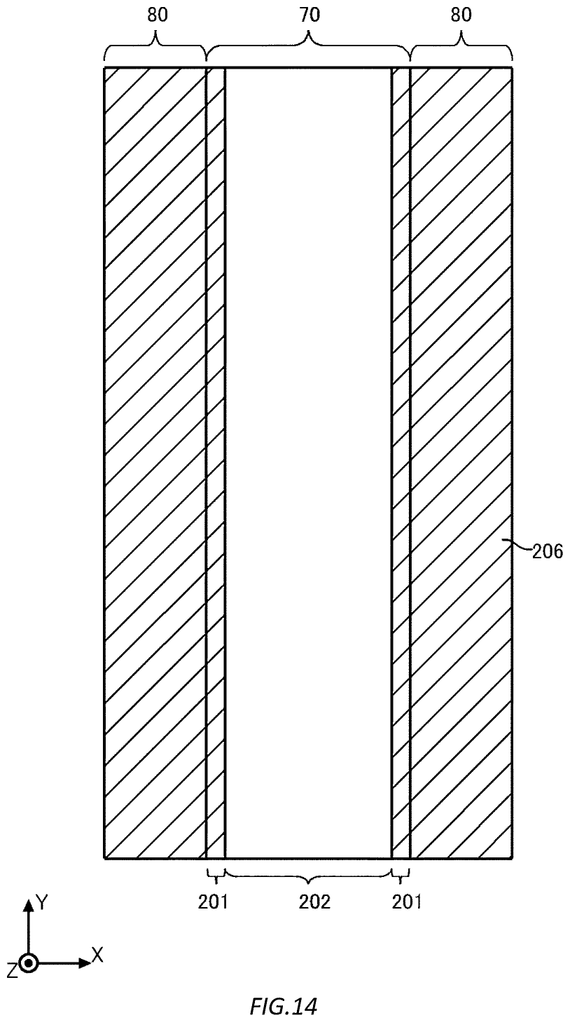

FIG. 14 illustrates an exemplary arrangement of the adjustment region 201 and the non-adjustment region 202 in a top view. The arrangement in the present example may be applied to a semiconductor device 100 according to any aspect described in the present specification. In FIG. 14, two diode portions 80 and one transistor portion 70 are shown, and other regions are omitted. In FIG. 14, the region provided with the lifetime adjustment region 206 is shaded with hatched lines.

The adjustment region 201 may be provided over the entire diode portion 80 in the X axis direction. The adjustment region 201 is provided in a region in contact with the diode portion 80 (or the boundary region 200) in the transistor portion 70. The area of the non-adjustment region 202 in the transistor portion 70 may be greater than the area of the adjustment region 201. In the non-adjustment region 202, the second contact portion 212 is arranged above the first contact portion 211. Therefore, the threshold voltage of the non-adjustment region 202 may be lower than the threshold voltage of the adjustment region 201. In this case, by making the area of the non-adjustment region 202 larger, even if the turn-off of the non-adjustment region 202 is later than the adjustment region 201, current crowding can be suppressed locally.

In the transistor portion 70, the number of the second mesa portions 62 (see FIG. 7 and so on) may be greater than the number of the first mesa portions 61 (see FIG. 7 and so on). In this manner, even if the turn-off of the non-adjustment region 202 is later than the adjustment region 201, current crowding can be suppressed locally. In the transistor portion 70, the threshold voltage of the second mesa portion 62 may be lower than the threshold voltage of the first mesa portion 61. The threshold voltage of each mesa portion can be adjusted by adjusting the depth of the trench contact portions 17 in the first mesa portion 61 and the dose amount of each plug region. The threshold voltage of the mesa portion refers to a voltage at which at least one channel region in the mesa portion transitions from OFF to ON.

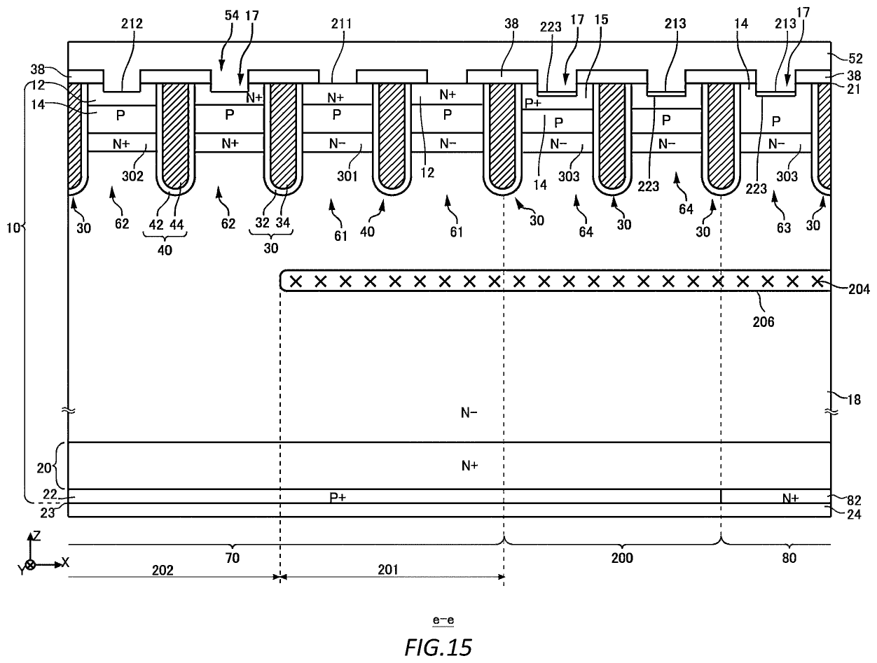

FIG. 15 illustrates a view showing another example of the cross section e-e. The present example is different from the examples described in FIG. 1 to FIG. 6 in a point that the first mesa portion 61 has the first contact portion 211, the second mesa portion 62 has the second contact portion 212, the third mesa portion 63 and the fourth mesa portion 64 have the third contact portion 213. Other structures are similar to those of the examples described in FIG. 1 to FIG. 6.

The first contact portion 211 may be provided with respect to some first mesa portions 61, the first contact portion 211 may also be provided with respect to all the first mesa portions 61. The second contact portion 212 may be provided with respect to some second mesa portions 62, the second contact portion 212 may also be provided with respect to all the second mesa portions 62. The third contact portion 213 may be provided with respect to some third mesa portions 63, the third contact portion 213 may also be provided with respect to all the third mesa portions 63. The third contact portion 213 may be provided with respect to some fourth mesa portions 64, the third contact portion 213 may also be provided to all the fourth mesa portions 64.

In the present example, each contact portion refers to a boundary where the emitter electrode 52 contacts the semiconductor substrate 10. The contact portion may include a surface of the emitter electrode 52 and a surface of the semiconductor substrate 10. When a metal silicide layer is formed at the boundary between the emitter electrode 52 and the semiconductor substrate 10, the metal silicide layer may be included in the emitter electrode 52 (metal electrode). That is, the boundary between the metal silicide layer and the semiconductor substrate 10 may be regarded as the contact portion.

In at least a part of the mesa portions 60, the trench contact portion 17 may be provided. The trench contact portion 17 is a portion where the metal electrode of the emitter electrode 52 or the like is provided inside the semiconductor substrate 10. The trench contact portion 17 can be formed by forming a groove on the upper surface 21 of the semiconductor substrate 10 that is exposed via the contact hole 54, and filling the metal electrode inside the groove. In the mesa portion 60 provided with the trench contact portion 17, the region, in the trench contact portion 17, where the mesa portion 60 contacts the metal electrode of the emitter electrode 52 or the like corresponds to the contact portion. In the example of FIG. 15, the trench contact portion 17 is provided in the second mesa portion 62, the third mesa portion 63, and the fourth mesa portion 64.

In at least a part of the mesa portions 60, the plug region may be provided in the region that contacts the lower end of the contact portion. The plug region may be a region of a P++ type with a doping concentration higher than that of the contact region 15. In the example of FIG. 15, a third plug region 223 in direct contact with the third contact portion 213 is provided.

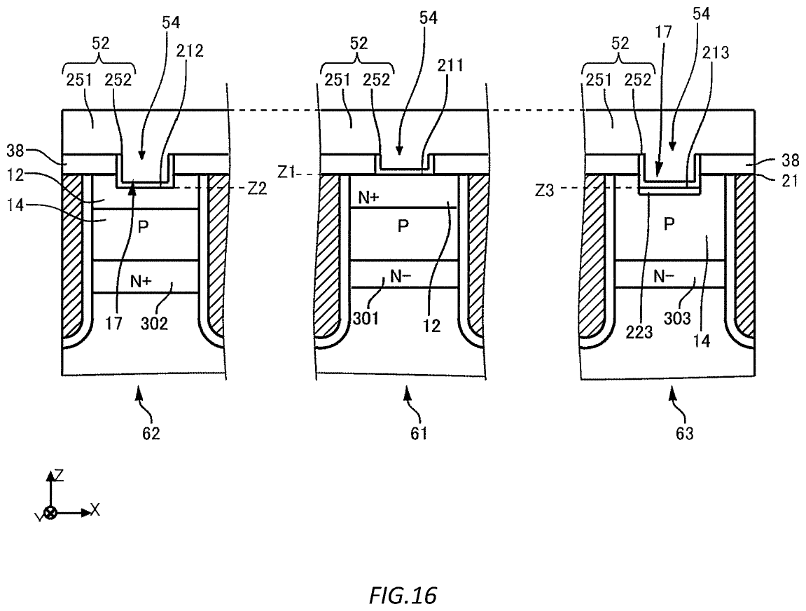

FIG. 16 illustrates enlarged views near the first mesa portion 61, the second mesa portion 62, and the third mesa portion 63. In FIG. 16, the first mesa portion 61, the second mesa portion 62, and the third mesa portion 63 are shown respectively, and the regions between each mesa portions are omitted.

The emitter electrode 52 (metal electrode) of the present example includes a barrier metal portion 252 and an upper portion 251. The barrier metal portion 252 is provided above the upper surface 21 of the semiconductor substrate 10. The barrier metal portion 252 is provided on the bottom surface of at least either of the contact hole 54 or the trench contact portion 17. The barrier metal portion 252 may be provided at the lower end of each contact portion. The barrier metal portion 252 may contact the semiconductor substrate 10. The barrier metal portion 252 may be provided on a side surface of the contact hole 54 and the trench contact portion 17. The barrier metal portion 252 may be provided or may also be not provided on the upper surface of the interlayer insulating film 38.

The barrier metal portion 252 is formed of a material that absorbs more hydrogen than the upper portion 251. With this configuration, entry of hydrogen ions into the semiconductor substrate 10 is suppressed. The barrier metal portion 252 in the present example contains titanium. The barrier metal portion 252 may include a titanium nitride layer. The barrier metal portion 252 may be a stacked film of a titanium layer and a titanium nitride layer.

The upper portion 251 is provided above the barrier metal portion 252. The upper portion 251 is also provided above the interlayer insulating film 38. The upper portion 251 is formed of a material different from that of the barrier metal portion 252. In the present example, the upper portion 251 does not contain titanium. As an example, the upper portion 251 contains aluminum. The upper portion 251 may be an alloy of aluminum and silicon. Inside the contact hole 54 or the trench contact portions 17, the upper portion 251 may contain a plug portion formed of tungsten, or the plug portion may be provided above the interlayer insulating film 38.

The depth position of the lower end of the first contact portion 211 is regarded as Z1, the depth position of the lower end of the second contact portion 212 is regarded as Z2, and the depth position of the lower end of the third contact portion 213 is regarded as Z3. The lower end of each contact portion refers to the portion arranged lowest at the boundary where the metal electrode contacts the semiconductor substrate 10. The depth position Z2 is arranged above the depth position Z1. That is, the depth position Z1 is away from the upper surface 21 of the semiconductor substrate 10 further than the depth position Z2. In the example of FIG. 16, the depth position Z1 is a position below the upper surface 21 of the semiconductor substrate 10, and the depth position Z2 is a depth position with a depth identical to the upper surface 21 of the semiconductor substrate 10. In another example, the depth position Z2 may be located between the depth position Z1 and the upper surface 21 of the semiconductor substrate 10. In this case, taking the upper surface 21 of the semiconductor substrate 10 as reference, the depth position Z2 may be at half or less, or may be at 1/4 or less of the depth position Z1.

The adjustment region 201 is irradiated with charged particles from the upper surface 21 to form the lifetime adjustment region 206 (see FIG. 15). On the other hand, the irradiation of charged particles may form a level in the gate insulating film 42 in the adjustment region 201, causing the threshold voltage (ON voltage and OFF voltage) in the adjustment region 201 to be lower than the threshold voltage in the non-adjustment region 202. As the threshold voltage decreases, the turn-off timing is delayed, so the turn-off in the adjustment region 201 is later than in the non-adjustment region 202, and the current crowding may occur in the adjustment region 201, resulting in a decrease in the withstand capability.

In the semiconductor device 100 of the present example, the depth position Z2 of the second contact portion 212 is made deeper than the depth position Z1 of the first contact portion 211. In this manner, it is easy to make the volume of the barrier metal portion 252 in one second mesa portion 62 larger than the volume of the barrier metal portion 252 in one first mesa portion 61. The volume of the barrier metal portion 252 in one mesa portion refers to the volume of the barrier metal portion 252 provided inside the trench contact portions 17 and the contact hole 54 above the mesa portion.

The manufacturing process of the semiconductor device 100 includes process of annealing the semiconductor substrate 10 in a hydrogen atmosphere, for example. The process allows oxygen to penetrate into the semiconductor substrate 10 and the insulating film, terminating defects. This suppresses the decrease in the threshold voltage.

Since the barrier metal portion 252 absorbs hydrogen, hydrogen penetration is suppressed in the second mesa portion 62, where more barrier metal portions 252 are formed, compared to the first mesa portion 61. Therefore, the threshold voltage of the second mesa portion 62 is lower when compared to that of the first mesa portion 61, and the threshold voltage of the first mesa portion 61 can be relatively higher. This can offset the decrease in the threshold voltage of the first mesa portion 61 due to the formation of the lifetime adjustment region 206. The volume of the barrier metal portion 252 in one second mesa portion 62 may be 1.1 time or more, or 1.2 times or more, or 1.5 times or more of the volume of the barrier metal portion 252 in one first mesa portion 61.

The lower end of the first contact portion 211 of the present example is arranged above the third contact portion 213. The depth position Z3 of the third contact portion 213 may be at the same depth as the depth position Z2 of the second contact portion 212, or may be arranged between the depth position Z2 and the depth position Z1. The depth position Z3 of the third contact portion 213 may be at the same depth as the depth position Z1 of the first contact portion 211.

The third mesa portion 63 may be provided to contact the lower end of the third contact portion 213, and have a third plug region 223 of the P++ type with a higher doping concentration than the base region 14 (anode region). The third plug region 223 may have a higher doping concentration than the contact region 15. The doping concentration of the base region 14 (anode region) of the third mesa portion 63 may be lower than the doping concentration of the base region 14 of the transistor portion 70. In this case, the implantation of holes from the third mesa portion 63 to the drift region 18 can be suppressed.

As shown in FIG. 15, both of the trench contact portions 17 and the second region 302 are provided in at least one second mesa portion 62. All the second mesa portions 62 may have both of the trench contact portions 17 and the second region 302 provided therein. In another example, some second mesa portions 62 may have the second region 302 but be without the trench contact portions 17. Also, some second mesa portions 62 may have the trench contact portions 17 but be without the second region 302.

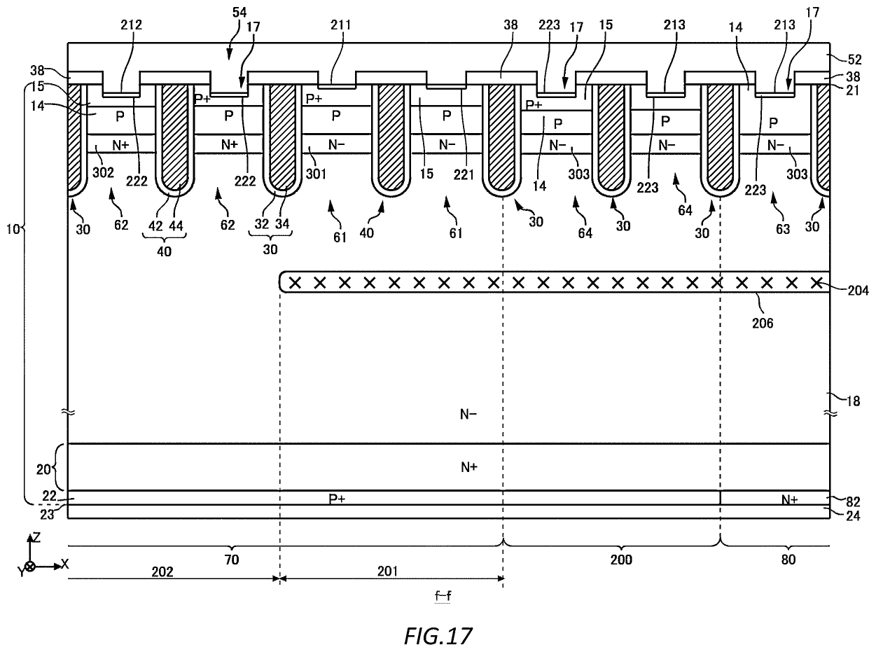

FIG. 17 illustrates an example of a cross section f-f in FIG. 2. The cross section f-f is an XZ plane passing through the contact region 15 and the cathode region 82. In the cross section f-f, a contact region 15 is arranged instead of the emitter region 12 in the cross section e-e as shown in FIG. 15. Other structures are similar to the cross section e-e. Also in the cross section f-f, the structures of the first contact portion 211, the second contact portion 212 and the third contact portion 213 are similar to those in the cross section e-e.

The first mesa portion 61 in the present example is provided to contact the lower end of the first contact portion 211, and has a first plug region 221 of the P++ type with a higher doping concentration than the contact region 15. At least a part of the first plug region 221 is provided to overlap the contact region 15 in a top view. That is, the first plug region 221 is provided in any XZ cross section passing through the contact region 15. The first plug region 221 may be provided in the XZ cross section passing through the center in the Y axis direction of the contact region 15. A part of the first plug region 221 may overlap the emitter region 12 in the top view. The first plug region 221 may be provided in the end region of the emitter region 12 that contacts the contact region 15. The first plug region 221 may not be provided in any XZ cross section passing through the emitter region 12. For example, the first plug region 221 is not provided in the XZ cross section passing through the center in the Y axis direction of the emitter region 12. The entire first plug region 221 may be provided to overlap the contact region 15. In this case, the first plug region 221 does not overlap the emitter region 12 in the top view.

The second mesa portion 62 in the present example is provided to contact the lower end of the second contact portion 212, and has a second plug region 222 of the P++ type with a higher doping concentration than the contact region 15. At least a part of the second plug region 222 is provided to overlap the contact region 15 in a top view. That is, the second plug region 222 is provided in any XZ cross section passing through the contact region 15. The second plug region 222 may be provided in the XZ cross section passing through the center in the Y axis direction of the contact region 15. A part of the second plug region 222 may overlap the emitter region 12 in the top view. The second plug region 222 may be provided in the end region of the emitter region 12 that contacts the contact region 15. The second plug region 222 may not be provided in any XZ cross section passing through the emitter region 12. For example, the second plug region 222 is not provided in the XZ cross section passing through the center in the Y axis direction of the emitter region 12. The entire second plug region 222 may be provided to overlap the contact region 15. In this case, the second plug region 222 does not overlap the emitter region 12 in the top view. By providing each plug region, it is easier to extract holes in each mesa portion. Therefore, it is possible to suppress reduction in withstand capability.

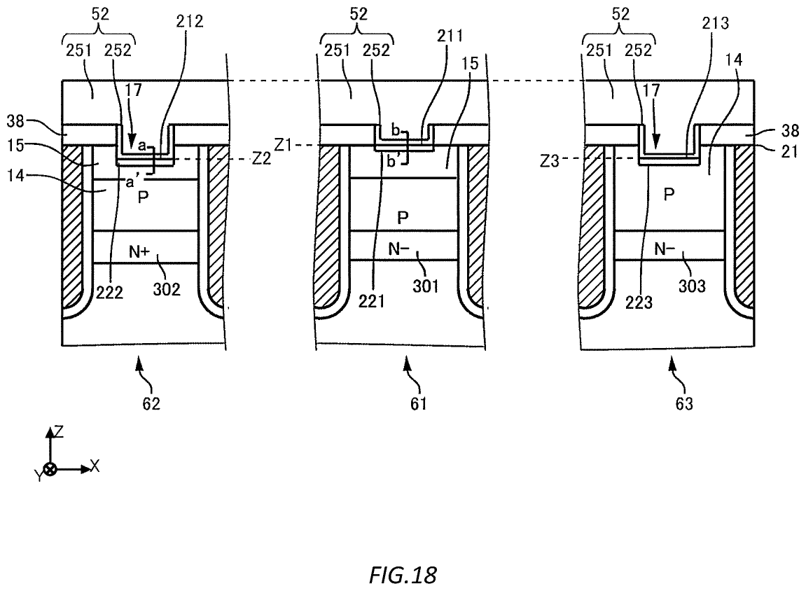

FIG. 18 illustrates enlarged views near the first mesa portion 61, the second mesa portion 62, and the third mesa portion 63 shown in FIG. 17. In FIG. 18, the first mesa portion 61, the second mesa portion 62, and the third mesa portion 63 are shown one by one respectively, and the regions between the each mesa portions are omitted. The structure of the third mesa portion 63 is similar to that of the third mesa portion 63 shown in FIG. 16.

The first mesa portion 61 has a contact region 15 instead of the emitter region 12 and a first plug region 221 contacting the lower end of the first contact portion 211 with respect to the structure shown in FIG. 16. Other structures are similar to those of the example shown in FIG. 16. The second mesa portion 62 has a contact region 15 instead of the emitter region 12 and a second plug region 222 contacting the lower end of the second contact portion 212 with respect to the structure shown in FIG. 16. Other structures are similar to those of the example shown in FIG. 16.

The first plug region 221 may be provided up to a region lower than the second plug region 222.

Each plug region is a region of the P++ type with a high concentration. The first plug region 221 and the second plug region 222 may be formed by implantation of impurities by different dose amounts (/cm²). The first plug region 221 and the second plug region 222 may also be formed by implantation of impurities by the same dose amount. This allows for manufacturing the semiconductor device by easy process.

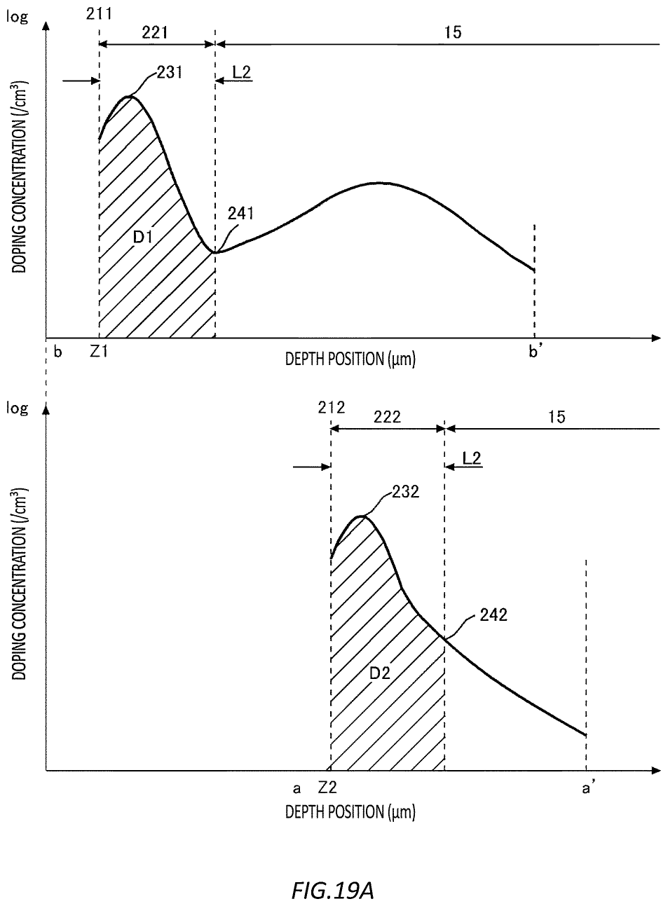

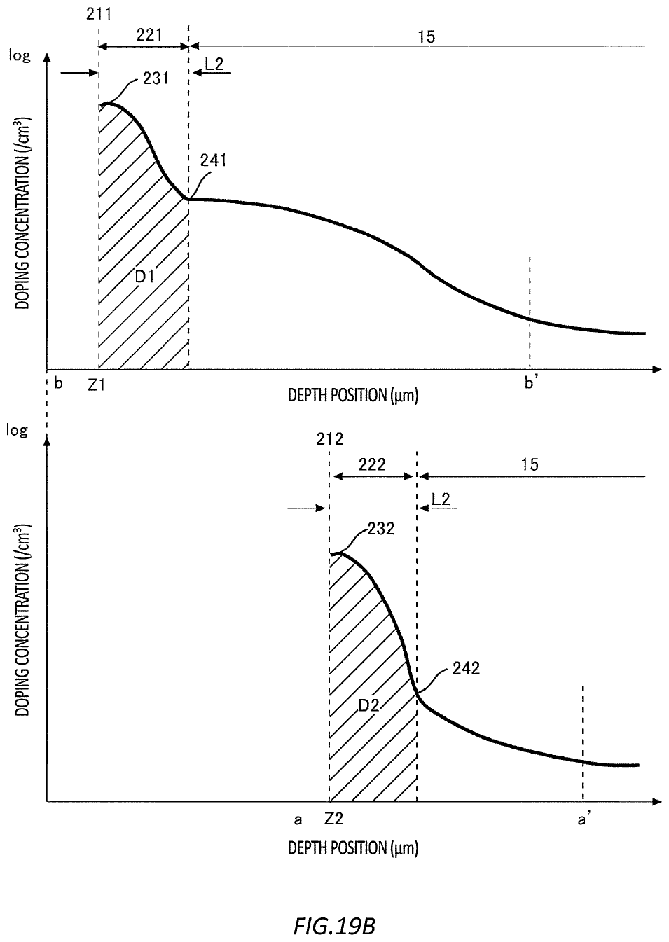

FIG. 19A illustrates an example of a doping concentration distribution on a line a-a′ and a line b-b′ in FIG. 18. The line a-a′ is a line parallel to the Z axis, passing through the second plug region 222. The line b-b′ is a line parallel to the Z axis, passing through the first plug region 221. The first plug region 221 and the second plug region 222 have a first peak 231 and a second peak 232 of the doping concentration. The first plug region 221 has a bonding portion 241 of the doping concentration in the boundary with the contact region 15. The second plug region 222 in the present example may not have a valley portion of the doping concentration in the boundary with the contact region 15, but may have a bonding portion 241 that becomes a valley portion.

The dose amount of the second plug region 222 is regarded as D2, and the dose amount of the first plug region 221 is regarded as D1. The dose amount D1 may use a value obtained by integrating the doping concentration from the lower end position Z1 of the first contact portion 211 to the bonding portion 241 of the doping concentration in the depth direction. Similarly, the dose amount D2 may use a value obtained by integrating the doping concentration from the lower end position Z2 of the second contact portion 212 to the bonding portion 242 of the doping concentration in the depth direction. When there does not exist a valley portion of the doping concentration in the boundary between the second plug region 222 and the contact region 15, the value obtained by integrating the doping concentration over a predetermined depth distance L2 from the depth position Z2 may be regarded as the dose amount D2. The distance L2 is a distance from the depth position Z1 in the first plug region 221 to the bonding portion 241 in the depth direction, for example. That is, in the first plug region 221 and the second plug region 222, the value obtained by integrating the doping concentration over the same distance L2 may be used as each dose amount. In another example, the value obtained by integrating the doping concentration from the lower end position (Z1 or Z2) of each contact portion to the peak of the doping concentration (the peak 231 or the peak 232) may be used as an indicator representing each dose amount. The doping concentration at the peak (the peak 231 or the peak 232) of the doping concentration may be used as an indicator representing each dose amount.

As described above, the dose amount D1 and the dose amount D2 may be the same. The dose amounts being the same means that an error of +20% may be allowed, an error of +10% may be allowed, and an error of +5% may be allowed. Although the first plug region 221 and the second plug region 222 are formed by exposing the first contact portion 211 and the second contact portion 212 and performing ion implantation, the difference of the doping concentrations of the contact regions 15 of the first contact portion 211 and the second contact portion 212 is sufficiently less than the doping concentrations of the formed first peak 231 and second peak 232.

FIG. 19B illustrates an example of a doping concentration distribution on a line a-a′ and a line b-b′ in FIG. 18. The line a-a′ is a line parallel to the Z axis, passing through the second plug region 222. The line b-b′ is a line parallel to the Z axis, passing through the first plug region 221. The first plug region 221 and the second plug region 222 have a first peak 231 and a second peak 232 of the doping concentration.

The dose amount of the second plug region 222 is regarded as D2, and the dose amount of the first plug region 221 is regarded as D1. The dose amount D1 may use a value obtained by integrating the doping concentration from the lower end position Z1 of the first contact portion 211 to the bonding portion 241 of the doping concentration in the depth direction. Similarly, the dose amount D2 may use a value obtained by integrating the doping concentration from the lower end position Z2 of the second contact portion 212 to the bonding portion 242 of the doping concentration in the depth direction. The value obtained by integrating the doping concentration over the predetermined depth distance L2 from the depth position Z2 may be regarded as the dose amount D2. The distance L2 is a distance from the depth position Z1 in the first plug region 221 to the bonding portion 241 in the depth direction, for example. That is, in the first plug region 221 and the second plug region 222, the value obtained by integrating the doping concentration over the same distance L2 may be used as each dose amount. In another example, the value obtained by integrating the doping concentration from the lower end position (Z1 or Z2) of each contact portion to the peak of the doping concentration (the first peak 231 or the second peak 232) may be used as an indicator representing each dose amount. The doping concentration at the peak (the first peak 231 or the second peak 232) of the doping concentration may be used as an indicator representing each dose amount.

The lower end of the first contact portion 211 is in contact with a region with a doping concentration of the contact region 15 higher than that of the second contact portion 212 that is the bottom of the trench contact portions 17. Accordingly, when compared to a case where the lower end position Z1 of the first contact portion 211 is at depth identical to the lower end position Z2 of the second contact portion 212, hole implantation from the first mesa portion 61 becomes more, and the forward voltage reduces. Therefore, by providing the trench contact portions 17 in the first mesa portion 61 of the transistor portion 70, trade-off between reverse recovery loss and the forward voltage can be adjusted.

As described above, the dose amount D1 and the dose amount D2 may be the same. The dose amounts being the same means that an error of ±20% may be allowed, an error of ±10% may be allowed, and an error of ±5% may be allowed. Although the first plug region 221 and the second plug region 222 are formed by exposing the first contact portion 211 and the second contact portion 212 and performing ion implantation, the difference of the doping concentrations of the contact regions 15 of the first contact portion 211 and the second contact portion 212 is sufficiently less than the doping concentrations of the formed first peak 231 and second peak 232.

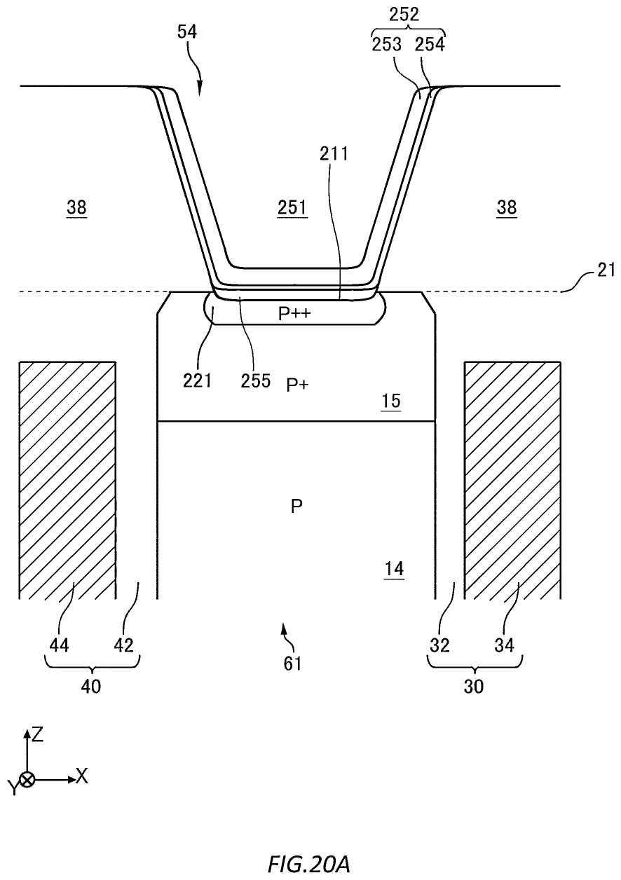

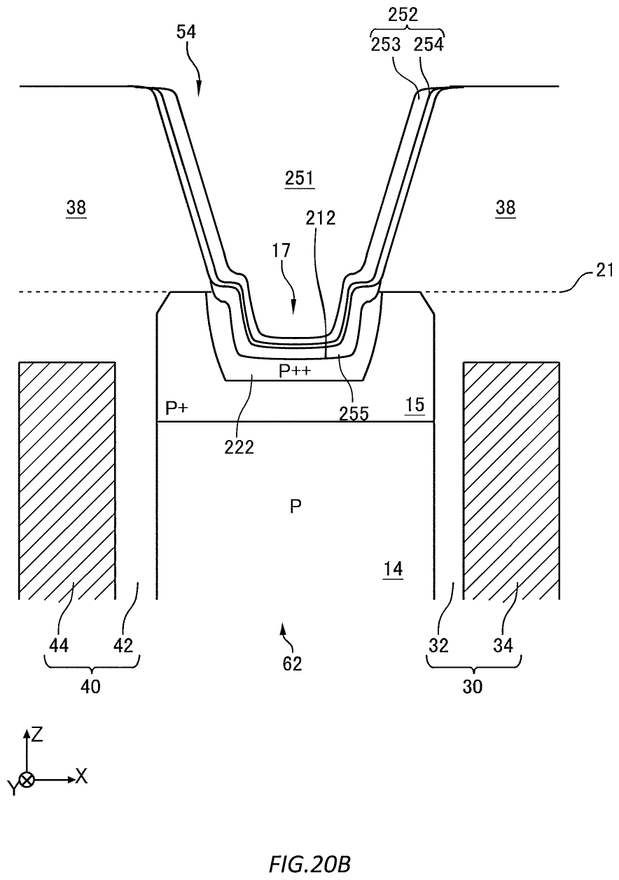

FIG. 20A is an enlarged view of the vicinity of the first contact portion 211 shown in FIG. 16. The first contact portion 211 may have a structure similar to the example shown in FIG. 12A. The barrier metal portion 252 in the present example has a first layer 253 and a second layer 254. The first layer 253 is a titanium layer or a titanium nitride layer provided between the upper portion 251 and the semiconductor substrate 10. The second layer 254 is a titanium nitride layer provided between the first layer 253 and the semiconductor substrate 10.

The barrier metal portion 252 of the first mesa portion 61 is provided inside the contact hole 54. The barrier metal portion 252 may contact the upper surface 21 of the semiconductor substrate 10. The barrier metal portion 252 may further have a silicide layer 255. The silicide layer 255 is formed at a position in contact with the semiconductor substrate 10. The silicide layer 255 is a layer in which a part of the second layer 254 is silicided. In the position of the barrier metal portion 252 contacting the upper surface 21 of the semiconductor substrate 10, all the second layer 254 may change to the silicide layer 255 and no more exist.

FIG. 20B is an enlarged view of the vicinity of the second contact portion 212 shown in FIG. 16. The second contact portion 212 may have a structure similar to that of the example of FIG. 12B. Similar to the example of FIG. 20A, the barrier metal portion 252 has a first layer 253 and a second layer 254. The barrier metal portion 252 may further have a silicide layer 255.

The barrier metal portion 252 of the second mesa portion 62 is provided inside the contact hole 54 and the trench contact portion 17. Therefore, the barrier metal portion 252 of the second mesa portion 62 becomes larger in volume than the barrier metal portion 252 of the first mesa portion 61. The thickness of the barrier metal portion 252 provided on the side wall of the contact hole 54 of the first mesa portion 61 may be the same as the thickness of the barrier metal portion 252 provided on the side wall of the contact hole 54 of the second mesa portion 62. The barrier metal portion 252 of the first mesa portion 61 and the barrier metal portion 252 of the second mesa portion 62 may be formed by the same process.

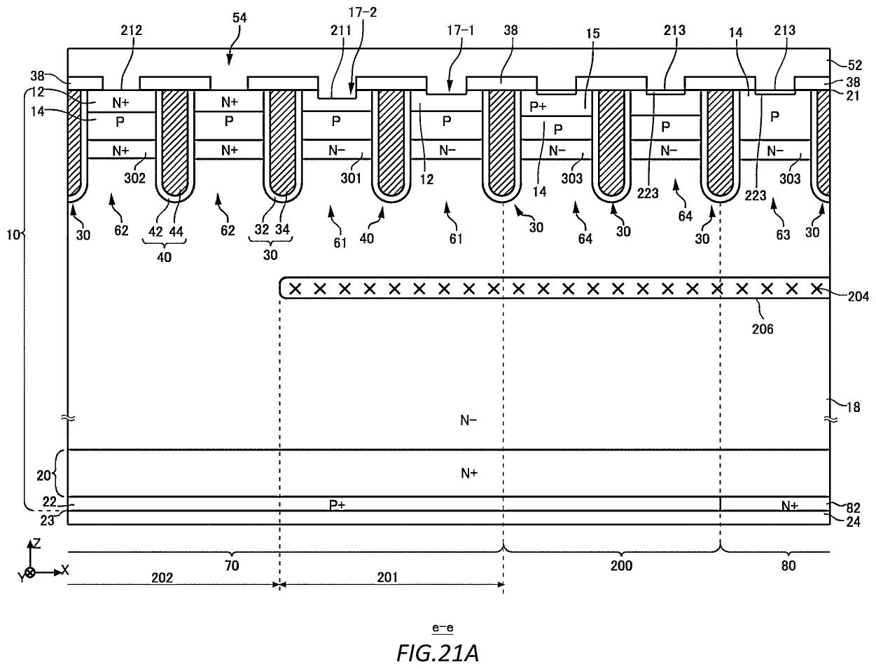

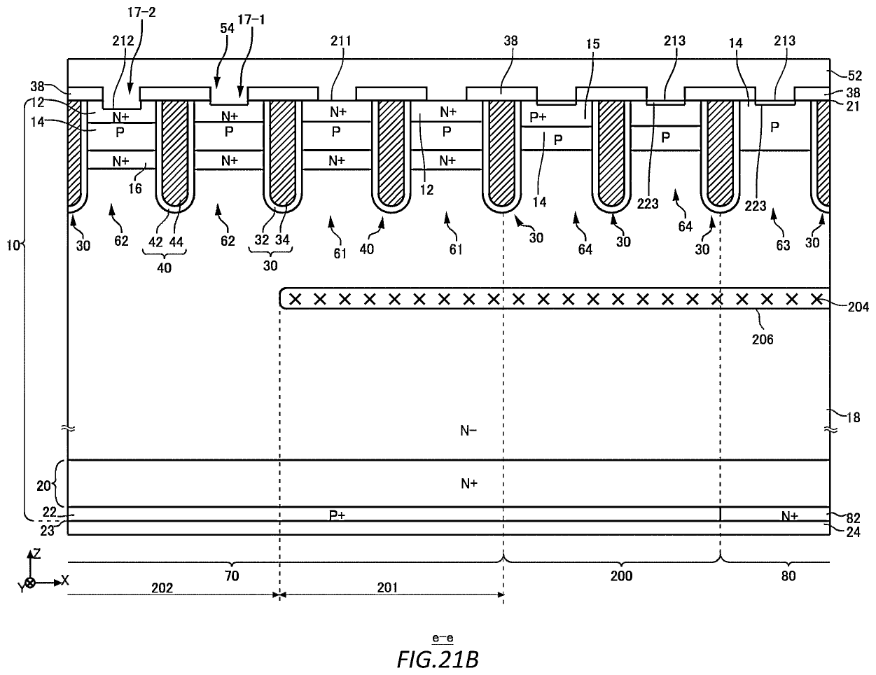

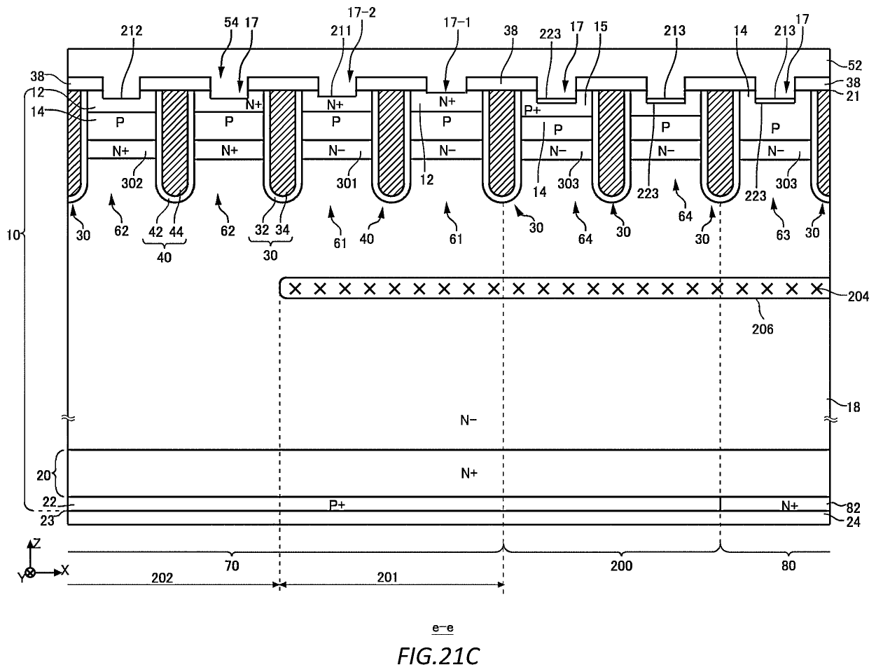

FIG. 21A illustrates another example of the cross section e-e. In the present example, the adjustment region 201 includes two or more first mesa portions 61 arranged side by side in the X axis direction. The semiconductor device 100 in the present example has a structure of the trench contact portion 17 of the first mesa portion 61 different from that in the other examples described in the present specification. Structures other than the trench contact portion 17 in the first mesa portion 61 are similar to any aspect described in the present specification.

In the present example, the trench contact portion 17-2 of at least one first mesa portion 61 is provided deeper than the trench contact portion 17-1 of the first mesa portion 61 arranged closer to the diode portion 80 than the first mesa portion 61 with the trench contact portion 17-2. The trench contact portion 17 of each first mesa portion 61 may be formed deeper the further away from the diode portion 80. However, the adjustment region 201 may include two or more trench contact portions 17 that are arranged next to each other in the X axis direction at the same depth. With such a structure, the volume of the barrier metal portion 252 in the first mesa portion 61 can change gradually.

In another example, the depth of each trench contact portion 17 may be adjusted according to the density of lattice defects 204 in the lower lifetime adjustment region 206. As an example, the lower the density of the lattice defects 204 arranged below, the deeper the trench contact portion 17 may be formed. The deeper the trench contact portion 17 is formed, the larger the volume of the barrier metal portion 252 is. This makes it easier to offset the variation in the threshold voltage. As an example, if the density of the lattice defects 204 becomes lower as being further away from the diode portion 80, the trench contact portion 17 may be formed deeper as being further away from the diode portion 80.

FIG. 21B illustrates a view showing another example of the cross section e-e. In the present example, the non-adjustment region 202 includes two or more second mesa portions 62 arranged side by side in the X axis direction. The semiconductor device 100 in the present example has a structure of the trench contact portion 17 of the second mesa portion 62 different from that in the other examples described in the present specification. Structures other than the trench contact portion 17 in the second mesa portion 62 are similar to any aspect described in the present specification.

In the present example, the trench contact portion 17-2 of at least one second mesa portion 62 is provided deeper than the trench contact portion 17-1 of the second mesa portion 62 arranged closer to the diode portion 80 than the second mesa portion 62. The trench contact portion 17 of each second mesa portion 62 may be formed deeper the further away from the diode portion 80. However, the non-adjustment region 202 may include two or more trench contact portions 17 that are arranged next to each other in the X axis direction at the same depth. With such a structure, the volume of the barrier metal portion 252 in the second mesa portion 62 can change gradually.

FIG. 21C illustrates another example of the cross section e-e. In the present example, the adjustment region 201 includes two or more first mesa portions 61 arranged side by side in the X axis direction. The semiconductor device 100 in the present example has a structure of the trench contact portion 17 of the first mesa portion 61 different from that in the other examples described in the present specification. Structures other than the trench contact portion 17 in the first mesa portion 61 are similar to any aspect described in the present specification.

In the present example, the trench contact portion 17-2 of at least one first mesa portion 61 is provided deeper than the trench contact portion 17-1 of the first mesa portion 61 arranged closer to the diode portion 80 than the first mesa portion 61 with the trench contact portion 17-2. The trench contact portion 17 of each first mesa portion 61 may be formed deeper the further away from the diode portion 80. However, the adjustment region 201 may include two or more trench contact portions 17 that are arranged next to each other in the X axis direction at the same depth. With such a structure, the volume of the barrier metal portion 252 in the first mesa portion 61 can change gradually.

In another example, the depth of each trench contact portion 17 may be adjusted according to the density of lattice defects 204 in the lower lifetime adjustment region 206. As an example, the lower the density of the lattice defects 204 arranged below, the deeper the trench contact portion 17 may be formed. The deeper the trench contact portion 17 is formed, the larger the volume of the barrier metal portion 252 is. This makes it easier to offset the variation in the threshold voltage. As an example, if the density of the lattice defects 204 becomes lower as being further away from the diode portion 80, the trench contact portion 17 may be formed deeper as being further away from the diode portion 80.

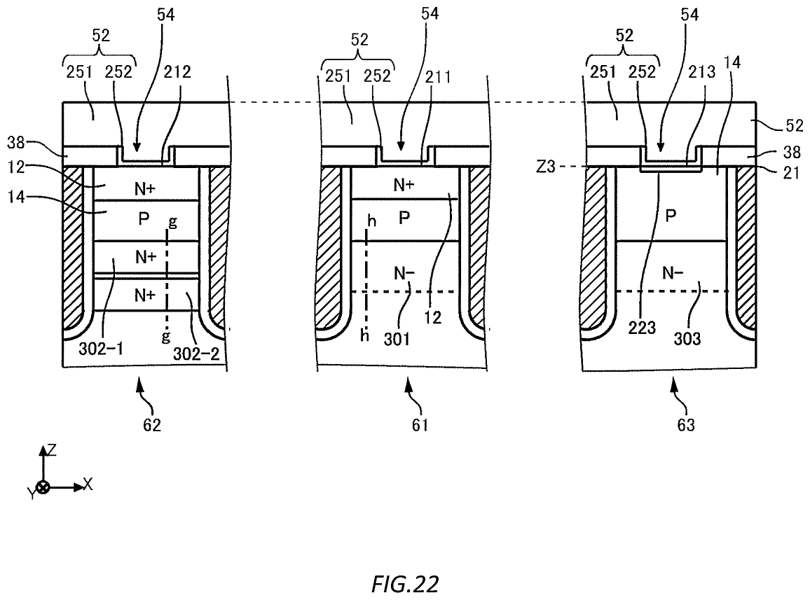

FIG. 22 illustrates another configuration example of the first mesa portion 61, the second mesa portion 62 and the third mesa portion 63. The second mesa portion 62 of the present example has a plurality of second regions 302 in the depth direction. Each second region 302 has a peak of the doping concentration in the depth direction. The second mesa portion 62 in the present example has a second region 302-1 and a second region 302-2.

The first mesa portion 61 in the present example has the first regions 301 in a number less than the number of the second regions 302 of the second mesa portion 62. In FIG. 22, the first mesa portion 61 has one first region 301. The doping concentration of the first region 301 in the present example is the same as that of the drift region 18. The doping concentration in the depth direction of the first region 301 in the present example may be constant.

The third mesa portion 63 in the present example has the third regions 303 in a number less than the number of the second regions 302 of the second mesa portion 62. The doping concentration of the third region 303 in the present example is similar to the first region 301.

Structures other than the first region 301, the second region 302 and the third region 303 are similar to any form described in the present specification. For example, in the example of FIG. 22, although each mesa portion does not have the trench contact portion 17, each mesa portion may have trench contact portion 17 similar to any form described in the present specification.

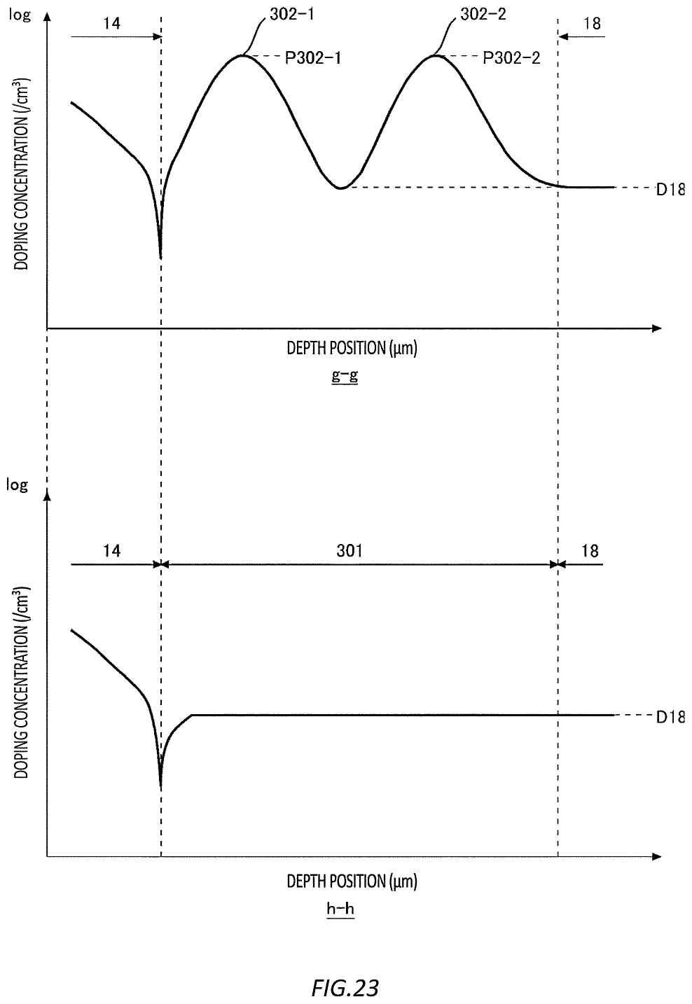

FIG. 23 illustrates an example of doping concentration distributions on a line g-g and a line h-h of FIG. 22. The line g-g is a line parallel to the Z axis that extends from the base region 14 to the drift region 18 in the second mesa portion 62. The line h-h is a line parallel to the Z axis that extends from the base region 14 to the drift region 18 in the first mesa portion 61. In the present specification, the doping concentration of the drift region 18 is regarded as D18. In the present example, the number of peaks of the doping concentration in the depth direction of the second region 302 of the second mesa portion 62 is greater than the number of peaks of the doping concentration in the depth direction of the first region 301 of the first mesa portion 61. The number of peaks in the first region 301 may be 0.

The second mesa portion 62 in the present example has a second region 302-1 and a second region 302-2 in sequence from the upper surface 21 side. The second region 302-1 and the second region 302-2 each have a peak of the doping concentration. That is, the number of peaks of the doping concentration of the second region 302 in the present example is two. The doping concentration P302-1 of the second region 302-1 may be the same as, or may be different from the doping concentration P302-2 of the second region 302-2.

There exists a valley portion indicating a local minimum value of the doping concentration between the second region 302-1 and the second region 302-2. The doping concentration of the valley portion may be the same as that of the drift region 18. In another example, the doping concentration of the valley portion may be higher than that of the drift region 18.

The first mesa portion 61 in the present example has a first region 301 with a doping concentration identical to that of the drift region 18. In the present example, the number of peaks of the doping concentration in the first region 301 is 0. According to the present example, hole implantation in the transistor portion 70 near the diode portion 80 can be adjusted, the decrease of the withstand capability can be suppressed, and trade-off between reverse recovery loss and the forward voltage can be adjusted.

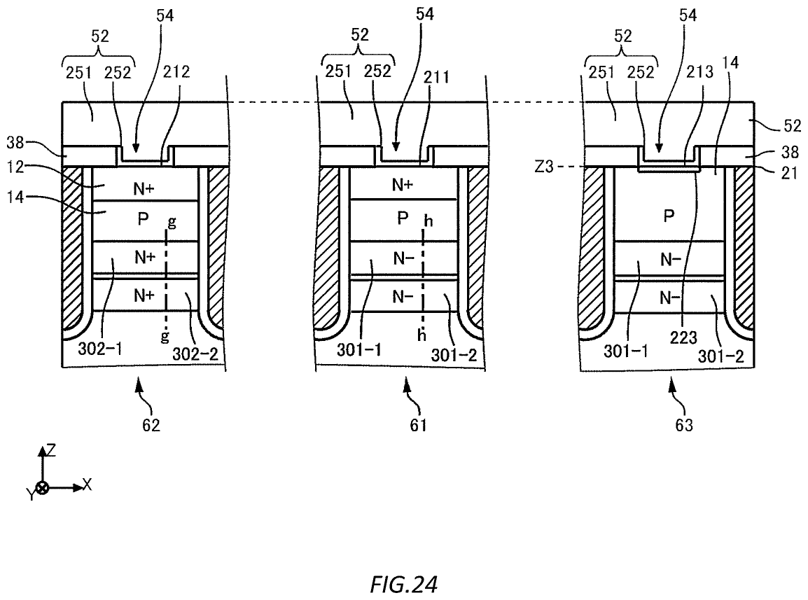

FIG. 24 illustrates another configuration example of the first mesa portion 61, the second mesa portion 62 and the third mesa portion 63. The second mesa portion 62 of the present example is similar to the example of FIG. 22. The first mesa portion 61 in the present example has a plurality of first regions 301 in the depth direction. Each first region 301 has a peak of the doping concentration in the depth direction. The first mesa portion 61 in the present example has a first region 301-1 and a first region 301-2.

The third mesa portion 63 in the present example has the first regions 301 (or the third regions 303) in a number identical to the first mesa portions 61.

Structures other than the first region 301, the second region 302 and the third region 303 are similar to any form described in the present specification.

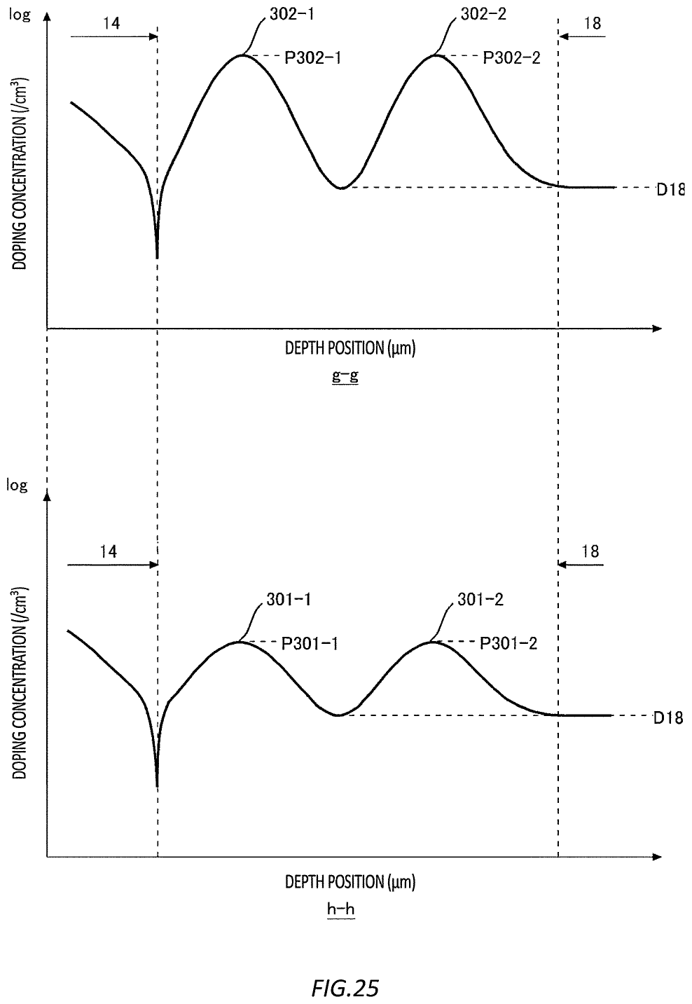

FIG. 25 illustrates an example of doping concentration distributions on a line g-g and a line h-h of FIG. 24. The doping concentration distribution in the second mesa portion 62 in the present example is similar to the example shown in FIG. 23.

The first mesa portion 61 in the present example has the first region 301-1 and the first region 301-2 in sequence from the upper surface 21 side. The number of the first regions 301 in the first mesa portion 61 may be the same, or may be different from the number of the second regions 302 in the second mesa portion 62.

The first region 301-1 and the first region 301-2 each have a peak of the doping concentration. The doping concentration P301-1 of the first region 301-1 may be the same, or may be different from the doping concentration P301-2 of the first region 301-2. The doping concentration P301-1 of the first region 301-1 may be lower than any of the doping concentration P302-1 of the second region 302-1 or the doping concentration P302-2 of the second region 302-2. The doping concentration P301-2 of the first region 301-2 is lower than any of the doping concentration P302-1 of the second region 302-1 or the doping concentration P302-2 of the second region 302-2. The doping concentration P301-1 may be half or less, or may be 1/10 or less of the doping concentration P302-1. The doping concentration P301-2 may be half or less, or may be 1/10 or less of the doping concentration P302-2.

A valley portion indicating a local minimum value of the doping concentration exists between the first region 301-1 and the first region 301-2. The doping concentration of the valley portion may be the same as that of the drift region 18. In another example, the doping concentration of the valley portion may be higher than that of the drift region 18. According to the present example, hole implantation in the transistor portion 70 near the diode portion 80 can be adjusted, the decrease of the withstand capability can be suppressed, and trade-off between reverse recovery loss and the forward voltage can be adjusted.

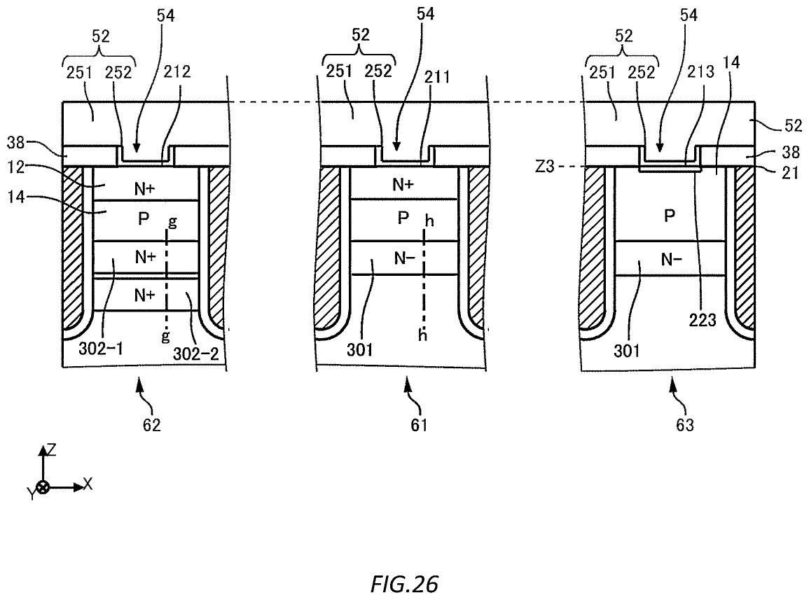

FIG. 26 illustrates another configuration example of the first mesa portion 61, the second mesa portion 62 and the third mesa portion 63. The second mesa portion 62 in the present example is similar to the example shown in FIG. 22. The first mesa portion 61 in the present example has one or more first regions 301 in the depth direction. Each first region 301 has a peak of the doping concentration in the depth direction. The number of first regions 301 in the first mesa portion 61 is less than the number of the second regions 302 in the second mesa portion 62. The second mesa portion 62 in the present example has two second regions 302, and the first mesa portion 61 has one first region 301.

The third mesa portion 63 in the present example has the first regions 301 (or the third regions 303) in a number similar to the first mesa portions 61. Structures other than the first region 301, the second region 302 and the third region 303 are similar to any form described in the present specification.

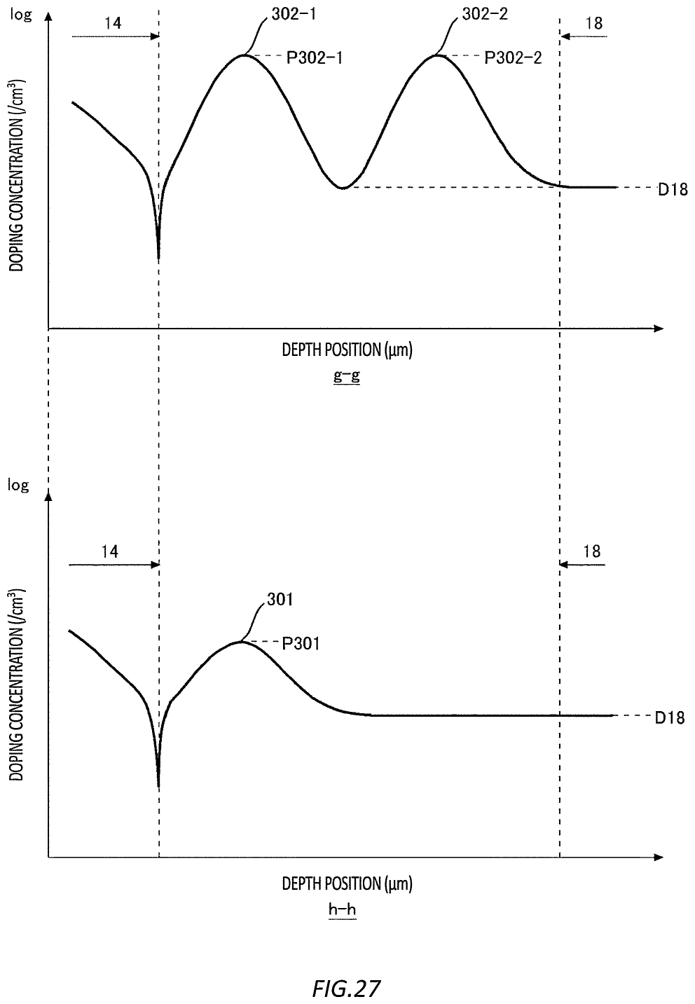

FIG. 27 illustrates an example of the doping concentration distributions on the line g-g and the line h-h of FIG. 26. The doping concentration distribution in the second mesa portion 62 in the present example is similar to the example shown in FIG. 23.

The first mesa portion 61 of the present example has one first region 301. The doping concentration P301 of the first region 301 may be lower than any of that of the second region 302-1 or the second region 302-2. In another example, the doping concentration P301 of the first region 301 may be the same as either of that of the second region 302-1 or the second region 302-2. Since the number of the first regions 301 is less than the number of the second regions 302, even if the doping concentrations of each peak are the same, the total dose amount of the first region 301 can be less than the total dose amount of the second regions 302. According to the present example, hole implantation in the transistor portion 70 near the diode portion 80 can be adjusted, the decrease of the withstand capability can be suppressed, and trade-off between reverse recovery loss and the forward voltage can be adjusted.

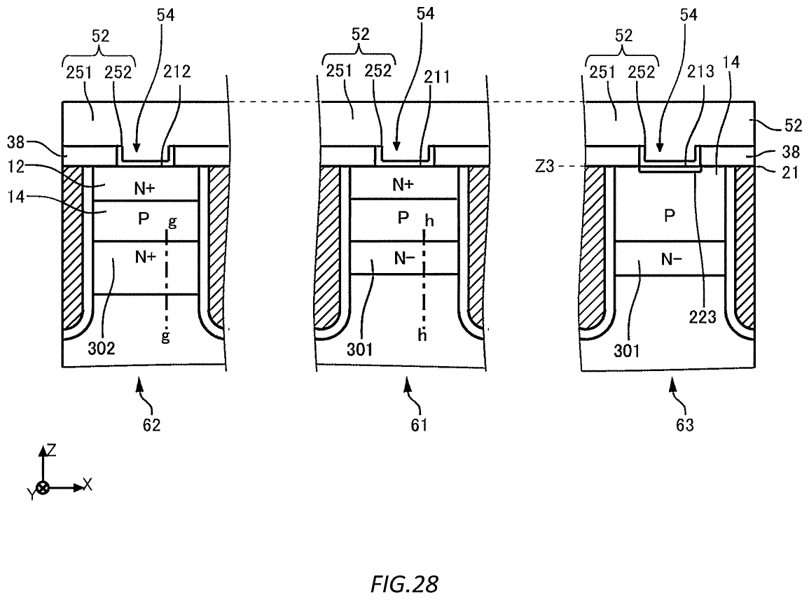

FIG. 28 illustrates another configuration example of the first mesa portion 61, the second mesa portion 62 or the third mesa portion 63. In the present example, the number of the first regions 301 of the first mesa portion 61 is the same as the number of the second regions 302 of the second mesa portion 62. The number of the first regions 301 (or the third regions 303) in the third mesa portion 63 may be the same as the number of the first regions 301 of the first mesa portion 61. In the example of FIG. 28, the first mesa portion 61 has one first region 301, the second mesa portion 62 has one second region 302, and the third mesa portion 63 has one third region 303.

In the present example, a width in the depth direction of the second region 302 is greater than a width in the depth direction of the first region 301. Each region has a peak of the doping concentration in the depth direction.

Structures other than the first region 301, the second region 302 and the third region 303 are similar to any form described in the present specification.

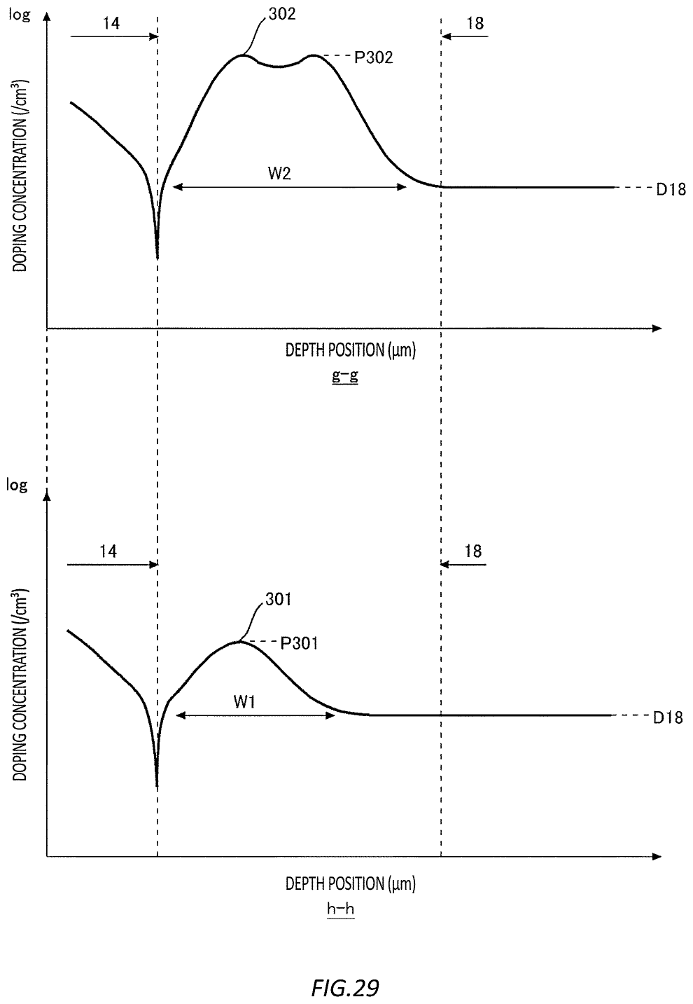

FIG. 29 illustrates an example of doping concentration distributions on a line g-g and a line h-h of FIG. 28. The second region 302 has one or more peaks of the doping concentration. The second region 302 in the present example may be formed by the implantation of dopants into different depth positions. In this case, although a peak is provided in the doping concentration at each depth position, in a case where the depth positions are close to each other, the peaks of the doping concentration are attached to each other, and may be observed to be like one peak.

In the present example. the first region 301 has one peak of the doping concentration. The first region 301 in the present example may be formed by the implantation of dopants at a single depth position. In the present example, a width W2 in the depth direction of the second region 302 is greater than a width W1 in the depth direction of the first region 301. The width W2 may be 1.5 times or more, or may be twice or more of the width W1. A width of the first region 301 and the second region 302 is a width of a region where the doping concentration in a region of the N type between the base region 14 and the drift region 18 is higher than that of the drift region 18.

The doping concentration P301 of the first region 301 may be less than the doping concentration P302 of the second region 302. In another example, the doping concentration P301 of the first region 301 may be the same as the doping concentration P302 of the second region 302. Even if in the present example, the total dose amount of the first region 301 can be less than the total dose amount of the second region 302. According to the present example, hole implantation in the transistor portion 70 near the diode portion 80 can be adjusted, the decrease of the withstand capability can be suppressed, and trade-off between reverse recovery loss and the forward voltage can be adjusted.

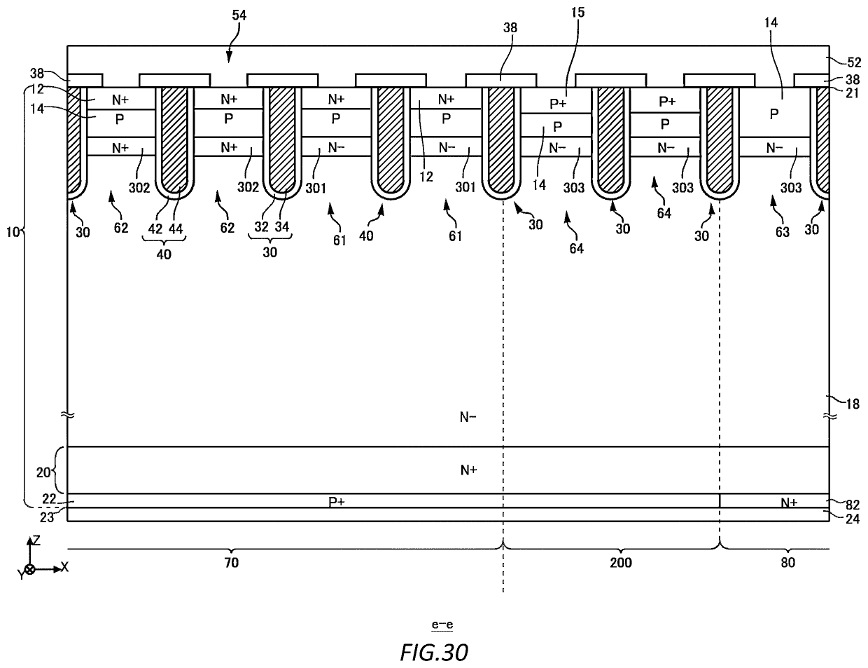

FIG. 30 illustrates a view showing another example of the cross section e-e. In the present example, the semiconductor device 100 differs from the semiconductor device 100 described in the present specification in a point of not having a lifetime adjustment region 206, an adjustment region 201 or a non-adjustment region 202. The other structures are similar to those of the semiconductor device 100 in any aspect described in the present specification. In FIG. 30, an example in which the lifetime adjustment region 206, adjustment region 201, and non-adjustment region 202 are deleted from the structure shown in FIG. 3A is shown, but the lifetime adjustment region 206, adjustment region 201, and non-adjustment region 202 may also be deleted in the structures shown in other figures.

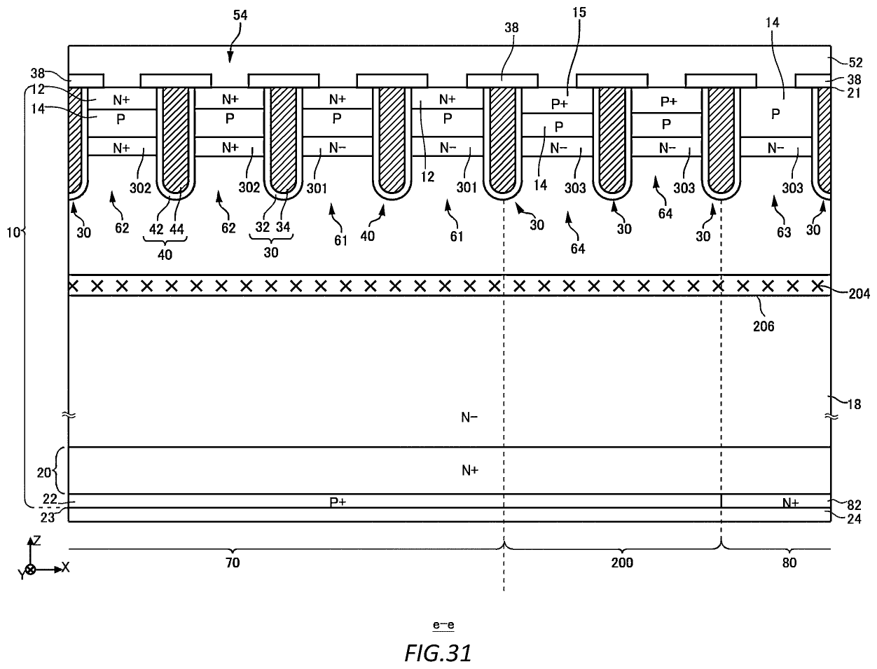

FIG. 31 illustrates a view showing another example of the cross section e-e. The semiconductor device 100 in the present example differs from the semiconductor device 100 described in the present specification in a point that the lifetime adjustment region 206 is provided throughout the transistor portion 70 in the X axis direction. The other structures are similar to the semiconductor device 100 of any aspect described in the present specification. In FIG. 31, in the structure shown in FIG. 3A, an example in which the lifetime adjustment region 206 is located throughout the transistor portion 70 is shown, but in the structure shown in the other figures, the lifetime adjustment region 206 may be located throughout the transistor portion 70.

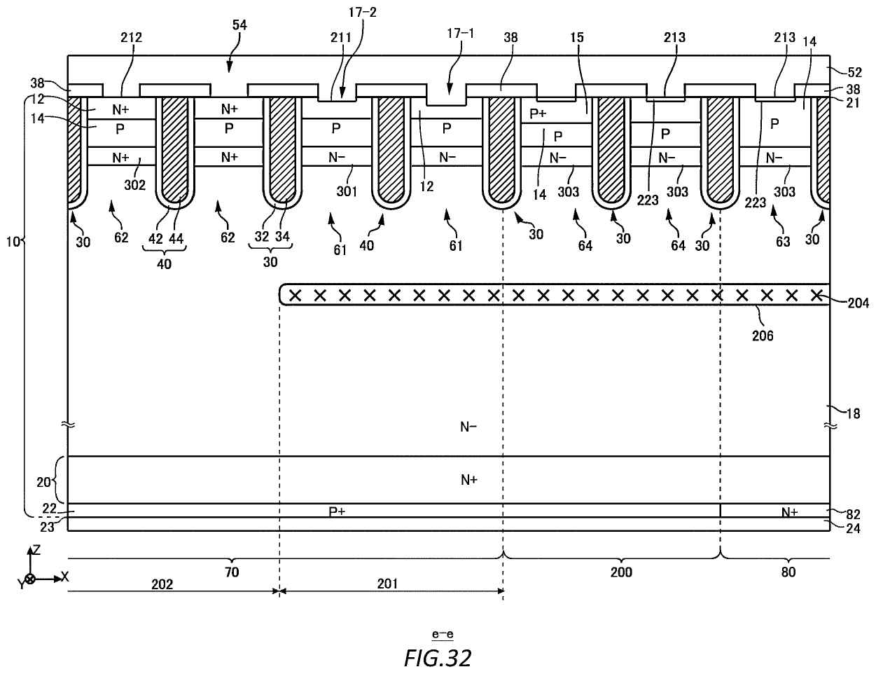

FIG. 32 illustrates a view showing another example of the cross section e-e. The semiconductor device 100 of the present example is different when compared to the structures described in FIG. 13 in the depth of the trench contact portions 17-1 and the trench contact portions 17-2. The other structures are similar to those of the semiconductor device 100 of any aspect described in the present specification.

In the present example, the trench contact portion 17-2 of at least one first mesa portion 61 is provided shallower than the trench contact portion 17-1 of the first mesa portion 61 arranged closer to the diode portion 80 than the first mesa portion 61 with the trench contact portion 17-2.

The trench contact portion 17 of each first mesa portion 61 may be formed shallower the further away from the diode portion 80. According to the present example, hole implantation in the transistor portion 70 near the diode portion 80 can be adjusted, the decrease of the withstand capability can be suppressed, and trade-off between reverse recovery loss and the forward voltage can be adjusted.

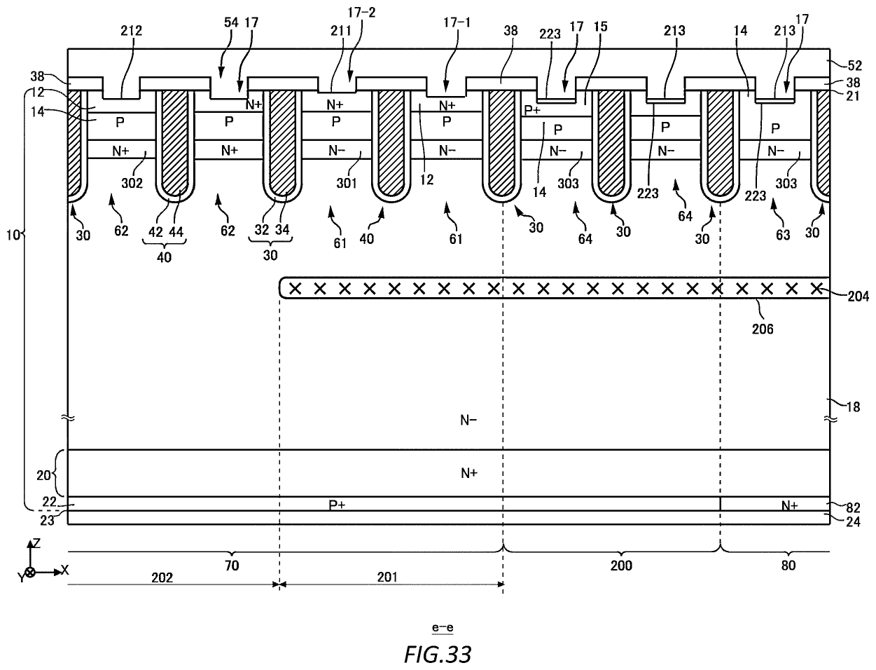

FIG. 33 illustrates a view showing another example of the cross section e-e. The semiconductor device 100 of the present example is different when compared to the structures described in FIG. 21A in the depth of the trench contact portions 17-1 and the trench contact portions 17-2. The other structures are similar to those of the semiconductor device 100 of any aspect described in the present specification.

In the present example, the trench contact portion 17-2 of at least one first mesa portion 61 is provided shallower than the trench contact portion 17-1 of the first mesa portion 61 arranged closer to the diode portion 80 than the first mesa portion 61 with the trench contact portion 17-2. The trench contact portion 17 of each first mesa portion 61 may be formed shallower the further away from the diode portion 80. According to the present example, hole implantation in the transistor portion 70 near the diode portion 80 can be adjusted, the decrease of the withstand capability can be suppressed, and trade-off between reverse recovery loss and the forward voltage can be adjusted.

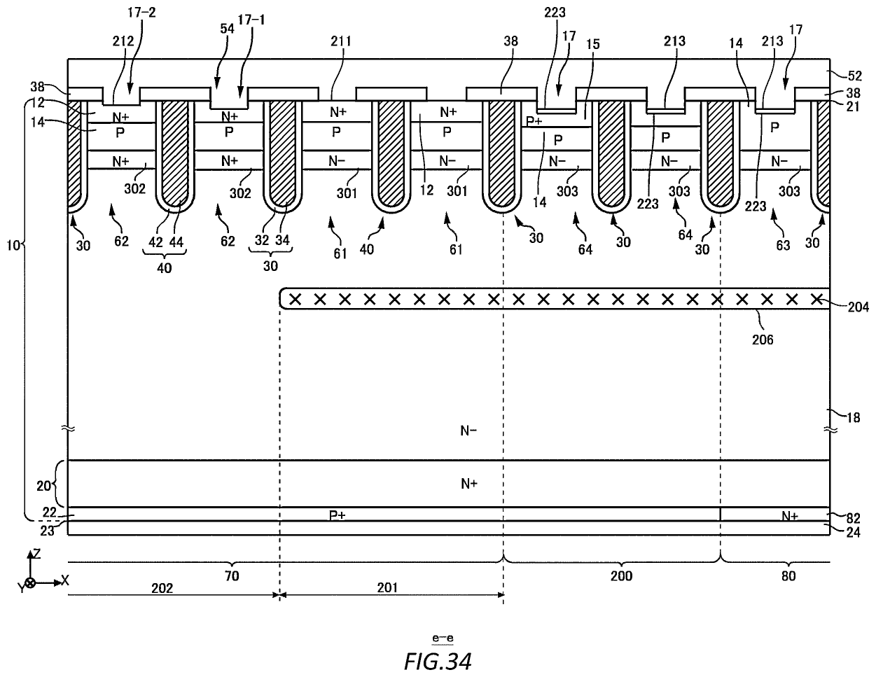

FIG. 34 illustrates a view showing another example of the cross section e-e. The semiconductor device 100 of the present example is different when compared to the structures described in FIG. 21B in the depth of the trench contact portions 17-1 and the trench contact portions 17-2. The other structures are similar to those of the semiconductor device 100 of any aspect described in the present specification. In the present example, the trench contact portions 17-2 of at least one second mesa portion 62 is provided shallower than the trench contact portions 17-1 of the second mesa portion 62 arranged closer to the diode portion 80 than the second mesa portion 62. The trench contact portions 17 of each second mesa portion 62 may be formed shallower as leaving further away from the diode portion 80. According to the present example, hole implantation in the transistor portion 70 near the diode portion 80 can be adjusted, the decrease of the withstand capability can be suppressed, and trade-off between reverse recovery loss and the forward voltage can be adjusted.

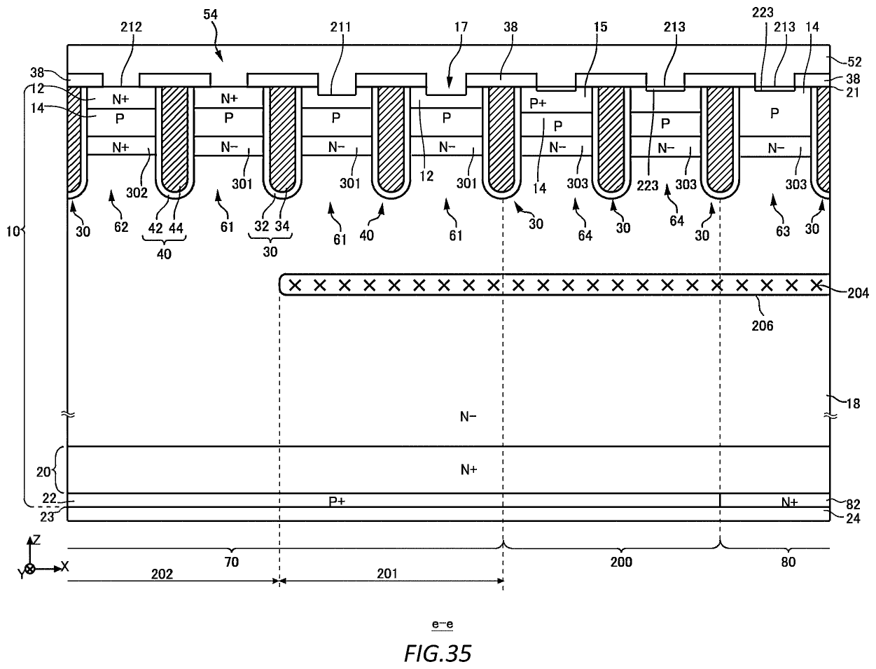

FIG. 35 illustrates a view showing another example of the cross section e-e. The semiconductor device 100 of the present example is different when compared to the structures described in FIG. 7 in a point that at least one first mesa portion 61 includes the second contact portion 212. The other structures are similar to those of the semiconductor device 100 of any aspect described in the present specification. One or more first mesa portions 61 arranged closest to the second mesa portion 62 may include the second contact portion 212.

In the present example, at least one first mesa portions 61 do not include the trench contact portions 17 similar to the second mesa portion 62. According to the present example, hole implantation in the transistor portion 70 near the diode portion 80 can be adjusted, the decrease of the withstand capability can be suppressed, and trade-off between reverse recovery loss and the forward voltage can be adjusted.

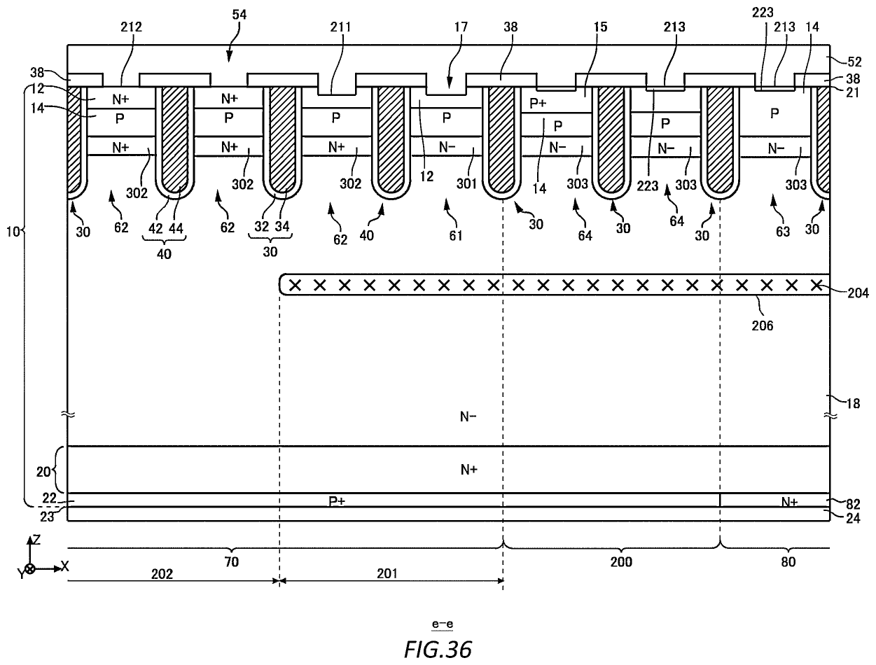

FIG. 36 illustrates a view showing another example of the cross section e-e. The semiconductor device 100 of the present example is different when compared to the structures described in FIG. 7 in a point that at least one second mesa portion 62 includes the first contact portion 211. The other structures are similar to those of the semiconductor device 100 of any aspect described in the present specification. One or more second mesa portions 61 arranged closest to the first mesa portion 61 may include the first contact portion 211.

In the present example, at least one second mesa portion 62 includes the trench contact portions 17 similar to the first mesa portion 61. According to the present example, hole implantation in the transistor portion 70 near the diode portion 80 can be adjusted, the decrease of the withstand capability can be suppressed, and trade-off between reverse recovery loss and the forward voltage can be adjusted.

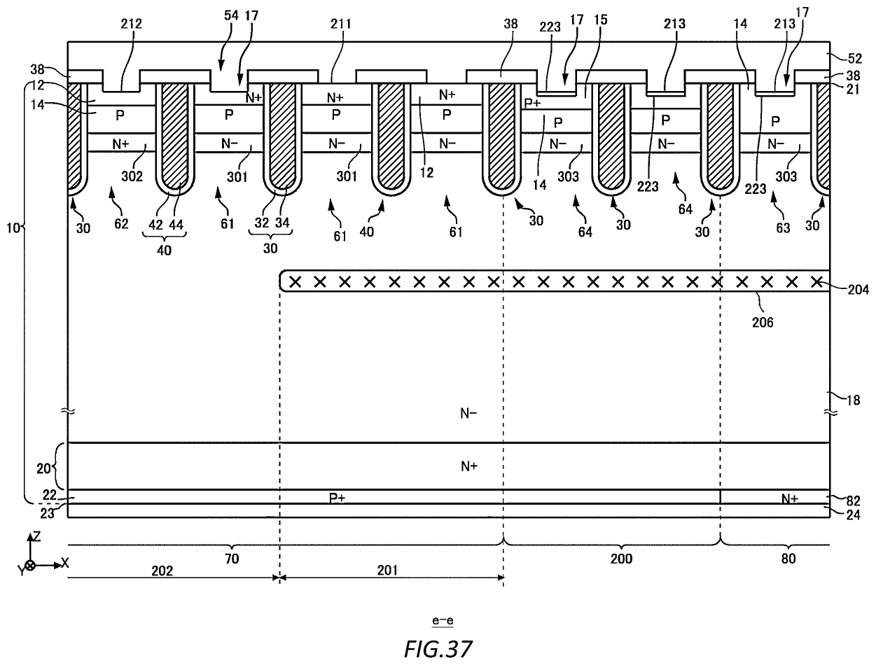

FIG. 37 illustrates a view showing another example of the cross section e-e. The semiconductor device 100 of the present example is different when compared to the structures described in FIG. 15 in a point that at least one first mesa portion 61 includes the second contact portion 212. The other structures are similar to those of the semiconductor device 100 of any aspect described in the present specification. One or more first mesa portions 61 arranged closest to the second mesa portion 62 may include the second contact portion 212.

In the present example, at least one first mesa portions 61 include the trench contact portions 17 similar to the second mesa portion 62. According to the present example, hole implantation in the transistor portion 70 near the diode portion 80 can be adjusted, the decrease of the withstand capability can be suppressed, and trade-off between reverse recovery loss and the forward voltage can be adjusted.

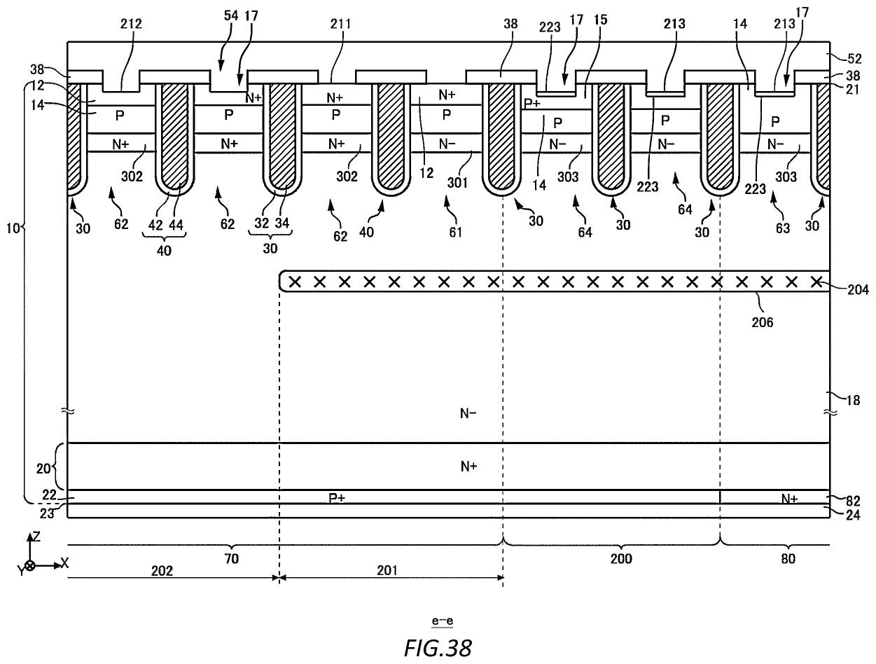

FIG. 38 illustrates a view showing another example of the cross section e-e. The semiconductor device 100 of the present example is different when compared to the structures described in FIG. 15 in a point that at least one second mesa portion 62 includes the first contact portion 211. The other structures are similar to those of the semiconductor device 100 of any aspect described in the present specification. One or more second mesa portions 61 arranged closest to the first mesa portion 61 may include the first contact portion 211.

In the present example, at least one second mesa portion 62 does not include the trench contact portions 17 similar to the first mesa portion 61. According to the present example, hole implantation in the transistor portion 70 near the diode portion 80 can be adjusted, the decrease of the withstand capability can be suppressed, and trade-off between reverse recovery loss and the forward voltage can be adjusted.

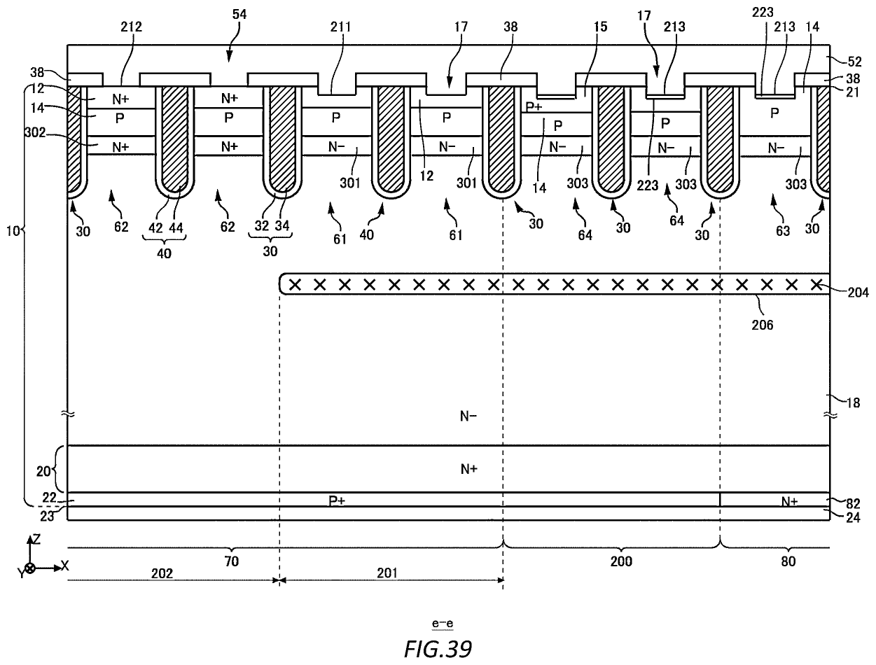

FIG. 39 illustrates a view showing another example of the cross section e-e. In the semiconductor device 100 of the present example, at least one third mesa portions 63 of the diode portion 80 has the trench contact portions 17. All the third mesa portions 63 of the diode portion 80 may have the trench contact portions 17. At least one fourth mesa portions 64 of the boundary region 200 may not have the trench contact portions 17. All the fourth mesa portions 64 of the boundary region 200 may have the trench contact portions 17. The other structures are similar to the semiconductor device 100 of any aspect described in the present specification. In FIG. 39, in the structure shown in FIG. 3A, although the example where the third mesa portion 63 and the fourth mesa portion 64 has the trench contact portions 17, in the structures shown in other figures, the third mesa portion 63 and the fourth mesa portion 64 may not have the trench contact portions 17.

The trench contact portions 17 of the third mesa portion 63 may be formed shallower than, or may be formed deeper than, or may be formed at the same depth as the trench contact portions 17 of the transistor portion 70. The trench contact portions 17 of the fourth mesa portion 64 may be formed shallower than, or may be formed deeper than, or may be formed at the same depth as the trench contact portions 17 of the transistor portion 70.

As shown in FIG. 39, the lower end of the third contact portion 213 may be arranged below the lower end of the second contact portion 212. The lower end of the third contact portion 213 may be arranged at the depth position identical to the lower end of the second contact portion 212.

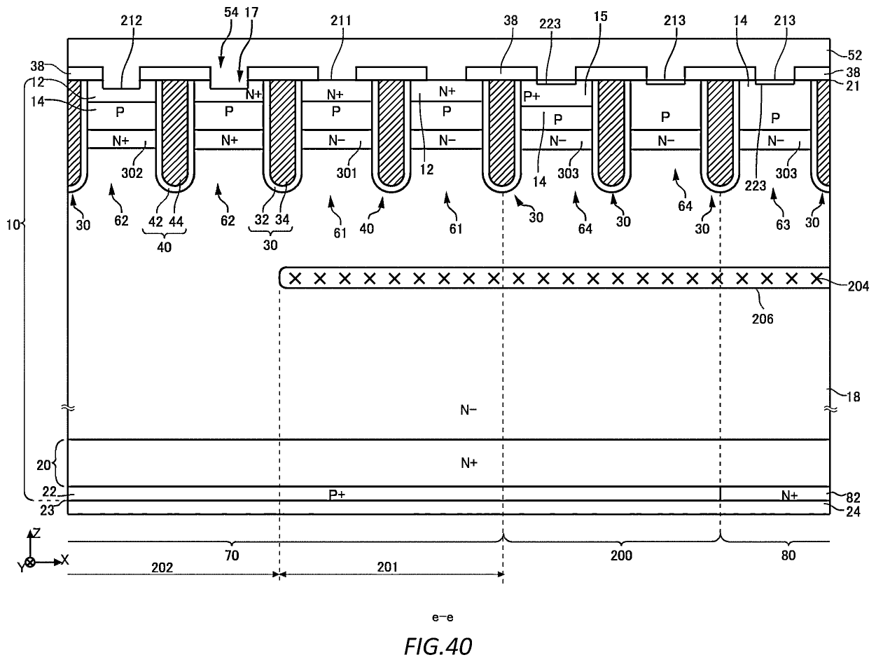

FIG. 40 illustrates a view showing another example of the cross section e-e. In the semiconductor device 100 of the present example, the lower end of the third contact portion 213 of at least one third mesa portion 63 of the diode portion 80 is arranged above the lower end of the second contact portion 212. The lower ends of the third contact portions 213 of all the third mesa portions 63 of the diode portion 80 may be arranged above the lower end of the second contact portion 212. The lower end of the third contact portion 213 may be arranged at a height position identical to that of the upper surface 21 of the semiconductor substrate 10. The fourth mesa portion 64 of the boundary region 200 may have the third contact portion 213 similar to the third mesa portion 63. The other structures are similar to the semiconductor device 100 of any aspect described in the present specification.

The lower end of the third contact portion 213 may be arranged at the depth position identical to the lower end of the first contact portion 211. The lower end of the third contact portion 213 may be arranged above, or may be arranged below the lower end of the first contact portion 211. The third plug region 223 may not be provided at the lower end of the third contact portion 213, which is provided in the fourth mesa portion 64 and the third mesa portion 63 of the boundary region 200.

In the present example, since the third contact portion 213 is formed shallow, the base region 14 of the third mesa portion 63 can remain more. Therefore, the amount of hole implantation in the diode portion 80 can be more, and the forward voltage can be reduced, thereby the trade-off with reverse recovery loss can be adjusted. Even if the barrier metal is provided in the semiconductor device 100, the amount of barrier metal in the third contact portion 213 can be reduced. In this manner, hydrogen absorption in the third contact portion 213 can be suppressed, and the implantation amount of hydrogen to the transistor portion 70 via the third contact portion 213 can be maintained. In this manner, the decrease of the threshold voltage of the transistor portion 70 can be suppressed.

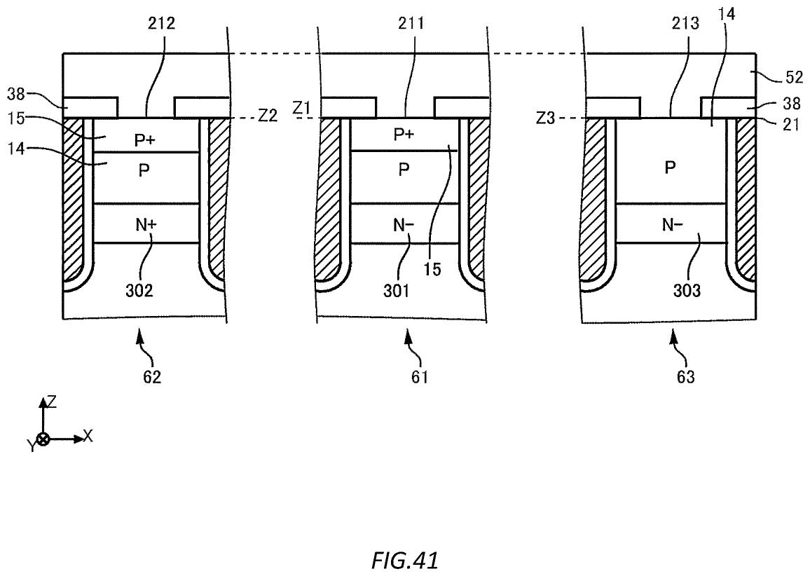

FIG. 41 illustrates another configuration example of the first mesa portion 61, the second mesa portion 62 and the third mesa portion 63. In the present example, the first mesa portion 61 includes the first contact portion 211, the second mesa portion 62 includes the second contact portion 212, and the third mesa portion 63 includes the third contact portion 213.

The emitter electrode 52 in the present example does not have a barrier metal portion 252 in a portion contacting the semiconductor substrate 10. The first plug region 221, the second plug region 222 or the third plug region 223 is not included. Other structures are similar to the semiconductor device 100 in any aspect described in the present specification.

In the present example, the dose amount of the first region 301 of the first mesa portion 61 is less than the dose amount of the second region 302 of the second mesa portion 62. According to the present example, hole implantation in the transistor portion 70 near the diode portion 80 can be adjusted, the decrease of the withstand capability can be suppressed, and trade-off between reverse recovery loss and the forward voltage can be adjusted.

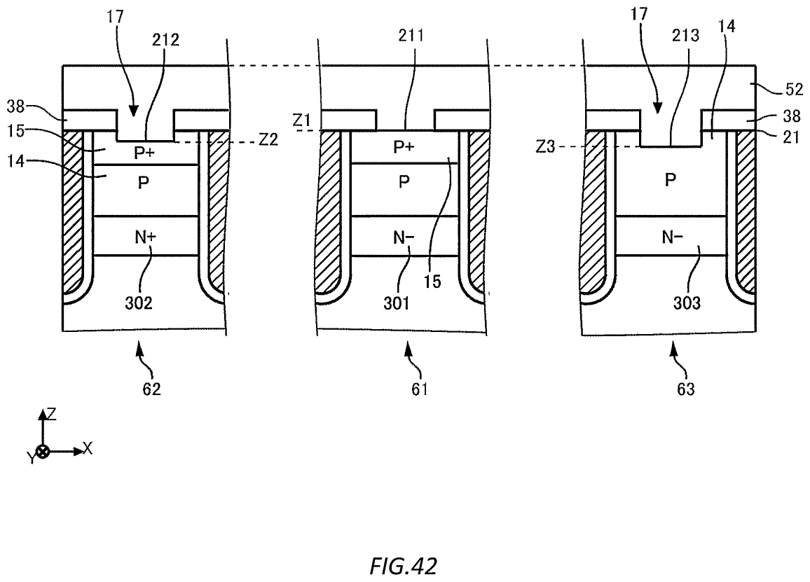

FIG. 42 illustrates another configuration example of the first mesa portion 61, the second mesa portion 62 and the third mesa portion 63. The present example is different from the example shown in FIG. 41 in a point of having the trench contact portions 17 provided in the second mesa portion 62 and the third mesa portion 63.

The present example includes the first contact portion 211 provided in the first mesa portion 61. The present example also includes the trench contact portions 17 with the second contact portion 212 provided in the second mesa portion 63, and the trench contact portions 17 with the third contact portion 213 provided in the third mesa portion 62.

The emitter electrode 52 in the present example does not have a barrier metal portion 252 in a portion contacting the semiconductor substrate 10. The first plug region 221, the second plug region 222 or the third plug region 223 is not included. Other structures are similar to the semiconductor device 100 of any aspect described in the present specification. In this manner, by not providing the trench contact portions 17 in the first mesa portion 61 of the transistor portion 70, the forward voltage can be reduced. As described above, according to the present example, hole implantation in the transistor portion 70 near the diode portion 80 can be adjusted, the decrease of the withstand capability can be suppressed, and trade-off between reverse recovery loss and the forward voltage can be adjusted.

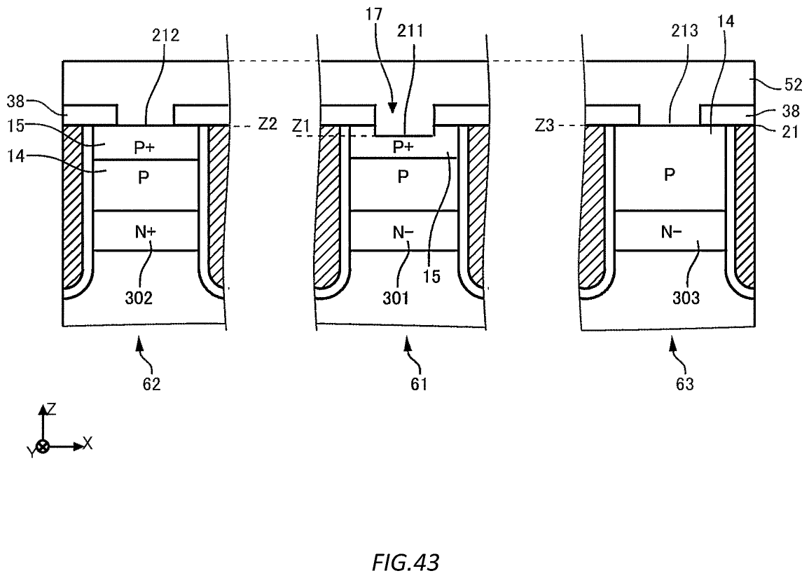

FIG. 43 illustrates another configuration example of the first mesa portion 61, the second mesa portion 62 and the third mesa portion 63. The present example is different from FIG. 41 in a point of providing the trench contact portions 17 in the first mesa portion 61.

In the present example, the second mesa portion 62 includes the second contact portion 212, and the third mesa portion 63 includes the third contact portion 213. Also, the present example includes the trench contact portions 17 with the first contact portion 211 provided in the first mesa portion.

The emitter electrode 52 in the present example does not have a barrier metal portion 252 in a portion contacting the semiconductor substrate 10. The first plug region 221, the second plug region 222 or the third plug region 223 is not included. Other structures are similar to the semiconductor device 100 in any aspect described in the present specification. In this manner, by providing the trench contact portions 17 in the first mesa portion 61 of the transistor portion 70, reverse recovery loss can be reduced. As described above, according to the present example, hole implantation in the transistor portion 70 near the diode portion 80 can be adjusted, the decrease of the withstand capability can be suppressed, and trade-off between reverse recovery loss and the forward voltage can be adjusted.

In FIG. 41, FIG. 42 and FIG. 43, the presence or absence of the trench contact portions 17 corresponds to the first mesa portion 61, the second mesa portion 62 and the third mesa portion 63. For example, all the first mesa portions 61 may have the trench contact portions 17, or all the first mesa portions 61 may not have the trench contact portions 17. Similarly, all the second mesa portions 62 may have the trench contact portions 17, or all the second mesa portions 62 may not have the trench contact portions 17. Similarly, all the third mesa portions 63 may have the trench contact portions 17, or all the third mesa portions 63 may not have the trench contact portions 17.

In another example, the presence or absence of the trench contact portions 17 may not be identical in all of the first mesa portion 61, the second mesa portion 62 and the third mesa portion 63. For example, some first mesa portions 61 may have the trench contact portions 17, and the rest first mesa portions 61 may not have the trench contact portions 17. Similarly, some second mesa portions 62 may have the trench contact portions 17, and the rest second mesa portions 62 may not have the trench contact portions 17. Similarly, some third mesa portions 63 may have the trench contact portions 17, and the rest third mesa portions 63 may not have the trench contact portions 17. The fourth mesa portion 64 (not shown) without the third plug region 223 may be further included. In the fourth mesa portion 64 without this third plug region 223, the trench contact portions 17 may be provided, or may be not provided.

While the present invention has been described with the embodiments, the technical scope of the present invention is not limited to the above-described embodiments. It is apparent to persons skilled in the art that various alterations and improvements can be added to the above-described embodiments. It is also apparent from the described scope of the claims that the embodiments added with such alterations or improvements can be included the technical scope of the present invention.

It should be noted that the operations, procedures, steps, stages, or the like of each process performed by a device, system, program, and method shown in the claims, the specification, or the drawings can be performed in any order as long as the order is not indicated by “prior to,” “before,” or the like and as long as the output from a previous process is not used in a later process. Even if the process flow is described using phrases such as “first” or “next” in the claims, the specification, or the drawings for the sake of convenience, it does not necessarily mean that the process must be performed in this order.

What is claimed is:

1. A semiconductor device comprising a semiconductor substrate having an upper surface and a lower surface, a transistor portion provided on the semiconductor substrate, and a diode portion provided on the semiconductor substrate and arranged side by side with the transistor portion in a first direction,
wherein each of the transistor portion and the diode portion has:
a plurality of trench portions provided inward from the upper surface of the semiconductor substrate, and arranged side by side in the first direction; and
a plurality of mesa portions, each of which is a portion sandwiched between two of the trench portions in the first direction in the semiconductor substrate,
wherein the semiconductor substrate has a drift region of a first conductivity type and a base region of a second conductivity type arranged between the drift region and the upper surface;
wherein the plurality of mesa portions include first mesa portions and second mesa portions arranged farther away from the diode portion than the first mesa portions, the first mesa portions including a first mesa portion, and the second mesa portions including a second mesa portion;
wherein the first mesa portion has a first region of the first conductivity type provided in at least a part of a region between a depth position of a lower end of the base region and a depth position of a lower end of the trench portion; and
wherein the second mesa portion has a second region of the first conductivity type provided in at least a part of the region between the depth position of the lower end of the base region and the depth position of the lower end of the trench portion and having a dose amount greater than that of the first region.

2. The semiconductor device according to claim 1, wherein the first region is the drift region.

3. The semiconductor device according to claim 1, wherein the first region is a region with a doping concentration higher than that of the drift region.

4. The semiconductor device according to claim 1, wherein the diode portion has a lifetime adjustment region arranged on an upper surface side of the semiconductor substrate, including a lifetime killer that adjusts a lifetime of a carrier.

5. The semiconductor device according to claim 4, wherein the lifetime adjustment region extends to a region below the first mesa portion.

6. The semiconductor device according to claim 5, wherein:
the plurality of mesa portions include one or more of the second mesa portions; and
the lifetime adjustment region extends to a region below at least one of the second mesa portions, and does not extend to a region below another of the second mesa portions.

7. The semiconductor device according to claim 5, wherein the lifetime adjustment region is arranged away from the second mesa portion in the first direction.

8. The semiconductor device according to claim 1, wherein the second region has a doping concentration higher than that of the first region.

9. The semiconductor device according to claim 1, wherein a number of peaks of a doping concentration in a depth direction of the second region, is greater than a number of peaks of a doping concentration in a depth direction of the first region.

10. The semiconductor device according to claim 1, wherein a width in the depth direction of the second region is greater than a width in the depth direction of the first region.

11. The semiconductor device according to claim 1, wherein a dose amount per unit area of the second region is greater than a dose amount per unit area of the first region.

12. The semiconductor device according to claim 1, wherein:
the plurality of mesa portions include third mesa portions arranged in the diode portion, the third mesa portions including a third mesa portion;
the third mesa portion has:
an anode region of the second conductivity type arranged between the drift region and the upper surface; and
a third region of the first conductivity type provided in at least a part of a region between a depth position of a lower end of the anode region and a depth position of a lower end of the trench portion, and
the second region has a dose amount greater than that of the third region.

13. The semiconductor device according to claim 4, wherein:
each of the transistor portion and the diode portion has a metal electrode provided above the upper surface of the semiconductor substrate;
the first mesa portion has a first contact portion contacting the metal electrode;
the second mesa portion has a second contact portion contacting the metal electrode; and
a lower end of the second contact portion is arranged above a lower end of the first contact portion.

14. The semiconductor device according to claim 4, wherein:
each of the transistor portion and the diode portion has a metal electrode provided above the upper surface of the semiconductor substrate;
the first mesa portion has a first contact portion contacting the metal electrode;
the second mesa portion has a second contact portion contacting the metal electrode; and
a lower end of the first contact portion is arranged above a lower end of the second contact portion.

15. The semiconductor device according to claim 4, wherein:
the lifetime adjustment region is also provided in a part of the transistor portion;
the transistor portion includes an adjustment region with the lifetime adjustment region provided therein and a non-adjustment region without the lifetime adjustment region provided therein;
all of the mesa portions of the adjustment region are the first mesa portions; and
all of the mesa portions of the non-adjustment region are the second mesa portions.

16. The semiconductor device according to claim 4, wherein:
the lifetime adjustment region is provided in a part of the transistor portion;
the transistor portion includes an adjustment region with a lifetime adjustment region provided therein and a non-adjustment region without the lifetime adjustment region provided therein;
the adjustment region includes the first mesa portions and the second mesa portions; and
a number of the first mesa portions in the adjustment region is equal to or greater than a number of the second mesa portions in the adjustment region.

17. The semiconductor device according to claim 4, wherein:
the lifetime adjustment region is provided in a part of the transistor portion;
the transistor portion includes an adjustment region with the lifetime adjustment region provided therein and a non-adjustment region without the lifetime adjustment region provided therein;
at least some of the mesa portions of the adjustment region are the first mesa portions;
a density of lattice defects of the lifetime adjustment region in the adjustment region becomes lower as leaving further away from the diode portion; and
in the adjustment region, a doping concentration of the first region becomes higher as the first mesa portions leave further away from the diode portion.

18. The semiconductor device according to claim 5, wherein:
each of the transistor portion and the diode portion has a metal electrode provided above the upper surface of the semiconductor substrate;
the first mesa portion has a first contact portion contacting the metal electrode;
the second mesa portion has a second contact portion contacting the metal electrode; and
a lower end of the first contact portion is arranged above a lower end of the second contact portion.

19. The semiconductor device according to claim 6, wherein:
each of the transistor portion and the diode portion has a metal electrode provided above the upper surface of the semiconductor substrate;
the first mesa portion has a first contact portion contacting the metal electrode;
the second mesa portion has a second contact portion contacting the metal electrode; and
a lower end of the first contact portion is arranged above a lower end of the second contact portion.

20. The semiconductor device according to claim 7, wherein:
each of the transistor portion and the diode portion has a metal electrode provided above the upper surface of the semiconductor substrate;
the first mesa portion has a first contact portion contacting the metal electrode;
the second mesa portion has a second contact portion contacting the metal electrode; and
a lower end of the first contact portion is arranged above a lower end of the second contact portion.
